(19) United States
(12) Patent Application Publication
(10) Pub. No.: US 2023/0194988 A1
(43) Pub. Date: Jun. 22, 2023

(54) TRANSFER FILM, MANUFACTURING METHOD FOR LAMINATE, MANUFACTURING METHOD FOR CIRCUIT WIRE, AND MANUFACTURING METHOD FOR ELECTRONIC DEVICE

(71) Applicant: FUJIFILM Corporation, Tokyo (JP)

(72) Inventors: Satoru YAMADA, Shizuoka (JP); Yutaka NOZOE, Shizuoka (JP); Kazumasa MOROZUMI, Shizuoka (JP)

(73) Assignee: FUJIFILM Corporation, Tokyo (JP)

(21) Appl. No.: 18/170,591

(22) Filed: Feb. 17, 2023

Related U.S. Application Data
(63) Continuation of application No. PCT/JP2021/030399, filed on Aug. 19, 2021.

(30) Foreign Application Priority Data
Aug. 24, 2020 (JP) 2020-140811

(51) Int. Cl. G03F 7/09; G03F 7/20; G03F 7/34; G03F 1/80; H01L 21/683; G03F 7/004; G03F 7/038

(52) U.S. Cl. CPC G03F 7/09; G03F 7/2004; G03F 7/34; G03F 1/80; H01L 21/6835; G03F 7/0045; G03F 7/0382

(57) ABSTRACT

The present invention provides a transfer film in which a pattern appearance defect is unlikely to occur, a manufacturing method for a laminate, a manufacturing method for a circuit wire, and a manufacturing method for an electronic device. The transfer film of the present invention includes a temporary support a resin composition layer disposed on the temporary support, in which the resin composition layer contains a resin, and at least one compound selected from the group consisting of a block copolymer, which contains a block consisting of a constitutional unit X having a group represented by Formula (A) or a group represented by Formula (B) and a block a constitutional unit Y having a poly(oxyalkylene) group, and a compound represented by Formula (1).

### CROSS-REFERENCE TO RELATED APPLICATIONS

This application is a Continuation of PCT International Application No. PCT/JP2021/030399 filed on Aug. 19, 2021, which claims priority under 35 U.S.C. § 119(a) to Japanese Patent Application No. 2020-140811 filed on Aug. 24, 2020. The above applications are hereby expressly incorporated by reference, in their entirety, into the present application.

### BACKGROUND OF THE INVENTION

### 1. Field of the Invention

The present invention relates to a transfer film, a manufacturing method for a laminate, a manufacturing method for a circuit wire, and an electronic device.

A method, in which a resin composition layer provided on any substrate by using a transfer film is exposed through a mask including a desired pattern and then developed, has been widely used since the number of steps for obtaining a pattern having a predetermined shape is small.

For example, WO2017/057348A discloses a transfer film containing a copolymer having a predetermined fluoroalkyl group.

### SUMMARY OF THE INVENTION

As a result of studying such a transfer film as disclosed in WO2017/057348A, the inventor of the present invention found that a pattern obtained after exposure and subsequent development is likely to have an appearance defect. Specifically, the finding includes that the pattern is likely to be peeled off or residues are likely to be generated at the time of pattern formation and thus a high-resolution pattern cannot be obtained, that concentration unevenness is large in a case where the pattern contains a pigment, and that there are many defects on the surface of the pattern.

Hereinafter, in the present specification, it is also referred to as that the appearance defect of the pattern is unlikely to occur in a case where at least one of the following can be suppressed; that the pattern is likely to be peeled off or residues are likely to be generated at the time of pattern formation and thus a high-resolution pattern cannot be obtained, that concentration unevenness is large in a case where the pattern contains a pigment, or that there are many defects on the surface of the pattern.

An object of the present invention is to provide a transfer film in which an appearance defect of a pattern is unlikely to occur. In addition, another object of the present invention is to provide a manufacturing method for a laminate, a manufacturing method for a circuit wire, and a manufacturing method for an electronic device, which are related to the transfer film.

As a result of carrying out intensive studies to achieve the objects, the inventors of the present invention found that the objects can be achieved by the following configurations.

[1] A transfer film comprising:

a temporary support; and

a resin composition layer disposed on the temporary support,

in which the resin composition layer contains

a resin, and

at least one compound selected from the group consisting of a block copolymer, which contains a block consisting of a constitutional unit X having a group represented by Formula (A) described later or a group represented by Formula (B) described later and a block a constitutional unit Y having a poly(oxyalkylene) group, and a compound represented by Formula (1) described later.

[2] The transfer film according to [1], in which the constitutional unit X and the compound represented by Formula (1) have a group represented by Formula (A).

[3] The transfer film according to [1], in which the constitutional unit X and the compound represented by Formula (1) have a group represented by Formula (B).

[4] The transfer film according to any one of [1] to [3], in which the compound represented by Formula (I) is contained, and a molecular weight of the compound represented by Formula (1) is 2,000 or less.

[5] The transfer film according to any one of [1] to [4], in which the block copolymer is contained, and a weight-average molecular weight of the block copolymer is 5,000 or more.

[6] The transfer film according to any one of [1] to [5], in which the resin is an alkali-soluble resin, and the resin composition layer further contains a polymerizable compound.

[7] The transfer film according to any one of [1] to [5], in which the resin is a resin having a constitutional unit having an acid group protected by an acid-decomposable group, and the resin composition layer further contains a photoacid generator.

[8] The transfer film according to any one of [1] to [7], in which the resin composition layer is a water-soluble resin composition layer.

[9] The transfer film according to [8], in which the water-soluble resin composition layer contains metal oxide particles.

[10] The transfer film according to any one of [1] to [9], in which the resin composition layer is a thermoplastic resin composition layer.

[11] The transfer film according to any one of [1] to [10], in which the resin composition layer further contains a pigment.

[12] The transfer film according to any one of [1] to [11], in which the resin composition layer includes two or more layers of the resin composition layer.

[13] A manufacturing method for a laminate, comprising:

an affixing step of bringing a substrate into contact with a surface of the transfer film according to any one of [1] to [12] on a side opposite to the temporary support and affixing the transfer film to the substrate to obtain a transfer film-attached substrate;

an exposure step of subjecting the resin composition layer to pattern exposure;

a development step of developing the exposed resin composition layer to form a resin pattern; and

a peeling step of peeling the temporary support from the transfer film-attached substrate between the affixing step and the exposure step, or between the exposure step and the development step.

[14] A manufacturing method for a circuit wire, comprising:

an affixing step of bringing a surface of the transfer film according to any one of [1] to [12] on a side opposite to the temporary support into contact with a substrate having a conductive layer and affixing the transfer film to the substrate having the conductive layer to obtain a transfer film-attached substrate;

an exposure step of subjecting the resin composition layer to pattern exposure; a development step of developing the exposed resin composition layer to form a resin pattern;

an etching step of subjecting the conductive layer in a region where the resin pattern is not disposed to an etching treatment; and

a peeling step of peeling the temporary support from the transfer film-attached substrate, between the affixing step and the exposure step or between the exposure step and the development step.

[15] A manufacturing method for an electronic device, comprising:

the manufacturing method for a laminate according to [13],

in which the electronic device includes the resin pattern as a cured film.

[16] The transfer film according to [1],

in which the block copolymer is contained, a weight-average molecular weight of the block copolymer is 5,000 or more, and the constitutional unit X is a constitutional unit represented by Formula (C),

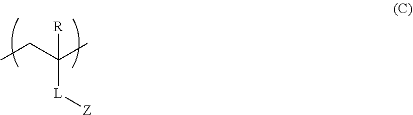

where R represents a hydrogen atom or a substituent, L represents a single bond or a divalent linking group, Z represents a group represented by the Formula (A) or a group represented by the Formula (B),

a content of the block copolymer is 0.01% to 3.00% by mass with respect to a total mass of the resin composition layer,

the resin is an alkali-soluble resin, and a content of the resin is 20.00% to 80.00% by mass with respect to a total mass of the resin composition layer, and

the resin composition layer further contains a polymerizable compound, and the polymerizable compound has an ethylenically unsaturated group as a polymerizable group.

According to the present invention, it is possible to provide a transfer film in which an appearance defect of a pattern is unlikely to occur. In addition, it is possible to provide a manufacturing method for a laminate, a manufacturing method for a circuit wire, and an electronic device, which are related to the transfer film.

### BRIEF DESCRIPTION OF THE DRAWINGS

FIG. 1 is a schematic view illustrating an example of a configuration of a transfer film.

### DESCRIPTION OF THE PREFERRED EMBODIMENTS

Hereinafter, the present invention will be described in more detail.

The following description of configuration requirements is based on representative embodiments of the invention; however, the present invention is not limited thereto.

In the present specification, a numerical value range expressed using “to” means a range that includes the preceding and succeeding numerical values of “to” as the lower limit value and the upper limit value, respectively.

A bonding direction of a divalent group (for example, —CO—O—) described in the present specification is not particularly limited.

In the present specification, (meth)acrylate indicates acrylate and methacrylate. The (meth)acrylic acid indicates acrylic acid and methacrylic acid. The (meth)acryloyl group indicates a methacryloyl group or an acryloyl group.

In describing a group (an atomic group) of the present specification, in a case where a description does not indicate substitution and non-substitution, the description means the group includes a group having a substituent as well as a group having no substituent. For example, the description “alkyl group” includes not only an alkyl group that does not have a substituent (an unsubstituted alkyl group) but also an alkyl group that has a substituent (a substituted alkyl group). Further, the “organic group” in the present specification means a group containing at least one carbon atom.

In the present specification, the kind of substituent, the position of substituent, and the number of substituents are not particularly limited in a case of being described as “may have a substituent”. The number of substituents may be, for example, one, two, three, or more. In addition, it may be unsubstituted.

Examples of the substituent include a monovalent non-metal atomic group excluding a hydrogen atom, and for example, the following substituent group T can be selected.

(Substituent T)

Examples of the substituent T include halogen atoms such as a fluorine atom, a chlorine atom, a bromine atom, and an iodine atom; alkoxy group such as a methoxy group, an ethoxy group, and a tert-butoxy group; aryloxy groups such as a phenoxy group and a p-tolyloxy group; alkoxycarbonyl groups such as a methoxycarbonyl group, a butoxycarbonyl group, and a phenoxycarbonyl group; acyloxy groups such as an acetoxy group, a propionyloxy group, and a benzoyloxy group; acyl groups such as an acetyl group, a benzoyl group, an isobutyryl group, an acryloyl group, a methacryloyl group, and a methoxalyl group; alkylsulfanyl groups such as a methylsulfanyl group and tert-butylsulfanyl group; arylsulfanyl groups such as a phenylsulfanyl group and a p-tolylsulfanyl group; an alkyl group; a cycloalkyl group; an aryl group; a heteroaryl group; a hydroxyl group; a carboxy group; a formyl group; a sulfo group; a cyano group; an alkylaminocarbonyl group; an arylaminocarbonyl group; a sulfonamide group; a silyl group; an amino group; a monoalkylamino group; a dialkylamino group; an arylamino group; and combinations thereof.

In the present specification, unless otherwise specified, the weight-average molecular weight (Mw) and the number-average molecular weight (Mn) are values calculated in terms of polystyrene by gel permeation chromatography (GPC).

The measurement by GPC is carried out under the following conditions.

[Eluent] tetrahydrofuran (THF)

[Device name] EcoSEC HLC-8320GPC (manufactured by Tosoh Corporation)

[Column] TSKgel SuperHZM-H, TSKgel SuperHZ4000, and TSKgel SuperHZ200 (manufactured by Tosoh Corporation)

[Column temperature] 40° C.

[Flow rate] 0.35 mL/min

In the present specification, unless otherwise specified, the molecular weight of a compound having a molecular weight distribution is the weight-average molecular weight (Mw).

In the present specification, unless otherwise specified, the room temperature is 25° C.

In the present specification, “alkali-soluble” means that the solubility in 100 g of an aqueous solution of 1% by mass sodium carbonate at 22° C. is 0.1 g or more. In the present specification, “water-soluble” means that the solubility in 100 g of water having a liquid temperature of 22° C. and a pH of 7.0 is 0.1 g or more.

In the present specification, the layer thickness (the film thickness) of each layer included in the transfer film or the like is measured by observing a cross section of a layer (a film) in a direction perpendicular to the main surface of the photosensitive transfer material with a scanning electron microscope (SEM), measuring the thickness of each layer at 10 points or more based on the obtained observation image, and calculating the average value thereof.

[Transfer Film]

A transfer film includes a temporary support and a resin composition layer disposed on the temporary support, where the resin composition layer contains a resin and at least one compound selected from the group consisting of a block copolymer (hereinafter, simply referred to as a “block copolymer”) which contains a block consisting of a constitutional unit X having a group represented by Formula (A) or a group represented by Formula (B) and a block a constitutional unit Y having a poly(oxyalkylene) group, and a compound (hereinafter, also referred to as a “compound (1)”) represented by Formula (1).

The mechanism by which the objects of the present invention are achieved by such configurations is not clear; however, the inventors of the present invention presume as follows.

In the transfer film in the related art, the above-described appearance defect of the pattern may occur. In particular, depending on the conditions for forming the resin composition layer, the above-described appearance defect of the pattern may occur more remarkably.

As a result of studying the cause thereof, the inventors of the present invention found that the above-described problem is caused by air bubbles (pores) in the resin composition layer. On the other hand, in a resin composition layer containing at least one compound selected from the group consisting of a predetermined block copolymer and the compound (1), which have a group represented by Formula (A) or a group represented by Formula (B), and a poly(oxyalkylene) group, it is presumed that the presence of each of the above groups suppresses the generation of the above-described bubbles (pores), which can suppress the appearance defect of the pattern.

Hereinafter, in the present specification, the fact that the appearance defect of the pattern is less likely to occur is also referred to as that the effect of the present invention is more excellent.

In the transfer film, the temporary support and the one or more resin composition layers described later may be directly laminated without another layer being interposed therebetween or may be laminated with another layer being interposed therebetween. In addition, another layer may be laminated on a surface of the one or more resin composition layers on a side opposite to the surface facing the temporary support. Another layer may be present between the one or more resin composition layers.

That is, the transfer film preferably has one or more resin composition layers and more preferably has two or more layers of the resin composition layers.

In the transfer film, it suffices that at least one layer of the one or more resin composition layers (for example, 1 to 5 layers) is the resin composition layer according to the embodiment of the present invention, half or more of the layers may be the resin composition layer according to the embodiment of the present invention, and all the layers may be the resin composition layer according to the embodiment of the present invention.

It is also preferable that the transfer film includes at least one photosensitive resin composition layer described later. The photosensitive resin composition layer may be a coloration resin composition layer.

[Temporary Support]

The transfer film has a temporary support.

The temporary support is a support that supports the resin composition layer described later or the laminate including the resin composition layer and can be peeled off.

The temporary support preferably has light transmittance from the viewpoint that exposure through a temporary support is possible in a case where the resin composition layer is subjected to pattern exposure. In addition, in this specification, “having light transmittance” means that the light transmittance at the wavelength used for pattern exposure is 50% or more.

From the viewpoint of improving exposure sensitivity, the temporary support preferably has a light transmittance of 60% or more and more preferably 70% or more at the wavelength (more preferably 365 nm) used for pattern exposure.

The light transmittance of the layer included in the transfer film is a rate of the intensity of the emitted light that has emitted and passed through a layer with respect to the intensity of the incident light in a case where the light is incident in a direction perpendicular to the main surface of the layer (the thickness direction), and it is measured by using MCPD Series manufactured by Otsuka Electronics Co., Ltd.

Examples of the material that constitutes the temporary support include a glass substrate, a resin film, and paper, and a resin film is preferable from the viewpoints of hardness, flexibility, and light transmittance.

Examples of the resin film include a polyethylene terephthalate (PET) film, a cellulose triacetate film, a polystyrene film, and a polycarbonate film. Among them, a PET film is preferable, and a biaxially stretched PET film is more preferable.

The thickness (the layer thickness) of the temporary support is not particularly limited, and it may be selected depending on the material from the viewpoints of the hardness as a support, the flexibility required for affixing to a substrate for forming a circuit wire, and the light transmittance required in the first exposure step.

The thickness of the temporary support is preferably 5 to 100 m, more preferably 10 to 50 m, still more preferably 10 to 20 m, and particularly preferably 10 to 16 m, from the viewpoints of ease of handling and general-purpose property.

In addition, it is preferable that the film to be used as the temporary support does not have deformation such as wrinkles, scratches, and defects.

From the viewpoint of pattern forming properties during pattern exposure through the temporary support and transparency of the temporary support, it is preferable that the number of fine particles, foreign substances, defects, and precipitates included in the temporary support is small. The number of fine particles having a diameter of 1 μm or more, foreign substances, and/or defects is preferably 50 pieces/10 mm² or less, more preferably 10 pieces/10 mm² or less, still more preferably 3 pieces/10 mm² or less, and particularly preferably 0 pieces/10 mm².

Preferred aspects of the temporary support are described in, for example, paragraphs [0017] and [0018] of JP2014-085643A, paragraphs [0019] to [0026] of JP2016-027363A, paragraphs [0041] to [0057] of WO2012/081680A1, paragraphs [0029] to [0040] of WO2018/179370A1, and paragraphs [0012] to [0032] of JP2019-101405A, the contents of these publications are incorporated in the present specification.

[Resin Composition Layer]

The resin composition layer according to the embodiment of the present invention contains a resin and at least one compound selected from the group consisting of the block copolymer and the compound (1).

An aspect of the resin composition layer may be, for example, a photosensitive resin composition layer, a thermoplastic resin composition layer, a coloration resin composition layer, and/or a water-soluble resin composition layer, which will be described later.

Hereinafter, components that can be contained in each resin composition layer in each aspect will be described.

It is noted that a component described as a component of a resin composition layer of a certain aspect is not intended to be allowed to be contained only in a case where the resin composition layer is the aspect and it can be used as a component of a resin composition layer of another aspect. For example, a component described as a component of the photosensitive resin composition layer may be used as a component other than the photosensitive resin composition layer.

<Resin>

The resin composition layer contains a resin.

The resin is a component different from a block copolymer described later.

The properties and/or characteristics of the resin are not limited, and the resin can be appropriately selected depending on the use application of the resin composition layer. Details of the resin will be described later according to each form of the resin composition layer.

<Block Copolymer>

The block copolymer contains a block (a block segment) consisting of a constitutional unit X having a group represented by Formula (A) or a group represented by Formula (B), and a block (a block segment) consisting of a constitutional unit Y having a poly(oxyalkylene) group.

The block copolymer is a polymer having a molecular structure in which a plurality of kinds of blocks are linked, and each block is a chain formed by linking constitutional units. The block structure of the block copolymer is not particularly limited, and examples thereof include block structures a to e represented by Formulae (a) to (e), respectively.

Formulae (a) (A)-(B)

In Formula (a), A represents a block consisting of the constitutional unit X, and B represents a block consisting of the constitutional unit Y The block structure represented by Formula (a) is a block structure (an A-B type) in which a block consisting of the constitutional unit X and a block consisting of the constitutional unit Y are linked.

Formulae (b) (B)-(A)-(B)

In Formula (b), A represents a block consisting of the constitutional unit X, and B represents a block consisting of the constitutional unit Y The block structure b represented by Formula (b) is a block structure (a B-A-B type) in which a block consisting of the constitutional unit Y is linked to both end portions of a block consisting of the constitutional unit X.

Formula (c) (B)-(A)-(C)

In Formula (c), A represents a block consisting of the constitutional unit X, B represents a block consisting of the constitutional unit Y, and C represents a block consisting of a constitutional unit different from the constitutional unit X and the constitutional unit Y The block structure c represented by Expression (c) is a block structure (a B-A-C type) in which a block consisting of the constitutional unit Y, a block consisting of the constitutional unit X, and a block consisting of a constitutional unit different from the constitutional unit X and the constitutional unit Y are linked in this order.

Formula (d) (B)-(A)-(C)-(D)

In Formula (d), A represents a block consisting of the constitutional unit X, B represents a block consisting of the constitutional unit Y, C represents a block consisting of a first constitutional unit different from the constitutional unit X and the constitutional unit Y, and D represents a block consisting of a second constitutional unit different from the constitutional unit X, the constitutional unit Y, and the first constitutional unit.

The block structure d represented by Expression (d) represents a block structure (a B-A-C-D type) in which a block consisting of the constitutional unit Y, a block consisting of the constitutional unit X, a block consisting of the first constitutional unit different from the constitutional unit X and the constitutional unit Y, and a block consisting of the second constitutional unit different from the constitutional unit X, the constitutional unit Y, and the first constitutional unit are linked in this order.

Formula (e) (A)-(B)-(A)-(B)

In Formula (e), A represents a block consisting of the constitutional unit X, and B represents a block consisting of the constitutional unit Y.

The block structure e represented by Formula (e) is a block structure in which a block consisting of the constitutional unit X and a block consisting of the constitutional unit Y are alternately linked a plurality of times.

Among the above, the block structure is preferably the block structures a to c, more preferably the block structure a or c, and still more preferably the block structure a.

From the viewpoint of solubility, the number of kinds of blocks included in the block structure is 2 or more, preferably 2 to 10, more preferably 2 to 5, still more preferably 2 to 3, and particularly preferably 2.

(Constitutional Unit X)

The constitutional unit X has a group represented by Formula (A) or a group represented by Formula (B).

Among the above, it is preferable that the constitutional unit X has a group represented by Formula (A) from the viewpoint that the effect of the present invention is more excellent.

*—(CH₂)ₘ—(CF₂)ₙ—CF₃ Formula (A)

In Formula (A), m and n each independently represent an integer of 1 to 3.

m is preferably an integer of 2 or 3 and more preferably 2.

n is preferably an integer of 2 or 3 and more preferably 3.

* represents a bonding position.

The number of groups represented by Formula (A) contained in the constitutional unit X is preferably 1 to 3 and more preferably 1.

*—Li—CH(CF₃)—CF₃ Formula (B)

In Formula (B), L¹ represents an oxygen atom or an alkylene group.

The alkylene group represented by L¹ may be linear or branched.

The alkylene group represented by L¹ preferably has 1 to 10 carbon atoms, more preferably 1 to 6 carbon atoms, still more preferably 1 to 3 carbon atoms, and particularly preferably 1 or 2 carbon atoms.

The alkylene group represented by L¹ may have a substituent. The substituent is not particularly limited, and examples thereof include the substituents exemplified in the substituent group T.

L¹ is preferably an oxygen atom or an alkylene group having 1 to 2 carbon atoms, and it is more preferably an oxygen atom.

* represents a bonding position.

The number of groups represented by Formula (B) contained in the structural unit X is preferably 1 to 3 and more preferably 1.

The structural unit X is preferably a structural unit represented by Formula (C).

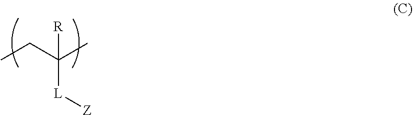

In Formula (C), R represents a hydrogen atom or a substituent. The substituent represented by R is not particularly limited, and examples thereof include the substituents exemplified in the substituent group T, where an alkyl group having 1 to 6 carbon atoms is preferable.

L represents a single bond or a divalent linking group. Examples of the divalent linking group include, —O—, —CO—, —S—, —SO₂—, —NR^{X}— (R^{X} represents a hydrogen atom or a substituent), an alkylene group, an alkenylene group, an alkynylene group, an aromatic ring group, an alicyclic group, and a group obtained by combining these (for example, —CO—O—, a —CO—O-alkylene group, or the like). Examples of the substituent represented by R^{X} include the substituents exemplified in the substituent group T, where an alkyl group having 1 to 2 carbon atoms is preferable.

The alkylene group, the alkenylene group, the alkynylene group, the aromatic ring group, and the alicyclic group may further have a substituent. Examples of the substituent include the substituents exemplified in the substituent group T. Among them, the substituent is preferably a halogen atom and more preferably a fluorine atom.

The alkylene group, the alkenylene group, and the alkynylene group may be linear or branched.

In addition, the alkylene group preferably has 1 to 20 carbon atoms, more preferably 1 to 10 carbon atoms, and still more preferably 1 to 5 carbon atoms.

In addition, the alkenylene group and the alkynylene group preferably have 2 to 20 carbon atoms, more preferably 2 to 10 carbon atoms, and still more preferably 2 to 5 carbon atoms.

Z represents a group represented by Formula (A) or a group represented by Formula (B).

The group represented by Formula (A) and the group represented by Formula (B) have the same meaning as the group represented by Formula (A) and the group represented by Formula (B), respectively, which are contained in the above-described block copolymer, and the same applies to the suitable range thereof.

One kind of the constitutional unit X may be used alone, or two or more kinds thereof may be used.

The lower limit value of the content of the constitutional unit X is more than 0% by mole, and it is preferably 1% by mole or more, more preferably 10% by mole or more, still more preferably 30% by mole or more, and particularly preferably 40% by mole or more, with respect to the number of moles of all constitutional units of the block copolymer. In addition, the upper limit value thereof is less than 100% by mole, and it is preferably 90% by mole or less, more preferably 80% by mole or less, and still more preferably 60% by mole or less.

(Constitutional Unit Y)

The constitutional unit Y has a poly(oxyalkylene) group.

The structural unit Y is not particularly limited; however, it preferably has a group represented by Formula (PAL1).

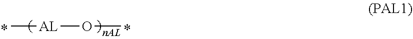

In Formula (PAL1), AL represents an alkylene group.

The alkylene group may be linear or branched. The alkylene group represented by AL preferably has 1 to 10 carbon atoms, more preferably 1 to 6 carbon atoms, still more preferably 2 to 4 carbon atoms, and particularly preferably 2 or 3 carbon atoms.

nAL represents a number of 2 or more, where it is preferably 2 to 100, more preferably 4 to 20, still preferably 4 to 15, and particularly preferably 4 to 12.

The nAL pieces of AL's may be the same or different from each other, and they preferably represent the same structure.

Further, the alkylene group represented by AL may have a substituent. The substituent is not particularly limited, and examples thereof include the substituents exemplified in the substituent group T.

Among them, AL is preferably —CH₂CH₂—, —CH₂CH₂CH₂—, —CH(CH₃)CH₂—, or —CH(CH₂CH₃)CH₂—, and it is more preferably —CH(CH₃)CH₂— or —CH₂CH₂—.

* represents a bonding position.

The constitutional unit Y preferably has a poly(oxyalkylene) group in the side chain, more preferably has a group represented by Formula (PAL1) in the side chain, and is still more preferably a constitutional unit derived from a monomer represented by Formula (PAL2).

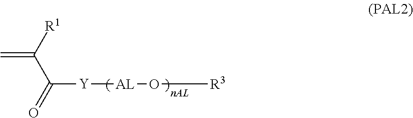

In Formula (PAL2), R¹ represents a hydrogen atom or a methyl group.

R¹ is preferably a hydrogen atom.

Y represents an oxygen atom, a sulfur atom, or —N(R²)—.

R² represents a hydrogen atom or an alkyl group having 1 to 4 carbon atoms.

The alkyl group having 1 to 4 carbon atoms, which is represented by R², may be either linear, branched, or cyclic.

R² is preferably a hydrogen atom or an alkyl group having 1 or 2 carbon atoms and more preferably an alkyl group having 1 or 2 carbon atoms.

Y is preferably an oxygen atom or a sulfur atom and more preferably an oxygen atom.

R³ represents a hydrogen atom or a substituent.

The substituent represented by R³ is not particularly limited, and examples thereof include the substituents exemplified in the substituent group T, where an alkyl group having 1 to 6 carbon atoms is preferable.

R³ is preferably a hydrogen atom.

AL and nAL in Formula (PAL2) have the same meanings as AL and nAL in Formula (PAL1) described above, respectively, and the same applies to the suitable aspect thereof.

One kind of the constitutional unit Y may be used alone, or two or more kinds thereof may be used.

The lower limit value of the content of the constitutional unit Y is more than 0% by mole, and it is preferably 1% by mole or more, more preferably 10% by mole or more, still more preferably 30% by mole or more, and particularly preferably 40% by mole or more, with respect to the number of moles of all constitutional units of the block copolymer. In addition, the upper limit value thereof is less than 100% by mole, and it is preferably 90% by mole or less and more preferably 60% by mole or less.

(Another Structural Unit)

The block copolymer may have another constitutional unit in addition to the structural unit X and the structural unit Y.

The other constitutional unit is preferably a constitutional unit selected from the group consisting of a constitutional unit derived from a (meth)acrylic acid ester and a constitutional unit derived from (meth)acrylic acid.

Examples of the (meth)acrylic acid ester include a (meth)acrylic acid alkyl ester having 1 to 18 carbon atoms in an alkyl group. Specific examples thereof include methyl (meth)acrylate, ethyl (meth)acrylate, n-butyl (meth)acrylate, isobutyl (meth)acrylate, 2-ethylhexyl (meth)acrylate, lauryl (meth)acrylate, and stearyl (meth)acrylate. Among them, lauryl (meth)acrylate is preferable.

One kind of the other constitutional unit may be used alone, or two or more kinds thereof may be used.

The lower limit value of the content of the other constitutional unit is preferably 1% by mole or more, more preferably 10% by mole or more, and still more preferably 20% by mole or more, with respect to the number of moles of all constitutional units of the block copolymer. In addition, the upper limit value thereof is preferably 90% by mole or less, more preferably 60% by mole or less, and still more preferably 40% by mole or less.

Hereinafter, specific examples of the block copolymer will be shown; however, the block copolymer in the present invention is not limited thereto.

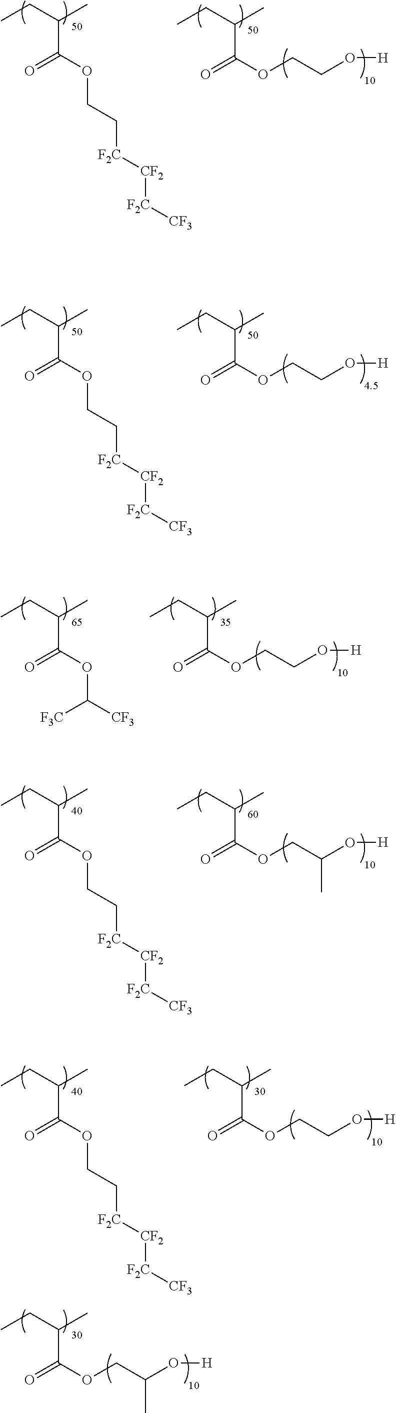

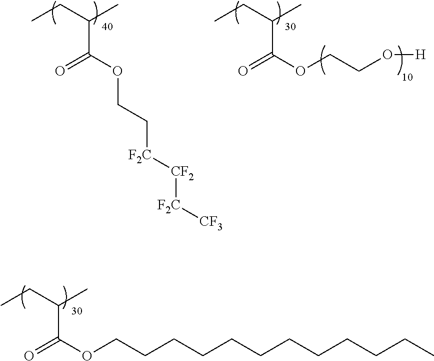

The lower limit value of the weight-average molecular weight of the block copolymer is preferably 1,000 or more, more preferably 1,500 or more, still more preferably 2,000 or more, and particularly preferably 5,000 or more. Further, the upper limit value thereof is preferably 100,000 or less, more preferably 50,000 or less, and still more preferably 20,000 or less.

The number-average molecular weight (Mn) of the block copolymer is preferably 1,000 to 40,000, more preferably 2,000 to 20,000, still more preferably 5,000 to 15,000, and particularly preferably 7,000 to 12,000.

The dispersivity (Mw/Mn) of the block copolymer is preferably 1.00 to 12.00, more preferably 1.00 to 11.00, still more preferably 1.00 to 10.00, particularly preferably 1.00 to 5.00, and most preferably 1.00 to 2.00.

One kind of block copolymer may be used alone, or two or more kinds thereof may be used.

The content of the block copolymer is preferably 0.001% to 10.00% by mass, more preferably 0.01% to 3.00% by mass, still more preferably 0.02% to 1.00% by mass, and particularly preferably 0.10% to 1.00% by mass, with respect to the total mass of the resin composition layer.

The polymerization method for the block copolymer is not particularly limited, and examples thereof include a known polymerization method.

Examples of the polymerization method for the block copolymer include living radical polymerization, living cationic polymerization, and living anionic polymerization.

Examples of the living radical polymerization, the living cationic polymerization, and the living anionic polymerization include “Guidebook of Precision Radical Polymerization (Sigma-Aldrich Co., LLC)” (URL: http://www.sigmaaldrich.com/japan/materialscience/polymer-science/crp-guide.html), “Synthesis of Polymers (I)—Radical Polymerization, Cationic Polymerization, and Anionic Polymerization”, Kodansha Ltd., 2010, p 60, p 105-108, p 249-259, and p 381-386, written by Tsuyoshi Endo, Mitsuo Sawamoto et. al., and paragraphs [0067] to [0074] of WO2017/014145A, the contents of which are incorporated in the present specification.

<Compound (1)>

The compound (1) is a compound represented by Formula (1).

Z-L²-W Formula (1)

In Formula (1), Z represents a group represented by Formula (A) or a group represented by Formula (B).

The group represented by Formula (A) and the group represented by Formula (B) have the same meaning as the group represented by Formula (A) and the group represented by Formula (B), respectively, which are contained in the above-described block copolymer, and the same applies to the suitable range thereof.

L² represents a single bond or a divalent linking group, and Examples of the divalent linking group represented by L² include, —O—, —CO—, —S—, —SO₂—, —NR^{X}— (R^{X} represents a hydrogen atom or a substituent), an alkylene group, an alkenylene group, an alkynylene group, an aromatic ring group, an alicyclic group, and a group obtained by combining these. Examples of the substituent represented by R^{X} include the substituents exemplified in the substituent group T, where an alkyl group having 1 to 2 carbon atoms is preferable.

The alkylene group, the alkenylene group, the alkynylene group, the aromatic ring group, and the alicyclic group may further have a substituent. Examples of the substituent include the substituents exemplified in the substituent group T. Among them, the substituent is preferably a halogen atom and more preferably a fluorine atom.

The alkylene group, the alkenylene group, and the alkynylene group may be linear or branched.

In addition, the alkylene group preferably has 1 to 20 carbon atoms, more preferably 1 to 10 carbon atoms, and still more preferably 1 to 5 carbon atoms.

In addition, the alkenylene group and the alkynylene group preferably have 2 to 20 carbon atoms, more preferably 2 to 10 carbon atoms, and still more preferably 2 to 5 carbon atoms.

Among the above, L² is preferably —O— n a case where Z is a group represented by Formula (A), and it is preferably a single bond in a case where Z is a group represented by Formula (B).

W represents a group including a poly(oxyalkylene) group.

W is not particularly limited as long as it is a group including a poly(oxyalkylene) group.

Among the above, W is preferably a monovalent organic group including a poly(oxyalkylene) group, more preferably a group including a group represented by Formula (PAL1), and still more preferably a group represented by Formula (2).

*-(AL-O—)_{nAL}—R³ Formula (2)

The definitions of AL, R³, and nAL in Formula (2) are the same as the definitions of the respective groups in Formula (PAL2) described above. * represents a bonding position.

Hereinafter, specific examples of the compound (1) will be shown; however, the compound (1) in the present invention is not limited thereto.

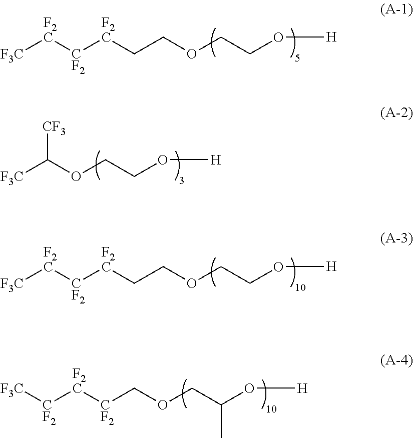

The low limit of the molecular weight of the compound (1) is preferably 100 or more and more preferably 500 or more. The upper limit of the molecular weight of the compound (1) is preferably 3,000 or less and more preferably 2,000 or less.

One kind of the compound (1) may be used alone, or two or more kinds thereof may be used.

The content of the compound (1) is preferably 0.001% to 10.00% by mass, more preferably 0.01% to 3.00% by mass, and still more preferably 0.02% to 1.00% by mass, with respect to the total mass of the resin composition layer.

<Other Components>

The resin composition layer may contain other components in addition to the resin, the block copolymer, and the compound (1).

Examples of the other components include components such as a polymerizable compound, a polymerization initiator, a coloring agent, a thermal crosslinking compound, an additive, a plasticizer, a sensitizing agent, a pigment, and a compound that generates an acid, a base, or a radical due to light.

Details of the other components will be described later in each form of the resin composition layer.

[Photosensitive Resin Composition Layer]

The resin composition layer may be a photosensitive resin composition layer.

The photosensitive resin composition layer is transferred on a transfer target and then subjected to exposure and development, whereby a pattern is formed on the transfer target.

The photosensitive resin composition layer may be a positive tone layer or a negative tone layer.

The positive tone photosensitive composition layer is a photosensitive composition layer in which the solubility of the exposed portion with respect to a developer becomes high upon exposure.

The negative tone photosensitive composition layer is a photosensitive composition layer in which the solubility of the exposed portion with respect to a developer decreases upon exposure.

Among the above, it is preferable to use a negative tone photosensitive composition layer. In a case where the photosensitive composition layer is a negative tone photosensitive composition layer, the pattern to be formed corresponds to a protective film.

It is preferable that the photosensitive resin composition layer further contains an alkali-soluble resin and a polymerizable compound in addition to the above-described block copolymer and compound (1).

In addition, it is also preferable that in addition to the above-described block copolymer and compound (1), the photosensitive resin composition layer further contains a resin having a constitutional unit having an acid group protected by an acid-decomposable group described later, and a photoacid generator described later.

The transfer film having the photosensitive resin composition layer may be used to obtain a wiring pattern or the like included in a touch panel.

In a display device (an organic electroluminescence (EL) display device, a liquid crystal display device, or the like) that includes a touch panel such as a capacitive input device, an electrode pattern corresponding to a sensor of a visual recognition part and a conductive layer pattern of a wire or the like of a peripheral wiring portion or a lead-out wiring portion are provided inside the touch panel.

Generally, a method of providing a photosensitive resin composition layer on a substrate using a transfer film or the like, subjecting the photosensitive resin composition layer to exposure through a mask having a desired pattern, and then carrying out development is widely employed for forming a patterned layer.

Hereinafter, components that can be contained in each photosensitive resin composition layer will be described.

<Alkali-Soluble Resin>

The photosensitive resin composition layer may contain an alkali-soluble resin (hereinafter, also referred to as a “polymer P”). The alkali-soluble resin corresponds to the resin contained in the resin composition layer described above.

The acid value of the polymer P is preferably 220 mgKOH/g or less, more preferably less than 200 mgKOH/g, and still more preferably less than 190 mgKOH/g, from the viewpoint of the more excellent resolution by suppressing the swelling of the photosensitive resin composition layer due to the developer.

The lower limit of the acid value of the polymer P is not particularly limited; however, it is preferably 60 mgKOH/g or more, more preferably 80 mgKOH/g or more, and still more preferably 90 mgKOH/g or more, from the viewpoint of the more excellent developability.

It is noted that the acid value is the mass [mg] of potassium hydroxide required to neutralize 1 g of the sample, and the unit thereof is described as mgKOH/g in the present specification. The acid value can be calculated, for example, from the average content of acid groups in the compound.

The acid value of the polymer P may be adjusted according to the kind of the constitutional unit that constitutes the polymer P and the content of the constitutional unit including an acid group.

The weight-average molecular weight of the polymer P is preferably 5,000 to 500,000. A case where the weight-average molecular weight is 500,000 or less is preferable from the viewpoint of improving resolution and developability. The weight-average molecular weight is more preferably 100,000 or less and still more preferably 60,000 or less. On the other hand, a case where the weight-average molecular weight is 5,000 or more is preferable from the viewpoint of controlling property of the developed aggregate and the property of the unexposed film such as edge fuse property and cut chip property in a case of forming a laminate having a photosensitive resin composition layer. The lower limit of the weight-average molecular weight is more preferably 10,000 or more, still more preferably 20,000 or more, and particularly preferably 30,000 or more. The edge fuse property refers to a degree of ease with which the photosensitive resin composition layer protrudes from the edge surface of the roll in a case of being wound backward in a roll shape as a laminate having the photosensitive resin composition layer. The cut chip property refers to a degree of ease of chip flying in a case where the unexposed film is cut with a cutter. In a case where this chip adheres to the upper surface or the like of a laminate having the photosensitive resin composition layer, it is transferred to the mask in the later exposure step or the like, which causes a defective product. The dispersivity of the polymer P is preferably 1.0 to 6.0, more preferably 1.0 to 5.0, still more preferably 1.0 to 4.0, and particularly preferably 1.0 to 3.0.

In the photosensitive resin composition layer, the polymer P preferably contains a constitutional unit based on a monomer having an aromatic hydrocarbon group from the viewpoint of suppressing line width thickening and deterioration of resolution in a case where the focal position has deviated during exposure. Examples of such an aromatic hydrocarbon group include a substituted or unsubstituted phenyl group and a substituted or unsubstituted aralkyl group.

The content of the constitutional unit derived from a monomer having an aromatic hydrocarbon group in the polymer P is preferably 20.0% by mass or more and more preferably 30.0% by mass or more with respect to the total mass of the polymer P. The upper limit thereof is not particularly limited; however, it is preferably 95.0% by mass or less and more preferably 85.0% by mass or less. In a case where a plurality of kinds of the polymer P are contained, the average value of the contents of the constitutional units derived from a monomer having an aromatic hydrocarbon group is preferably within the above range.

Examples of the monomer having an aromatic hydrocarbon group include a monomer having an aralkyl group, styrene, and a polymerizable styrene derivative (for example, methyl styrene, vinyl toluene, tert-butoxy styrene, acetoxy styrene, 4-vinylbenzoic acid, a styrene dimer, or a styrene trimer). Among them, a monomer having an aralkyl group or styrene is preferable. In one aspect, in a case where the monomer component having an aromatic hydrocarbon group in the polymer P is styrene, the content of the constitutional unit derived from the styrene is preferably 20.0% to 70.0% by mass, more preferably 25.0% to 65.0% by mass, still more preferably 30.0% to 60.0% by mass, and particularly preferably 30.0% to 55.0% by mass, with respect to the total mass of the polymer P.

Examples of the aralkyl group include a substituted or unsubstituted phenylalkyl group (excluding a benzyl group) and a substituted or unsubstituted benzyl group, where a substituted or unsubstituted benzyl group is preferable.

Examples of the monomer having a phenylalkyl group include phenylethyl (meth)acrylate.

Examples of the monomer having a benzyl group include (meth)acrylate having a benzyl group, for example, benzyl (meth)acrylate or chlorobenzyl (meth)acrylate; and a vinyl monomer having a benzyl group, for example, vinylbenzyl chloride or vinylbenzyl alcohol. Among them, benzyl (meth)acrylate is preferable. In one aspect, in a case where the monomer having an aromatic hydrocarbon group in the polymer P is derived from benzyl (meth)acrylate, the content of the constitutional unit derived from the benzyl (meth)acrylate is preferably 50.0% to 95.0% by mass, more preferably 60.0% to 90.0% by mass, still more preferably 70.0% to 90.0% by mass, and particularly preferably 75.0% to 90.0% by mass, with respect to the total mass of the polymer P.

The polymer P containing a constitutional unit derived from a monomer having an aromatic hydrocarbon group is preferably obtained by polymerizing a monomer having an aromatic hydrocarbon group with at least one kind of the first monomer described later and/or at least one kind of the second monomer described later.

The polymer P containing no constitutional unit derived from a monomer having an aromatic hydrocarbon group is preferably obtained by polymerizing at least one kind of the first monomers described later, and more preferably obtained by copolymerizing at least one kind of the first monomer and at least one kind of the second monomer described later.

The first monomer is a monomer having a carboxy group in the molecule.

Examples of the first monomer include (meth)acrylic acid, fumaric acid, cinnamic acid, crotonic acid, itaconic acid, 4-vinylbenzoic acid, a maleic acid anhydride, and a maleic acid semi-ester. Among them, (meth)acrylic acid is preferable.

The content of the constitutional unit derived from the first monomer in the polymer P is preferably 5% to 50% by mass, more preferably 10% to 40% by mass, and still more preferably 15% to 30% by mass, with respect to the total mass of the polymer P.

It is preferable that the content is 5% by mass or more from the viewpoint of exhibiting good developability and the viewpoint of controlling the edge fuse property. It is preferable that the content is 50% by mass or less from the viewpoints of the high resolution of the resist pattern and the viewpoint of the skirt shape, as well as the viewpoint of the chemical resistance of the resist pattern.

The second monomer is a monomer that is non-acidic and has at least one polymerizable unsaturated group in the molecule.

Examples of the second monomer include (meth)acrylate such as methyl (meth)acrylate, ethyl (meth)acrylate, n-propyl (meth)acrylate, isopropyl (meth)acrylate, n-butyl (meth)acrylate, isobutyl (meth)acrylate, tert-butyl (meth)acrylate, 2-hydroxyethyl (meth)acrylate, 2-hydroxypropyl (meth)acrylate, cyclohexyl (meth)acrylate, 2-ethylhexyl (meth)acrylate; esters of vinyl alcohols such as vinyl acetate; and (meth)acrylonitriles. Among them, methyl (meth)acrylate, 2-ethylhexyl (meth)acrylate, or n-butyl (meth)acrylate is preferable, and methyl (meth)acrylate is more preferable.

The content of the constitutional unit derived from the second monomer in the polymer P is preferably 5% to 60% by mass, more preferably 15% to 50% by mass, and still more preferably 17% to 45% by mass, with respect to the total mass of the polymer P.

A case where the polymer P contains a constitutional unit derived from a monomer having an aralkyl group and/or a constitutional unit derived from styrene is preferable from the viewpoint of suppressing line width thickening and deterioration of resolution in a case where the focal position has deviated during exposure. For example, a copolymer containing a constitutional unit derived from methacrylic acid, a constitutional unit derived from benzyl methacrylate, and a constitutional unit derived from styrene, a copolymer containing a constitutional unit derived from methacrylic acid, a constitutional unit derived from methyl methacrylate, a constitutional unit derived from benzyl methacrylate, and a constitutional unit derived from styrene, or the like is preferable.

In one aspect, the polymer P is preferably a polymer which contains 25% to 55% by mass of a constitutional unit derived from a monomer having an aromatic hydrocarbon group, 20% to 35% by mass of a constitutional unit derived from the first monomer, and 15% to 45% by mass of a constitutional unit derived from the second monomer. In addition, in another aspect, it is preferably a polymer which contains 70% to 90% by mass of a constitutional unit derived from a monomer having an aromatic hydrocarbon group and 10% to 25% by mass of a constitutional unit derived from the first monomer.

The polymer P may have a branched structure and/or an alicyclic structure in the side chain. In addition, the polymer P may have a linear structure in the side chain. In a case where a monomer containing a group having a branched structure in the side chain or a monomer containing a group having an alicyclic structure in the side chain is used, it is possible to introduce a branched structure and/or an alicyclic structure into the side chain of polymer P. The group having an alicyclic structure may be a monocyclic ring or a polycyclic ring.

Specific examples of the monomer containing a group having a branched structure in the side chain include i-propyl (meth)acrylate, i-butyl (meth)acrylate, s-butyl (meth)acrylate, t-butyl (meth)acrylate, i-amyl (meth)acrylate, t-amyl (meth)acrylate, sec-iso-amyl (meth)acrylate, 2-octyl (meth)acrylate, 3-octyl (meth)acrylate, and t-octyl (meth)acrylate. Among these, i-propyl (meth)acrylate, i-butyl (meth)acrylate, or t-butyl methacrylate is preferable, and i-propyl methacrylate or t-butyl methacrylate is more preferable.

Examples of the alicyclic structure include a monocyclic alicyclic structure and a polycyclic alicyclic structure, where a polycyclic alicyclic structure is preferable.

Specific examples of the monomer having an alicyclic structure in the side chain include an (meth)acrylate having an alicyclic hydrocarbon group having 5 to 20 carbon atoms. More specific examples thereof include (bicyclo[2.2.1]heptyl-2) (meth)acrylate, 1-adamantyl (meth)acrylate, 2-adamantyl (meth)acrylate, 3-methyl-1-adamantyl (meth)acrylate, 3,5-dimethyl-1-adamantyl (meth)acrylate, 3-ethyladamantyl (meth)acrylate, 3-methyl-5-ethyl-1-adamantyl (meth)acrylate, 3,5,8-triethyl-1-adamantyl (meth)acrylate, 3,5-dimethyl-8-ethyl-1-adamantyl (meth)acrylate, 2-methyl-2-adamantyl (meth)acrylate, 2-ethyl-2-adamantyl (meth)acrylate, 3-hydroxy-i-adamantyl (meth)acrylate, octahydro-4,7-menthanoinden-5-yl (meth)acrylate, octahydro-4,7-menthanoinden-1-ylmethyl (meth)acrylate, 1-menthyl (meth)acrylate, tricyclodecane (meth)acrylate, 3-hydroxy-2,6,6-trimethyl-bicyclo[3.1.1]heptyl (meth)acrylate, 3,7,7-trimethyl-4-hydroxy-bicyclo[4.1.0]heptyl (meth)acrylate, (nor)bornyl (meth)acrylate, isobornyl (meth)acrylate, fenchyl (meth)acrylate, 2,2,5-trimethylcyclohexyl (meth)acrylate, and cyclohexyl (meth)acrylate. Among them, cyclohexyl (meth)acrylate (nor)bornyl (meth)acrylate, isobornyl (meth)acrylate, 1-adamantyl (meth)acrylate, 2-adamantyl (meth)acrylate, fenchyl (meth)acrylate, 1-menthyl (meth)acrylate, or tricyclodecane (meth)acrylate is preferable, and cyclohexyl (meth)acrylate, (nor)bornyl (meth)acrylate, isobornyl (meth)acrylate, 2-adamantyl (meth)acrylate, or tricyclodecane (meth)acrylate is more preferable.

One kind of the polymer P may be used alone, or two or more kinds thereof may be used.

In a case where two or more kinds are used, it is preferable that two kinds of the polymer P containing a constitutional unit derived from a monomer having an aromatic hydrocarbon group are mixed and used, or it is preferable that the polymer P containing a constitutional unit derived from a monomer having an aromatic hydrocarbon group and the polymer P containing no constitutional unit derived from a monomer having an aromatic hydrocarbon group are mixed and used. In the latter case, the content of the polymer P containing a constitutional unit derived from a monomer having an aromatic hydrocarbon group is preferably 50% by mass or more, more preferably 70% by mass or more, still preferably 80% by mass or more, and particularly preferably 90% by mass or more, with respect to the total amount of the polymer P. The upper limit thereof is not particularly limited, and it is preferably 100% by mass or less.

The synthesis of the polymer P is preferably carried out by adding an appropriate amount of a radical polymerization initiator such as benzoyl peroxide or azoisobutyronitrile to a solution obtained by diluting the one or more monomers described above with a solvent such as acetone, methyl ethyl ketone, or isopropanol, and then stirring and heating the resultant mixture. In some cases, the synthesis is carried out while a part of the mixture is added dropwise to the reaction solution. After completion of the reaction, a solvent may be further added to adjust the concentration to a desired level. As the synthesis means, bulk polymerization, suspension polymerization, or emulsion polymerization may be used in addition to the solution polymerization.

The glass transition temperature Tg of the polymer P is preferably 30° C. to 135° C. In a case where the polymer P having a Tg of 135° C. or lower is used, it is possible to suppress line width thickening and deterioration of resolution in a case where the focal position has deviated during exposure. From this viewpoint, the Tg of the polymer P is more preferably 130° C. or lower, still more preferably 120° C. or lower, and particularly preferably 110° C. or lower. Further, it is preferable to use the polymer P having a Tg of 30° C. or higher from the viewpoint of improving the edge fuse resistance. From this viewpoint, the Tg of the polymer P is more preferably 40° C. or higher, still more preferably 50° C. or higher, particularly preferably 60° C. or higher, and most preferably 70° C. or higher.

The photosensitive resin composition layer may contain a resin other than those described above.

Examples of the other resin include an acrylic resin, a styrene-acrylic copolymer, a polyurethane resin, polyvinyl alcohol, polyvinyl formal, a polyamide resin, a polyester resin, an epoxy resin, a polyacetal resin, a polyhydroxystyrene resin, a polyimide resin, a polybenzoxazole resin, a polysiloxane resin, polyethyleneimine, polyallylamine, and polyalkylene glycol.

As the polymer P, an alkali-soluble resin described in the description of the thermoplastic resin composition layer described later may be used.

The content of the polymer P is preferably 10.00% to 90.00% by mass, more preferably 20.00% to 80.00% by mass, still more preferably 20.00% to 70.00% by mass, and particularly preferably 20.00% to 60.00% by mass, with respect to the total mass of the photosensitive resin composition layer. It is preferable that the content of the polymer P is 90.00% by mass or less from the viewpoint of controlling the development time. On the other hand, it is preferable that the content of the polymer P is 10.00% by mass or more from the viewpoint of improving the edge fuse resistance.

<Resin Having Constitutional Unit Having Acid Group Protected by Acid-Decomposable Group>

In a case where the photosensitive resin composition layer is a positive tone photosensitive resin composition layer, the photosensitive resin composition layer preferably contains a resin having an acid group protected by an acid-decomposable group. The resin having an acid group protected by an acid-decomposable group corresponds to the resin contained in the above-described resin composition layer.

The resin having an acid group protected by an acid-decomposable group is preferably a polymer (hereinafter, also referred to as a “polymer A”) having a constitutional unit (hereinafter, also referred to as a “constitutional unit A”) having an acid group protected by an acid-decomposable group.

In addition, the positive tone photosensitive resin composition layer may contain another polymer in addition to the polymer having the constitutional unit A. In the present specification, the polymer having the constitutional unit A and another polymer are collectively referred to as a “polymer component”.

In the polymer A, the constitutional unit A having an acid group protected by an acid-decomposable group in the polymer A undergoes a deprotection reaction to become an acid group under the action of a catalytic amount of an acidic substance which is generated upon exposure, which enables the development with a developer

Hereinafter, the preferred aspect of the constitutional unit A will be described.

The photosensitive resin composition layer may further contain a polymer other than the polymer having a constitutional unit having an acid group protected by an acid-decomposable group.

In addition, it is preferable that all the polymers contained in the polymer component are polymers having at least a constitutional unit having an acid group described later.

In addition, the photosensitive resin composition layer may further contain a polymer other than these. The polymer component in the present specification is not particularly limited, and it is intended to include another polymer which is added as necessary.

The polymer A is preferably an addition polymerization type resin and more preferably a polymer having a constitutional unit derived from (meth)acrylic acid or an ester thereof. It is noted that a constitutional unit other than the constitutional unit derived from (meth)acrylic acid or an ester thereof may have, for example, a constitutional unit derived from a constitutional unit derived from styrene, and a constitutional unit derived from a vinyl compound.

From the viewpoint of solubility in a developer and transferability, the photosensitive resin composition layer preferably contains, as the polymer component, a polymer having a constitutional unit A1 represented by Formula (A1) described later as the constitutional unit A, more preferably contains, as the polymer component, the polymer A having a constitutional unit A1 represented by Formula (A1) described later as the constitutional unit A and having a glass transition temperature of 90° C. or lower, and still more preferably contains, as the polymer component, the polymer A having a constitutional unit A1 represented by Formula (A1) described later as the constitutional unit A, having a constitutional unit B having an acid group described later, and having a glass transition temperature of 90° C. or lower.

(Constitutional Unit A)

The constitutional unit A is a constitutional unit having an acid group protected by an acid-decomposable group.

Examples of the acid group protected by an acid-decomposable group include known acid groups and acid-decomposable groups.

Examples of the acid group include a carboxy group and a phenolic hydroxyl group. In addition, examples of the acid group protected by an acid-decomposable group include a group that is relatively easily decomposed by an acid (for example, an acetal-based functional group such as an ester group protected by a group represented by Formula (A1), a tetrahydropyranyl ester group, or a tetrahydrofuranyl ester group), and a group that is relatively difficult to be decomposed by an acid (for example, a tertiary alkyl group such as a tert-butyl ester group or a tertiary alkyl carbonate group such as a tert-butyl carbonate group).

Among them, the acid-decomposable group is preferably a group having a structure protected by an acetal-based functional group.

The constitutional unit A is preferably constitutional units A1 to A4 described later, more preferably a constitutional unit A2 or A4, and still more preferably a constitutional unit A2.

—Constitutional Unit A1—

From the viewpoint of sensitivity and resolution, it is also preferable that the constitutional unit A having an acid group protected by an acid-decomposable group is the constitutional unit A1 represented by Formula (A1).

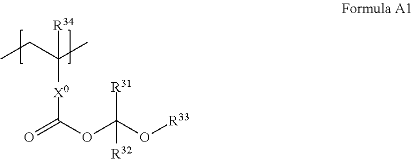

In Formula (A1), R³¹ and R³² each independently represent a hydrogen atom, an alkyl group, or an aryl group, and at least one of R³¹ or R³² represents an alkyl group or an aryl group.

In a case where R³¹ or R³² is an alkyl group, R³¹ and R³² are preferably an alkyl group having 1 to 10 carbon atoms. In a case where R³¹ or R³² is an aryl group, R³¹ and R³² are preferably a phenyl group. R³¹ and R³² are each preferably a hydrogen atom or an alkyl group having 1 to 4 carbon atoms.

R³³ represents an alkyl group or an aryl group, and R³¹ or R³² may be linked to R³³ to form a cyclic ether.

The number of ring members of the cyclic ether is not particularly limited; however, it is preferably 5 or 6 and more preferably 5.

R³³ is preferably an alkyl group having 1 to 10 carbon atoms and more preferably an alkyl group having 1 to 6 carbon atoms.

The alkyl group and the aryl group represented by R³¹ to R³³ may have a substituent. The substituent is not particularly limited, and examples thereof include the substituents exemplified in the substituent group T.

R³⁴ represents a hydrogen atom or a methyl group.

R³⁴ is preferably a hydrogen atom from the viewpoint that the Tg of the polymer A can be further decreased.

The content of the constitutional unit in which R³⁴ is a hydrogen atom is preferably 20% by mass or more with respect to the total amount of the constitutional unit A1 contained in the polymer A. The upper limit thereof is not particularly limited, and it is preferably 100% by mass or less.

It is noted that the content (the content proportion; in terms of mass ratio) of the constitutional unit in which R³⁴ is a hydrogen atom can be checked by the intensity ratio of the peak intensity calculated from the ¹³C-nuclear magnetic resonance spectrum (NMR) measurement by a conventional method.

X⁰ represents a single bond or an arylene group.

X⁰ is preferably a single bond.

The arylene group may have a substituent. The substituent is not particularly limited, and examples thereof include the substituents exemplified in the substituent group T.

—Constitutional Unit A2—

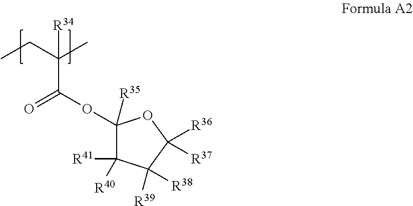

In Formula (A2), R³⁴ represents a hydrogen atom or a methyl group.

In Formula (A2), R³⁴ has the same meaning as R³⁴ in Formula (A1) described above, the same also applies to the suitable range thereof.

R³⁵ and R⁴¹ each independently represent a hydrogen atom or an alkyl group having 1 to 4 carbon atoms.

R³⁵ and R⁴¹ are preferably a hydrogen atom.

Specific examples of the constitutional units A1 and A2 will be shown.

In the following constitutional units, R³⁴ represents a hydrogen atom or a methyl group.

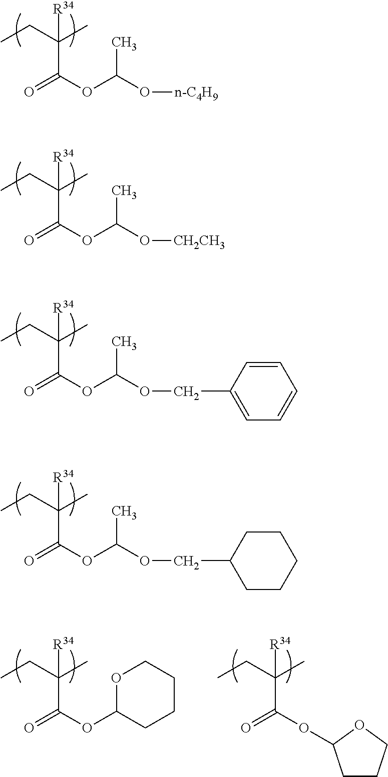

—Constitutional Unit A3—

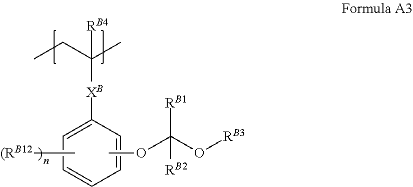

In Formula (A3), R^{B1} to R^{B4} respectively have the same meanings as R³¹ to R³⁴ in Formula (A1) described above, and the same applies to the suitable ranges thereof.

X^{B} represents a single bond or a divalent linking group.

Examples of the divalent linking group represented by X^{B} include an alkylene group, —C(═O)O—, —C(═O)NR^{N}—, —O—, and a combination thereof.

The alkylene group may have a linear structure, a branched structure, or a cyclic structure.

In addition, the alkylene group may have a substituent. The substituent is not particularly limited, and examples thereof include the substituents exemplified in the substituent group T.

The alkylene group preferably has 1 to 10 carbon atoms and more preferably 1 to 4 carbon atoms.

In a case where X^{B} includes —C(═O)O—, it is preferable that the carbon atom contained in —C(═O)O— and a carbon atom to which R^{B4} is bonded are directly bonded. In a case where X^{B} includes —C(═O)NR^{N}—, it is preferable that the carbon atom contained in —C(═O)NR^{N}— and a carbon atom to which R^{B4} is bonded are directly bonded.

R^{N} represents an alkyl group or a hydrogen atom, and an alkyl group or a hydrogen atom, having 1 to 4 carbon atoms, is preferable, and a hydrogen atom is more preferable.

Among the above, X^{B} is preferably a single bond.

It is preferable that a group containing R^{B1} to R^{B3} and X^{B} are bonded to each other at the para-position.

R^{B12} represents a substituent.

R^{B12} is preferably an alkyl group or a halogen atom.

The alkyl group preferably has 1 to 10 carbon atoms and more preferably 1 to 4 carbon atoms.

n represents an integer of 0 to 4.

n is preferably 0 or 1 and more preferably 0.

—Constitutional Unit A4—

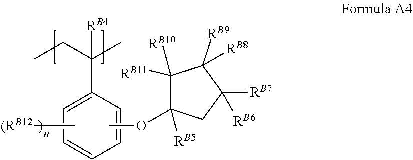

In Formula (A4), R^{B4} to R^{B11} respectively have the same meanings as R³⁴ to R⁴¹ in Formula (A2), and the same applies to the suitable ranges thereof.

In addition, R^{B12} and n in Formula (A4) respectively have the same meanings as R^{B12} and n in Formula (A3), and the same applies to the suitable ranges thereof.

Specific examples of the constitutional unit A4 include the following constitutional units. Here, R^{B4} represents a hydrogen atom or a methyl group.

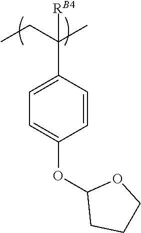

One kind of the constitutional unit A may be used alone, or two or more kinds thereof may be used.

The content of the constitutional unit A is preferably 20.0% by mass or more, more preferably 20.0% to 90.0% by mass, and still more preferably 30.0% to 70.0% by mass, with respect to the total mass of the polymer A.

In addition, the content of the monomer derived from the constitutional unit A is preferably 5.0% to 80.0% by mass, more preferably 10% to 80% by mass, and still more preferably 30% to 70% by mass, with respect to the total mass of the polymer A.

(Constitutional Unit B)

The polymer A may contain a constitutional unit B having an acid group.

The constitutional unit B is, for example, an acid group that is not protected by an acid-decomposable group, that is, a constitutional unit containing an acid group having no protective group. In a case where the polymer A contains the constitutional unit B, the sensitivity at the time of pattern formation is improved, and the polymer X is easily dissolved in an alkali developer in the development step after the pattern exposure, whereby the development time can be shortened.

Examples of the constitutional unit B include the constitutional unit contained in the alkali-soluble resin described above.

One kind of the constitutional unit B may be used alone, or two or more kinds thereof may be used.

The content of the constitutional unit B is preferably 0.1% to 20.0% by mass, more preferably 0.5% to 150.0% by mass, and still more preferably 1% to 10.0% by mass, with respect to the total mass of the polymer A.

(Another Constitutional Unit)

The polymer A may contain another constitutional unit (hereinafter, also referred to as a “constitutional unit C”) in addition to the constitutional units A to B described above.

Examples of the monomer that forms the constitutional unit C include styrenes, a (meth)acrylic acid alkyl ester, a (meth)acrylic acid cyclic alkyl ester, a (meth)acrylic acid aryl ester, an unsaturated dicarboxylic acid diester, a bicyclic unsaturated compound, a maleimide compound, an unsaturated aromatic compound, a conjugated diene compound, an unsaturated monocarboxylic acid, an unsaturated dicarboxylic acid, an unsaturated dicarboxylic acid anhydride, a compound having an aliphatic cyclic skeleton, and another unsaturated compound.

In a case of adjusting at least any one of the kind or the content by using the constitutional unit C, it is possible to adjust various characteristics of the polymer A. In particular, in a case of properly using the constitutional unit C, it is possible to easily adjust the Tg of the polymer A to 90° C. or lower.

Specific examples of the constitutional unit C include a constitutional unit formed by polymerizing styrene, tert-butoxystyrene, methylstyrene, α-methylstyrene, acetoxystyrene, methoxystyrene, ethoxystyrene, chlorostyrene, methyl vinylbenzoate, ethyl vinylbenzoate, methyl (meth)acrylate, ethyl (meth)acrylate, n-propyl (meth)acrylate, isopropyl (meth)acrylate, 2-hydroxyethyl acrylate, 2-hydroxypropyl (meth)acrylate benzyl (meth)acrylate, isobornyl (meth)acrylate, acrylonitrile, a mono(meth)acrylate of ethylene glycol monoacetoaceate, or the like.

In addition, the compounds described in paragraphs [0021] to [0024] of JP2004-264623A are also included.

The constitutional unit C is preferably a constitutional unit having an aromatic ring or a constitutional unit having an aliphatic cyclic skeleton.

Examples of the monomer that forms the above-described constitutional unit include styrene, tert-butoxystyrene, methylstyrene, α-methylstyrene, dicyclopentanyl (meth)acrylate, cyclohexyl (meth)acrylate, isobornyl (meth)acrylate, and benzyl (meth)acrylate.

Among them, the constitutional unit C is preferably a constitutional unit derived from cyclohexyl (meth)acrylate.

In addition, the monomer that forms the constitutional unit C, is for example, preferably a (meth)acrylic acid alkyl ester as well, and it is more preferably a (meth)acrylic acid alkyl ester having an alkyl group having 4 to 12 carbon atoms. Specific examples thereof include methyl (meth)acrylate, ethyl (meth)acrylate, propyl (meth)acrylate, n-butyl (meth)acrylate, and 2-ethylhexyl (meth)acrylate.

One kind of the constitutional unit C may be used alone, or two or more kinds thereof may be used.

The content of the constitutional unit C is preferably 70.0% by mass or less, more preferably 60.0% by mass or less, and still more preferably 50.0% by mass or less, with respect to the total mass of the polymer A. The lower limit thereof is preferably 0% by mass or more, more preferably 1.0% by mass or more, and still more preferably 5.0% by mass or more. In a case of the above range, the resolution and the adhesiveness are further improved.

It is also preferable that the polymer A contains, as the constitutional unit C, a constitutional unit having an ester of an acid group in the constitutional unit B, from the viewpoint of optimizing the solubility in a developer and the physical properties of the photosensitive resin composition layer.

Among the above, it is preferable that the polymer A contains a constitutional unit having a carboxylic acid group as the constitutional unit B and further contains the constitutional unit C containing a carboxylic acid ester group as a copolymerization component, where the polymer A that contains the constitutional unit B derived from methyl (meth)acrylate and the constitutional unit C derived from cyclohexyl (meth)acrylate and/or ethyl (meth)acrylate is more preferable.

Hereinafter, specific examples of the polymer A will be shown; however, the polymer A in the present invention is not limited thereto.

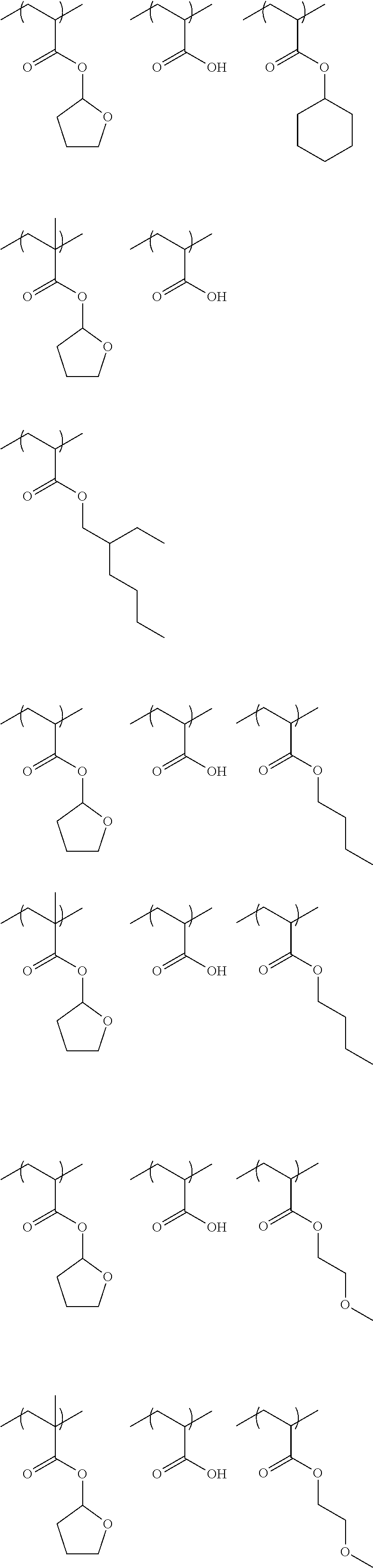

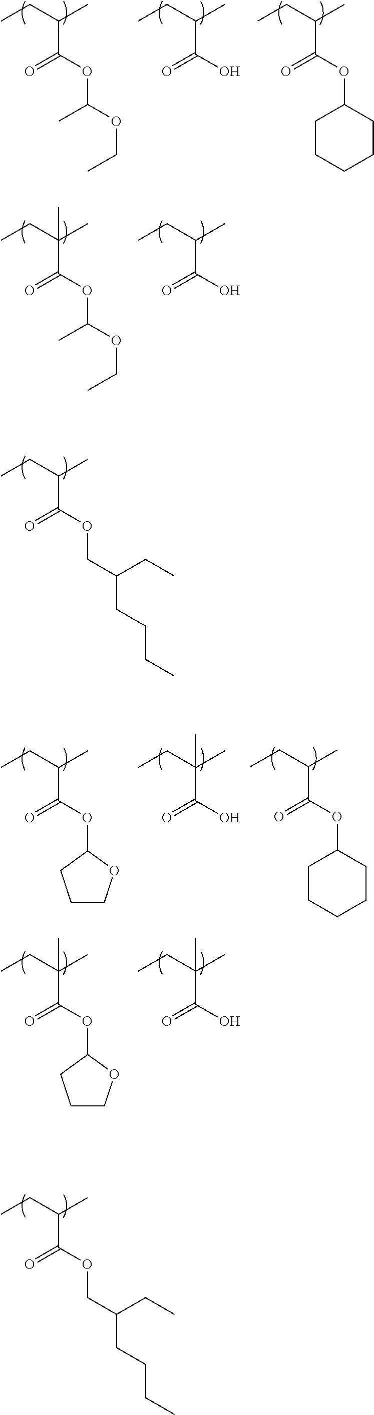

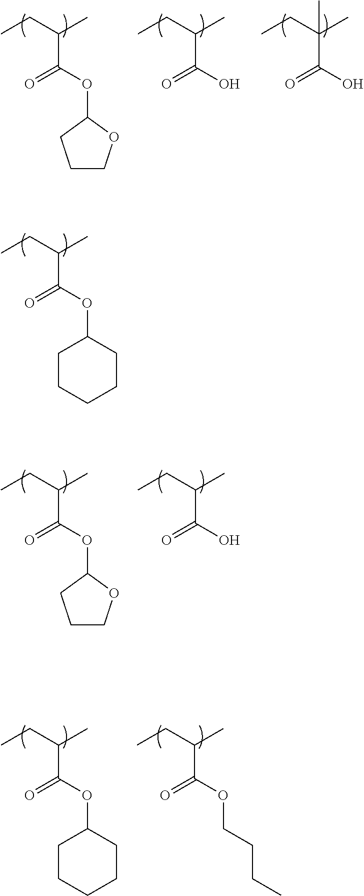

The glass transition temperature (Tg) of the polymer A is preferably 90° C. or lower. In a case where the Tg is 90° C. or lower, the photosensitive resin composition layer has high adhesiveness and has more excellent transferability. The Tg is more preferably 60° C. or lower and still more preferably 40° C. or lower. The lower limit value of the Tg is not particularly limited; however, it is preferably −20° C. or higher and more preferably −10° C. or higher. In a case where the Tg of the polymer A is −20° C. or higher, good pattern formation properties are maintained, and for example, in a case where a cover film is used, a decrease in peelability at the time of peeling the cover film is suppressed.

The glass transition temperature of the polymer A can be measured by differential scanning calorimetry (DSC). Specifically, the glass transition temperature is measured according to the method described in JIS K 7121 (1987) or JIS K 6240 (2011). As the glass transition temperature in the present specification, an extrapolated glass transition initiation temperature (hereinafter, also referred to as “Tig”) is used.

The molecular weight of the polymer A is preferably 60,000 or less, more preferably 2,000 to 60,000, and still more preferably 3,000 to 50,000.

The weight-average molecular weight of the polymer A can be measured by gel permeation chromatography (GPC).

The dispersivity (Mw/Mn) of the polymer A is preferably 1.0 to 5.0 and more preferably 1.05 to 3.5.

A production method for the polymer A is not particularly limited, and a known method may be used.

For example, it can be synthesized by being polymerized using a polymerization initiator in an organic solvent containing a monomer for forming the constitutional unit A1, a monomer for forming the constitutional unit B containing an acid group, and a monomer for forming the constitutional unit C.

The photosensitive resin composition layer may contain another polymer in addition to the polymer A.

In a case where the photosensitive resin composition layer contains another polymer, the content of the other polymer is preferably 50% by mass or less, more preferably 30% by mass or less, and still more preferably 20% by mass or less, with respect to the total mass of the photosensitive resin composition layer. The lower limit thereof is not particularly limited; however, it is 0% by mass or more in a large number of cases.

Examples of the other polymer include polyhydroxystyrene. Specific examples thereof include SMA1000P, SMA2000P, SMA3000P, SMA1440F, SMA17352P, SMA2625P, and SMA3840F (all of which are manufactured by Sartomer Company Inc.), ARUFONUC-3000, ARUFONUC-3510, ARUFONUC-3900, ARUFONUC-3910, ARUFONUC-3920, and ARUFONUC-3080 (all of which are manufactured by Toagosei Co., Ltd.), and Joncryl 690, Joncryl 678, Joncryl 67, and Joncryl 586 (all of which are manufactured by BASF SE).

One kind of the polymer A may be used alone, or two or more kinds thereof may be used.

The content of the polymer A is preferably 50.00% to 99.99% by mass and more preferably 70.00% to 98.00% by mass with respect to the total mass of the photosensitive resin composition layer.

<Photoacid Generator>

The photosensitive resin composition layer according to the embodiment of the present invention may contain a photoacid generator.

Examples of the photoacid generator include a photoacid generator which may be contained in the thermoplastic resin composition layer described later, and the same applies to the suitable aspect thereof.

One kind of photoacid generator may be used alone, or two or more kinds thereof may be used.

The content of the photoacid generator is preferably 0.1% to 30.0% by mass, more preferably 1.0% to 20.0% by mass, and still more preferably 5.0% to 15.0% by mass, with respect to the total mass of the photosensitive resin composition layer.

<Polymerizable Compound>

The photosensitive resin composition layer may contain a polymerizable compound having a polymerizable group.

In the present specification, the “polymerizable compound” means a compound different from the block copolymer, the compound (1), and the polymer P, which are described above.

The polymerizable group contained in the polymerizable compound is not particularly limited as long as it is a group involved in the polymerization reaction, and examples thereof include groups having an ethylenically unsaturated group, such as a vinyl group, an acryloyl group, a methacryloyl group, a styryl group, and a maleimide group; and groups having a cationically polymerizable group, such as an epoxy group and an oxetane group.

The polymerizable group is preferably a group having an ethylenically unsaturated group, and more preferably an acryloyl group or a methacryloyl group.

From the viewpoint that the photosensitive resin composition layer is more excellent in photosensitivity, the polymerizable compound is preferably a compound having one or more ethylenically unsaturated groups (an ethylenically unsaturated compound) and more preferably a compound having two or more ethylenically unsaturated groups in one molecule (a polyfunctional ethylenically unsaturated compound).

In addition, from the viewpoint of being excellent in resolution and peelability, the number of ethylenically unsaturated groups contained in one molecule of the ethylenically unsaturated compound is preferably 6 or less, more preferably 3 or less, and still more preferably 2 or less.

From the viewpoint that the balance of the photosensitivity, the resolution, and the peelability of the photosensitive resin composition layer is more excellent a bifunctional or trifunctional ethylenically unsaturated compound having two or three ethylenically unsaturated groups in one molecule is preferably contained, and a bifunctional ethylenically unsaturated compound having two ethylenically unsaturated groups in one molecule is more preferably contained.

From the viewpoint of excellent peelability, the content of the bifunctional ethylenically unsaturated compound with respect to the total mass of the polymerizable compound is preferably 20% by mass or more, more preferably more than 40% by mass, and still more preferably 55% by mass or more, with respect to the total mass of the photosensitive resin composition layer. The upper limit thereof is not particularly limited and may be 100% by mass or less. That is, all the polymerizable compounds may be bifunctional ethylenically unsaturated compounds.

In addition, the ethylenically unsaturated compound is preferably an (meth)acrylate compound having an (meth)acryloyl group as the polymerizable group.

(Polymerizable Compound B1)

It is also preferable that the photosensitive resin composition layer contains a polymerizable compound B1 having an aromatic ring and two ethylenically unsaturated groups.

The polymerizable compound B1 is a bifunctional ethylenically unsaturated compound having one or more aromatic rings in one molecule among the above-described polymerizable compounds B.

From the viewpoint of the more excellent resolution, the mass ratio of the content of the polymerizable compound B1 to the total mass of the polymerizable compound in the photosensitive resin composition layer is preferably 40% by mass or more, more preferably 50% by mass or more, still more preferably 55% by mass or more, and particularly preferably 60% by mass or more. The upper limit thereof is not particularly limited. However, from the viewpoint of peelability, it is, for example, 100% by mass or less, and it is preferably 99% by mass or less, more preferably 95% by mass or less, still more preferably 90% by mass or less, and particularly preferably 85% by mass or less.

Examples of the aromatic ring contained in the polymerizable compound B1 include aromatic hydrocarbon rings such as a benzene ring, a naphthalene ring, and an anthracene ring, aromatic heterocyclic rings such as a thiophene ring, a furan ring, a pyrrole ring, an imidazole ring, a triazole ring, and a pyridine ring, and fused rings thereof, where an aromatic hydrocarbon ring is preferable, and a benzene ring is more preferable. It is noted that the aromatic ring may have a substituent.

The polymerizable compound B1 may have only one aromatic ring or may have two or more aromatic rings.

The polymerizable compound B1 preferably has a bisphenol structure from the viewpoint of improving the resolution by suppressing the swelling of the photosensitive resin composition layer due to the developer.

Examples of the bisphenol structure include a bisphenol A structure derived from bisphenol A (2,2-bis(4-hydroxyphenyl)propane) a bisphenol F structure derived from bisphenol F (2,2-bis(4-hydroxyphenyl)methane), and a bisphenol B structure derived from bisphenol B (2,2-bis(4-hydroxyphenyl)butane), where a bisphenol A structure is preferable.

Examples of the polymerizable compound B1 having a bisphenol structure include a compound having a bisphenol structure and two polymerizable groups (preferably (meth)acryloyl groups) bonded to both ends of the bisphenol structure.

Both ends of the bisphenol structure and the two polymerizable groups may be directly bonded or may be bonded through one or more oxyalkylene groups. The oxyalkylene group to be added to both ends of the bisphenol structure is preferably an oxyethylene group or an oxypropylene group and more preferably an oxyethylene group. The number of oxyalkylene groups to be added to the bisphenol structure is not particularly limited; however, it is preferably 4 to 16 and more preferably 6 to 14 per molecule.

The polymerizable compound B1 having a bisphenol structure is described in paragraphs [0072] to [0080] of JP2016-224162A, and the content described in this publication is incorporated in the present specification.

The polymerizable compound B1 is preferably a bifunctional ethylenically unsaturated compound having a bisphenol A structure, and it is more preferably 2,2-bis(4-((meth)acryloxypolyalkoxy)phenyl)propane.

Examples of the 2,2-bis(4-((meth)acryloxypolyalkoxy)phenyl)propane include 2,2-bis(4-(methacryloxydiethoxy)phenyl)propane (FA-324M, manufactured by Showa Denko Materials Co., Ltd.), 2,2-bis(4-(methacryloxyethoxypropoxy)phenyl)propane, 2,2-bis(4-(methacryloxypentaethoxy)phenyl)propane (BPE-500, manufactured by SHIN-NAKAMURA CHEMICAL Co., Ltd.), 2,2-bis(4-(methacryloxydodecaethoxytetrapropoxy)phenyl)propane (FA-3200MY, manufactured by Showa Denko Materials Co., Ltd.), 2,2-bis(4-(methacryloxypentadecaethoxy)phenyl)propane (BPE-1300, manufactured by SHIN-NAKAMURA CHEMICAL Co., Ltd.), 2,2-bis(4-(methacryloxydiethoxy)phenyl)propane (BPE-200, manufactured by SHIN-NAKAMURA CHEMICAL Co., Ltd.), and ethoxylated (10) bisphenol A diacrylate (NK Ester A-BPE-10, manufactured by SHIN-NAKAMURA CHEMICAL Co., Ltd.).

The polymerizable compound B1 is preferably a compound represented by General Formula (B1).

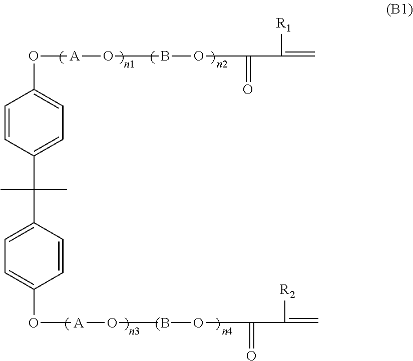

In General Formula B1, R₁, and R₂ each independently represent a hydrogen atom or a methyl group. A represents C₂H₄. B represents C₃H₆. n1 and n3 are each independently an integer of 1 to 39, and n1+n3 is an integer of 2 to 40. n2 and n4 are each independently an integer of 0 to 29, and n2+n4 is an integer of 0 to 30. The sequences of constitutional units of -(A-O)— and —(B—O)— may be a random type or a block type. Here, in a case of a block type, any one of -(A-O)— or —(B—O)— may be on the bisphenyl group side.

In one aspect, n1+n2+n3+n4 is preferably an integer of 2 to 20, more preferably an integer of 2 to 16, and still more preferably an integer of 4 to 12. In addition, n2+n4 is preferably an integer of 0 to 10, more preferably an integer of 0 to 4, still more preferably an integer of 0 to 2, and particularly preferably 0.

One kind of the polymerizable compound B1 may be used alone, or two or more kinds thereof may be used.

From the viewpoint of the more excellent resolution, the content of the polymerizable compound B1 is preferably 10% by mass or more and more preferably 20% by mass or more with respect to the total mass of the photosensitive resin composition layer. The upper limit is not particularly limited; however, it is preferably 70% by mass or less and more preferably 60% by mass or less from the viewpoint of transferability and edge fusion (a phenomenon in which a photosensitive resin exudes from an end portion of a transfer member).

The photosensitive resin composition layer may contain a polymerizable compound other than the above-described polymerizable compound B1.

The polymerizable compound other than the polymerizable compound B1 is not particularly limited and can be appropriately selected from known compounds. Examples thereof include a compound having one ethylenically unsaturated group in one molecule (a monofunctional ethylenically unsaturated compound), a bifunctional ethylenically unsaturated compound having no aromatic ring, and a trifunctional or higher functional ethylenically unsaturated compound.

Examples of the monofunctional ethylenically unsaturated compound include ethyl (meth)acrylate, ethylhexyl (meth)acrylate, 2-(meth)acryloyloxyethyl succinate, polyethylene glycol mono(meth)acrylate, polypropylene glycol mono(meth)acrylate, and phenoxyethyl (meth)acrylate.

Examples of the bifunctional ethylenically unsaturated compound having no aromatic ring include alkylene glycol di(meth)acrylate, polyalkylene glycol di(meth)acrylate, urethane di(meth)acrylate, and trimethylolpropane diacrylate.

Examples of the alkylene glycol di(meth)acrylate include tricyclodecanedimethanol diacrylate (A-DCP, manufactured by SHIN-NAKAMURA CHEMICAL Co., Ltd.), tricyclodecanedimethanol dimethacrylate (DCP, manufactured by SHIN-NAKAMURA CHEMICAL Co., Ltd.), 1,9-nonandiol diacrylate (A-NOD-N, manufactured by SHIN-NAKAMURA CHEMICAL Co., Ltd.), 1,6-hexanediol diacrylate (A-HD-N, manufactured by SHIN-NAKAMURA CHEMICAL Co., Ltd.), ethylene glycol dimethacrylate, 1,10-decanediol diacrylate, and neopentyl glycol di(meth)acrylate.

Examples of the polyalkylene glycol di(meth)acrylate include polyethylene glycol di(meth)acrylate, dipropylene glycol diacrylate, tripropylene glycol diacrylate, and polypropylene glycol di(meth)acrylate.

Examples of the urethane di(meth)acrylate include propylene oxide-modified urethane di(meth)acrylate, as well as ethylene oxide- and propylene oxide-modified urethane di(meth)acrylates. Examples of the commercially available product include 8UX-015A (manufactured by Taisei Fine Chemical Co., Ltd.), UA-32P (manufactured by SHIN-NAKAMURA CHEMICAL Co., Ltd.), and UA-1100H (manufactured by SHIN-NAKAMURA CHEMICAL Co., Ltd.).

Examples of the trifunctional or higher functional ethylenically unsaturated compound include dipentaerythritol (tri/tetra/penta/hexa)(meth)acrylate, pentaerythritol (tri/tetra)(meth)acrylate, trimethylolpropane tri(meth)acrylate, ditrimethylolpropane tetra(meth)acrylate, trimethylolethane tri(meth)acrylate, isocyanuric acid tri(meth)acrylate, glycerin tri(meth)acrylate, and an alkylene oxide-modified product thereof.

Here, “(tri/tetra/penta/hexa)(meth)acrylate” has a concept including tri(meth)acrylate, tetra(meth)acrylate, penta(meth)acrylate, and hexa(meth)acrylate, and “(tri/tetra)(meth)acrylate” has a concept that includes tri(meth)acrylate and tetra(meth)acrylate.

In one aspect, the photosensitive resin composition layer also preferably contains the above-described polymerizable compound B1 and the above-described trifunctional or higher functional ethylenically unsaturated compound, and it more preferably contains the above-described polymerizable compound B1 and two or more kinds of trifunctional or higher functional ethylenically unsaturated compounds. In this case, the mass ratio of the polymerizable compound B1 to the trifunctional or higher functional ethylenically unsaturated compound ((the total mass of the polymerizable compound B1):(the total mass of the trifunctional or higher functional ethylenically unsaturated compound)) is preferably 1:1 to 5:1, more preferably 1.2:1 to 4:1, and still more preferably 1.5:1 to 3:1.

Further, in one aspect, the photosensitive resin composition preferably contains the above-described polymerizable compound B1 and two or more kinds of trifunctional ethylenically unsaturated compounds.

Examples of the alkylene oxide-modified product of the trifunctional or higher functional ethylenically unsaturated compound include a caprolactone-modified (meth)acrylate compound (KAYARAD (registered trade name) DPCA-20 manufactured by Nippon Kayaku Co., Ltd., A-9300-1CL manufactured by SHIN-NAKAMURA CHEMICAL Co., Ltd., or the like), an alkylene oxide-modified (meth)acrylate compound (KAYARAD RP-1040 manufactured by Nippon Kayaku Co., Ltd., ATM-35E or A-9300 manufactured by SHIN-NAKAMURA CHEMICAL Co., Ltd., EBECRYL (registered trade name) 135 manufactured by DAICEL-ALLNEX Ltd., or the like), ethoxylated glycerin triacrylate (A-GLY-9E manufactured by SHIN-NAKAMURA CHEMICAL Co., Ltd. or the like), ARONIX (registered trade name) TO-2349 (manufactured by Toagosei Co., Ltd.), ARONIX M-520 (manufactured by Toagosei Co., Ltd.), and ARONIX M-510 (manufactured by Toagosei Co., Ltd.).

Further, as the polymerizable compound, a polymerizable compound having an acid group (a carboxy group or the like) may be used. The acid group may form an acid anhydride group. Examples of the polymerizable compound having an acid group include ARONIX (registered trade name) TO-2349 (manufactured by Toagosei Co., Ltd.), ARONIX (registered trade name) M-520 (manufactured by Toagosei Co., Ltd.), and ARONIX (registered trade name) M-510 (manufactured by Toagosei Co., Ltd.).

As the polymerizable compound having an acid group, for example, the polymerizable compound having an acid group described in paragraphs [0025] to [0030] of JP2004-239942A may be used.

The molecular weight (the weight-average molecular weight in a case of having a molecular weight distribution) of the polymerizable compound (including the polymerizable compound B1) is preferably 200 to 3,000, more preferably 280 to 2,200, and still more preferably 300 to 2,200.

One kind of polymerizable compound may be used alone, or two or more kinds thereof may be used.

The content of the polymerizable compound is preferably 1% to 70% by mass, more preferably 5% to 70% by mass, still more preferably 20% to 70% by mass, and particularly preferably 40% to 60% by mass, with respect to the total mass of the photosensitive resin composition layer.

<Polymerization Initiator>

The photosensitive resin composition layer may contain a polymerization initiator.

The polymerization initiator is selected according to the type of the polymerization reaction, and examples thereof include a thermal polymerization initiator and a photopolymerization initiator.

The polymerization initiator may be a radical polymerization initiator or a cationic polymerization initiator.

The photosensitive resin composition layer preferably contains a photopolymerization initiator.

The photopolymerization initiator is a compound that initiates the polymerization of a polymerizable compound by receiving an actinic ray such as an ultraviolet ray, visible light, or an X-ray. The photopolymerization initiator is not particularly limited, and a known photopolymerization initiator can be used.

Examples of the photopolymerization initiator include a photoradical polymerization initiator and a photocationic polymerization initiator, where a photoradical polymerization initiator is preferable.

Examples of the photoradical polymerization initiator include a photopolymerization initiator having an oxime ester structure, a photopolymerization initiator having an α-aminoalkyl phenone structure, a photopolymerization initiator having an α-hydroxyalkyl phenone structure, a photopolymerization initiator having an acylphosphine oxide structure, and a photopolymerization initiator having an N-phenyl glycine structure.

Further, from the viewpoints of the photosensitivity, the visibility of the exposed portion and the non-exposed portion, and the resolution, the photosensitive resin composition layer preferably contains at least one selected from the group consisting of 2,4,5-triarylimidazole dimer and a derivative thereof, as a photoradical polymerization initiator. The two 2,4,5-triarylimidazole structures in the 2,4,5-triarylimidazole dimer and the derivative thereof may be the same or different from each other.

Examples of the derivative of the 2,4,5-triarylimidazole dimer include a 2-(o-chlorophenyl)-4,5-diphenylimidazole dimer, a 2-(o-chlorophenyl)-4,5-di(methoxyphenyl)imidazole dimer, a 2-(o-fluorophenyl)-4,5-diphenylimidazole dimer, a 2-(o-methoxyphenyl)-4,5-diphenylimidazole dimer, and a 2-(p-methoxyphenyl)-4,5-diphenylimidazole dimer.

Examples of the photoradical polymerization initiator which may be used include polymerization initiators described in paragraphs [0031] to [0042] of JP2011-095716A and paragraphs [0064] to [0081] of JP2015-014783A.

Examples of the photoradical polymerization initiator include ethyl dimethylaminobenzoate (DBE, CAS No. 10287-53-3), benzoin methyl ether, anisyl (p,p′-dimethoxybenzyl), TAZ-110 (product name: Midori Kagaku Co., Ltd.), benzophenone, 4,4′-bis(diethylamino)benzophenone, TAZ-111 (product name: Midori Kagaku Co., Ltd.), Irgacure OXE01, OXE02, OXE03, OXE04 (BASF SE), Omnirad 651 and 369 (product name: IGM Resins B.V.), and 2,2′-bis(2-chlorophenyl)-4,4′,5,5′-tetraphenyl-1,2′-biimidazole (manufactured by Tokyo Chemical Industry Co., Ltd.).

Examples of the commercially available product of the photoradical polymerization initiator include 1-[4-(phenylthio)]-1,2-octanedione-2-(O-benzoyloxime) (product name: IRGACURE (registered trade name)), OXE-01 (manufactured by BASF SE), 1-[9-ethyl-6-(2-methylbenzoyl)-9H-carbazole-3-yl]ethanone-1-(0-acetyloxime) (product name: IRGACURE OXE-02, manufactured by BASF SE), IRGACURE OXE-03 (manufactured by BASF SE), IRGACURE OXE-04 (manufactured by BASF SE), 2-(dimethylamino)-2-[(4-methylphenyl)methyl]-1-[4-(4-morpholinyl)phenyl]-1-butanone (product name: Omnirad 379EG, IGM Resins B.V), 2-methyl-1-(4-methylthiophenyl)-2-morpholinopropane-1-one (product name: Omnirad 907, IGM Resins B.V.), 2-hydroxy-1-{4-[4-(2-hydroxy-2-methylpropionyl)benzyl]phenyl}-2-methylpropane-1-one (product name: Omnirad 127, IGM Resins B.V), 2-benzyl-2-dimethylamino-1-(4-morpholinophenyl)butanone-1 (product name: Omnirad 369, manufactured by IGM Resins B.V.), 2-hydroxy-2-methyl-1-phenylpropane-1-one (product name: Omnirad 1173, manufactured by IGM Resins B.V.), 1-hydroxycyclohexylphenylketone (product name: Omnirad 184, manufactured by IGM Resins B.V), 2,2-dimethoxy-1,2-diphenylethane-1-one (product name: Omnirad 651, manufactured by IGM Resins B.V.), 2,4,6-trimethylbenzoyl-diphenylphosphinoxide (product name: Omnirad TPO H, IGM Resins B.V), bis(2,4,6-trimethylbenzoyl)phenylphosphine oxide (product name: Omnirad 819, IGM Resins B.V), an oxime ester-based photopolymerization initiator (product name: Lunar 6, DKSH Management Ltd.), 2,2′-bis(2-chlorophenyl)-4,4′,5,5′-tetraphenylbisimidazole (a 2-(2-chlorophenyl)-4,5-diphenylimidazole dimer (product name: B-CIM, manufactured by Hampford Research Inc.), a 2-(o-chlorophenyl)-4,5-diphenylimidazole dimer (product name: BCTB, manufactured by Tokyo Chemical Industry Co., Ltd.), 1-[4-(phenylthio)phenyl]-3-cyclopentylpropane-1,2-dione-2-(O-benzoyloxime) (product name: TR-PBG-305, manufactured by Changzhou Tronly New Electronic Materials Co., Ltd.), 1,2-propanedione, 3-cyclohexyl-1-[9-ethyl-6-(2-furanylcarbonyl)-9H-carbazole-3-yl]-, 2-(0-acetyloxime) (product name: TR-PBG-326, manufactured by Changzhou Tronly New Electronic Materials Co., Ltd.), and 3-cyclohexyl-1-(6-(2-(benzoyloxyimino)hexanoyl)-9-ethyl-9H-carbazole-3-yl)-propane-1,2-dione-2-(O-benzoyloxime) (product name: TR-PBG-391, manufactured by Changzhou Tronly New Electronic Materials Co., Ltd.).

The photocationic polymerization initiator (a photoacid generator) is a compound that generates an acid by receiving an actinic ray. The photocationic polymerization initiator is preferably a compound which becomes sensitive to an actinic ray having a wavelength of 300 nm or more, preferably 300 to 450 nm, and generates an acid; however, the chemical structure thereof is not limited. A photocationic polymerization initiator which does not directly become sensitive to an actinic ray having a wavelength of 300 nm or more can also be preferably used in combination with a sensitizing agent as long as it is a compound which becomes sensitive to an actinic ray having a wavelength of 300 nm or more and then generates an acid by being used in combination with the sensitizing agent.

The photocationic polymerization initiator is preferably a photocationic polymerization initiator that generates an acid having a pKa of 4 or less, more preferably a photocationic polymerization initiator that generates an acid having a pKa of 3 or less, and particularly preferably a photocationic polymerization initiator that generates an acid having a pKa of 2 or less. The lower limit value of pKa is not particularly defined; however, it is, for example, preferably −10.0 or more.

Examples of the photocationic polymerization initiator include an ionic photocationic polymerization initiator and a nonionic photocationic polymerization initiator.

Examples of the ionic photocationic polymerization initiator include onium salt compounds such as diaryliodonium salts and triarylsulfonium salts, and quaternary ammonium salts.

As the ionic photocationic polymerization initiator, the ionic photocationic polymerization initiators described in paragraphs [0114] to [0133] of JP2014-085643A may be used.

Examples of the nonionic photocationic polymerization initiator include trichloromethyl-s-triazines, diazomethane compounds, imide sulfonate compounds, and oxime sulfonate compounds. As the trichloromethyl-s-triazines, the diazomethane compounds, and the imide sulfonate compounds, the compounds described in paragraphs [0083] to [0088] of JP2011-221494A may be used. Further, as the oxime sulfonate compound, the compounds described in paragraphs [0084] to [0088] of WO2018/179640A may be used.

Examples of the photocationic polymerization initiator (the photoacid generator) also include a thermoplastic resin composition layer which will be described in the description of a coloration resin composition layer described later and a photoacid generator described later.

The photosensitive resin composition layer preferably contains a photoradical polymerization initiator, and it more preferably contains at least one selected from the group consisting of a 2,4,5-triarylimidazole dimer and a derivative thereof.

One kind of polymerization initiator may be used alone, or two or more kinds thereof may be used.

The content of the polymerization initiator (preferably, the photopolymerization initiator) is not particularly limited. However, it is preferably 0.1% by mass or more, more preferably 0.5% by mass or more, and still more preferably 1.0% by mass or more, with respect to the total mass of the photosensitive resin composition layer. The upper limit thereof is not particularly limited: however, it is preferably 20% by mass or less, more preferably 15% by mass or less, still more preferably 10% by mass or less, and particularly preferably 5% by mass or less, with respect to the total mass of the photosensitive resin composition layer.

<Coloring Agent>

From the viewpoints of visibility of the exposed portion and the non-exposed portion, the pattern visibility after development, and the resolution, it is also preferable that the photosensitive resin composition layer contains a coloring agent (also referred to as a “coloring agent N”) that has a maximum absorption wavelength of 450 nm or more in a wavelength range of 400 to 780 nm at the time of color development, where the maximum absorption wavelength is changed by an acid, a base, or a radical. In a case where the coloring agent N is contained, the adhesiveness to an adjacent layer (for example, the temporary support and the interlayer) is improved, and thus the resolution is more excellent although the detailed mechanism is unknown.

In the present specification, the description that “the maximal absorption wavelength of the coloring agent is changed by an acid, a base, or a radical” may mean any one of an aspect in which a coloring agent in a colored state is decolorized by an acid, a base, or a radical, an aspect in which a coloring agent in a decolorized state develops a color by an acid, a base, or a radical, or an aspect in which a colored state of a coloring agent changes to a colored state of another color tone.

Specifically, the coloring agent N may be a compound that changes from the decolorized state to develop a color upon exposure or may be a compound that changes from the colored state to be decolorized upon exposure. In this case, it may be a coloring agent of which the color developing state or decolorized state changes by an action of an acid, a base, or a radical, which is generated upon exposure in the photosensitive resin composition layer, or it may be a coloring agent of which the color developing state or decolorized state changes due to a change in the state (for example, pH) of the inside of the photosensitive resin composition layer, the change being caused by an acid, a base, or a radical. Further, it may be a coloring agent of which the color developing state or decolorized state changes by directly receiving an acid, a base, or a radical as a stimulus without undergoing exposure.

Among the above, the coloring agent N is preferably a coloring agent of which the maximum absorption wavelength is changed by an acid or a radical, and more preferably a coloring agent of which the maximum absorption wavelength is changed by a radical, from the viewpoints of the visibility of the exposed portion and the non-exposed portion and the resolution.

From the viewpoints of the visibility of the exposed portion and the non-exposed portion and the resolution, the photosensitive resin composition layer preferably contains both a coloring agent of which the maximum absorption wavelength is changed by a radical as the coloring agent N and a photoradical polymerization initiator.

Further, from the viewpoint of the visibility of the exposed portion and the non-exposed portion, the coloring agent N is preferably a coloring agent that develops color by an acid, a base, or a radical.

Examples of the color development mechanism of the coloring agent N include an aspect in which a photoradical polymerization initiator, a photocationic polymerization initiator (a photoacid generator), or a photobase generator is added to the photosensitive resin composition layer so that a radical-reactive coloring agent, an acid-reactive coloring agent, or a base-reactive coloring agent (for example, a leuco coloring agent) develops a color by a radical, an acid, or a base, which is generated after exposure from the photoradical polymerization initiator, the photocationic polymerization initiator, or the photobase generator.

From the viewpoint of the visibility of the exposed portion and the non-exposed portion, the coloring agent N preferably has a maximal absorption wavelength of 550 nm or more, more preferably 550 to 700 nm, and still more preferably 550 to 650 nm, in a wavelength range of 400 to 780 nm at the time of color development.

In addition, the coloring agent N may have only one maximal absorption wavelength in a wavelength range of 400 to 780 nm at the time of color development or may have two or more coloring agents N. In a case where the coloring agent N has two or more maximal absorption wavelengths in a wavelength range of 400 to 780 nm at the time of color development, it suffices that the maximal absorption wavelength having the highest absorbance among the two or more maximal absorption wavelengths may be 450 nm or more.

The maximal absorption wavelength of the coloring agent N is obtained by measuring a transmission spectrum of a solution (solution temperature: 25° C.) containing the coloring agent N in a range of 400 to 780 nm using a spectrophotometer: UV3100 (manufactured by Shimadzu Corporation) in atmospheric air and detecting a wavelength (a maximal absorption wavelength) at which the intensity of light is minimal.

Examples of the coloring agent that develops a color or is decolorized upon exposure include a leuco compound.

Examples of the coloring agent that is decolorized upon exposure include a leuco compound, a diarylmethane-based coloring agent, an oxazine-based coloring agent, a xanthene-based coloring agent, an iminonaphthoquinone-based coloring agent, an azomethine-based coloring agent, and an anthraquinone-based coloring agent.

From the viewpoint of the visibility of the exposed portion and the non-exposed portion, the coloring agent N is preferably a leuco compound.

Examples of the leuco compound include a leuco compound having a triarylmethane skeleton (a triarylmethane-based coloring agent), a leuco compound having a spiropyran skeleton (a spiropyran-based coloring agent), a leuco compound having a fluoran skeleton (a fluoran-based coloring agent), a leuco compound having a diarylmethane skeleton (a diarylmethane-based coloring agent), a leuco compound having a rhodamine lactam skeleton (a rhodamine lactam-based coloring agent), a leuco compound having an indolyl phthalide skeleton (an indolyl phthalide-based coloring agent), and a leuco compound having a leuco auramine skeleton (a leuco auramine-based coloring agent).

Among them, a triarylmethane-based coloring agent or a fluoran-based coloring agent is preferable, and a leuco compound having a triphenylmethane skeleton (a triphenylmethane-based coloring agent) or a fluoran-based coloring agent is more preferable.

From the viewpoint of the visibility of the exposed portion and the non-exposed portion, the leuco compound preferably has a lactone ring, a sultine ring, or a sultone ring. As a result, the lactone ring, the sultine ring, or the sultone ring contained in the leuco compound is reacted with a radical generated from the photoradical polymerization initiator or an acid generated from the photocationic polymerization initiator to change the leuco compound into a closed ring state, thereby being decolorized, or change the leuco compound to an open ring state, whereby a color is developed. It is preferable that the leuco compound is a compound having a lactone ring, a sultine ring, or a sultone ring, where the lactone ring, the sultine ring, or the sultone ring is opened by a radical or an acid to develop a color, and it is more preferable that it is a compound having a lactone ring, where the lactone ring is opened by a radical or an acid to develop a color.

Examples of the coloring agent N include the following dyes and leuco compounds.

Among the coloring agents N, specific examples of the dye include Brilliant green, Ethyl violet, Methyl green, Crystal violet, Basic fuchsine, Methyl violet 2B, Quinaldine red, Rose bengal, Metanil yellow, thymol sulfonphthalein, Xylenol blue, Methyl orange, Paramethyl red, Congo red, Benzopurpurine 4B, α-Naphthyl red, Nile blue 2B, Nile blue A, Methyl violet, Malachite green, Parafuchsine, Victoria pure blue-naphthalene sulfonate, Victoria pure blue BOH (manufactured by HODOGAYA CHEMICAL CO., LTD.), Oil blue #603 (manufactured by ORIENT CHEMICAL INDUSTRIES CO., LTD.), Oil pink #312 (manufactured by ORIENT CHEMICAL INDUSTRIES CO., LTD.), Oil red 5B (manufactured by ORIENT CHEMICAL INDUSTRIES CO., LTD.), Oil scarlet #308 (manufactured by ORIENT CHEMICAL INDUSTRIES CO., LTD.), Oil red OG (manufactured by ORIENT CHEMICAL INDUSTRIES CO., LTD.), Oil red RR (manufactured by ORIENT CHEMICAL INDUSTRIES CO., LTD.), Oil green #502 (manufactured by ORIENT CHEMICAL INDUSTRIES CO., LTD.), Spiron red BEH special (manufactured by HODOGAYA CHEMICAL CO., LTD.), m-Cresol purple, Cresol red, rhodamine B, rhodamine 6G, sulforhodamine B, auramine, 4-p-diethylaminophenyliminonaphthoquinone, 2-carboxyanilino-4-p-diethylaminophenyliminonaphthoquinone, 2-carboxystearylamino-4-p-N,N-bis(hydroxyethyl) amino-phenyliminonaphthoquinone, 1-phenyl-3-methyl-4-p-diethylaminophenylimino-5-pyrazolone, and 1-O-naphthyl-4-p-diethylaminophenylimino-5-pyrazolone.

Among the coloring agents N, specific examples of the leuco compound include p,p′, p″-hexamethyltriaminotriphenylmethane (Leucocrystal violet), Pergascript blue SRB (manufactured by Ciba-Geigy AG), Crystal violet lactone, Malachite green lactone, benzoyl leucomethylene blue, 2-(N-phenyl-N-methylamino)-6-(N-p-tolyl-N-ethyl) aminofluoran, 2-anilino-3-methyl-6-(N-ethyl-p)-toluidino) fluoran, 3,6-dimethoxyfluoran, 3-(N,N-diethylamino)-5-methyl-7-(N,N-dibenzylamino) fluoran, 3-(N-cyclohexyl-N-methyl)amino)-6-methyl-7-anilinofluoran, 3-(N,N-diethylamino)-6-methyl-7-anilinofluoran, 3-(N,N-diethylamino)-6-methyl-7-xylidinofluoran, 3-(N,N-diethylamino)-6-methyl-7-chlorofluoran, 3-(N,N-diethylamino)-6-methoxy-7-aminofluoran, 3-(N,N-diethylamino)-7-(4-chloroanilino) fluoran, 3-(N,N-diethylamino)-7-chlorofluoran, 3-(N,N-diethylamino)-7-benzylaminofluoran, 3-(N,N-diethylamino)-7,8-benzofluoran, 3-(N,N-dibutylamino)-6-methyl-7-anilinofluoran, 3-(N,N-dibutylamino)-6-methyl-7-xylidinofluoran, 3-piperidino-6-methyl-7-anilinofluoran, 3-pyrrolidino-6-methyl-7-anilinofluoran, 3,3-bis(1-ethyl-2-methylindole-3-yl)phthalide, 3,3-bis(1-n-butyl-2-methylindole-3-yl)phthalide, 3,3-bis(p-dimethylaminophenyl)-6-dimethylaminophthalide, 3-(4-diethylamino-2-ethoxyphenyl)-3-(1-ethyl-2-methylindole-3-yl)-4-azaphthalide, 3-(4-diethylaminophenyl)-3-(1-ethyl-2-methylindole-3-yl)phthalide, and 3′,6′-bis(diphenylamino)spiroisobenzofuran-1 (3H),9′-[9H]xanthene-3-one.

From the viewpoints of visibility of the exposed portion and the non-exposed portion, the pattern visibility after development, and the resolution, the coloring agent N is preferably a coloring agent of which the maximum absorption wavelength is changed by a radical, and more preferably a coloring agent that develops a color by a radical.

The coloring agent N is preferably Leucocrystal violet, Crystal violet lactone, Brilliant green, or Victoria pure blue-naphthalene sulfonate.

One kind of the coloring agent N may be used alone, or two or more kinds thereof may be used.

From the viewpoints of visibility of the exposed portion and the non-exposed portion, the pattern visibility after development, and the resolution, the content of the coloring agent N is preferably 0.1% by mass or more, more preferably 0.1% to 10% by mass, still more preferably 0.1% to 5% by mass, and particularly preferably 0.1% to 1% by mass, with respect to the total mass of the photosensitive resin composition layer.

The content of the coloring agent N means the content of the coloring agent in a case where the whole coloring agent N contained in the total mass of the photosensitive resin composition layer is in a colored state. Hereinafter, a method of quantifying the content of the coloring agent N will be described by taking a coloring agent that develops color by a radical as an example.

A solution obtained by dissolving 0.001 g of the coloring agent in 100 mL of methyl ethyl ketone, and a solution obtained by dissolving 0.01 g of the coloring agent therein are prepared. A photoradical polymerization initiator Irgacure OXE01 (product name, BASF Japan Ltd.) is added to each of the obtained solutions, and radicals are generated by the irradiation with light of 365 nm to bring the whole coloring agent into a colored state. Then, in the atmospheric air, the absorbance of each solution having a liquid temperature of 25° C. is measured using a spectrophotometer (UV3100, manufactured by Shimadzu Corporation), and a calibration curve is prepared.

Next, the absorbance of the solution in which the coloring agent has been caused to develop a color is measured by the same method as the above except that 3 g of the photosensitive resin composition layer is dissolved in methyl ethyl ketone instead of the coloring agent. From the obtained absorbance of the solution containing the photosensitive resin composition layer, the content of the coloring agent with respect to the total mass of the photosensitive resin composition layer is calculated based on the calibration curve.

<Thermal Crosslinking Compound>

From the viewpoint of the hardness of the cured film to be obtained and the pressure-sensitive adhesiveness of the uncured film to be obtained, the photosensitive resin composition layer preferably contains a thermal crosslinking compound.

In this specification, the thermal crosslinking compound having an ethylenically unsaturated group described later shall be not treated as a polymerizable compound but be treated as a thermal crosslinking compound.

Examples of the thermal crosslinking compound include a methylol compound and a blocked isocyanate compound. Among them, from the viewpoint of the hardness of the cured film to be obtained and the pressure-sensitive adhesiveness of the uncured film to be obtained, a blocked isocyanate compound is preferable.

By the way, the blocked isocyanate compound reacts with a hydroxy group and a carboxy group. As a result, for example, in a case where the resin and/or the polymerizable compound has at least one of a hydroxy group or a carboxy group, a film to be formed has a low hydrophilicity, and thus in a case where a film obtained by curing the photosensitive resin composition layer is used as a protective film, the function thereof tends to be enhanced.

The blocked isocyanate compound refers to a “compound having a structure in which the isocyanate group of isocyanate is protected (so-called masked) by a blocking agent”.

The dissociation temperature of the blocked isocyanate compound is not particularly limited; however, it is preferably 100° C. to 160° C. and more preferably 130° C. to 150° C. The dissociation temperature of blocked isocyanate means “temperature at an endothermic peak accompanied with a deprotection reaction of blocked isocyanate, in a case where the measurement is carried out by differential scanning calorimetry (DSC) analysis using a differential scanning calorimeter”.

As the differential scanning calorimeter, for example, a differential scanning calorimeter (model: DSC6200) manufactured by Seiko Instruments Inc. can be suitably used. However, the differential scanning calorimeter is not limited thereto.

Examples of the blocking agent having a dissociation temperature of 100° C. to 160° C. include an active methylene compound [diester malonate (such as dimethyl malonate, diethyl malonate, di-n-butyl malonate, or di-2-ethylhexyl malonate)] and an oxime compound (a compound having a structure represented by —C(═N—OH)— in the molecule, such as formaldoxime, acetoaldoxime, acetoxime, methyl ethyl ketoxime, or cyclohexanoneoxime).

Among them, the blocking agent having a dissociation temperature of 100° C. to 160° C. is preferably, for example, at least one selected from oxime compounds from the viewpoint of storage stability.

The blocked isocyanate compound preferably has an isocyanurate structure, for example, from the viewpoint of improving the brittleness of the film and improving the adhesion force to a transferred material.

The blocked isocyanate compound having an isocyanurate structure can be obtained, for example, by isocyanurate-forming and protecting hexamethylene diisocyanate.

Among the blocked isocyanate compounds having an isocyanurate structure, a compound having an oxime structure using an oxime compound as a blocking agent is preferable from the viewpoint that the dissociation temperature can be easily set in a preferred range and the development residue can be easily reduced, as compared with a compound having no oxime structure.

The blocked isocyanate compound may have a polymerizable group.

The polymerizable group is not particularly limited, and a known polymerizable group can be used, where a radically polymerizable group is preferable.

Examples of the polymerizable group include an (meth)acryloxy group, an (meth)acrylamide group, an ethylenically unsaturated group such as styryl group, and an epoxy group such as a glycidyl group.

Among them, the polymerizable group is preferably an ethylenically unsaturated group, more preferably an (meth)acryloxy group, and still more preferably an acryloxy group.

A commercially available product can be used as the blocked isocyanate compound.

Examples of the commercially available blocked isocyanate compound include compounds such as Karenz (registered trade name), AOI-BM, Karenz (registered trade name), MOI-BM, Karenz (registered trade name), and MOI-BP (all of which are manufactured by Showa Denko K.K.); and block type DURANATE series (for example, DURANATE (registered trade name)), TPA-B80E, DURANATE (registered trade name), and WT32-B75P, manufactured by Asahi Kasei Chemicals Co., Ltd.).

Further, as the blocked isocyanate compound, a compound having the following structure can also be used.

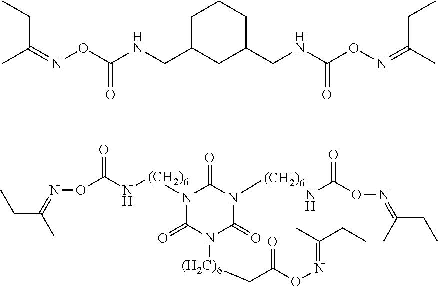

One kind of thermal crosslinking compound may be used alone, or two or more kinds thereof may be used.

The content of the thermal crosslinking compound is preferably 1% to 50% by mass and more preferably 5% to 30% by mass with respect to the total mass of the photosensitive resin composition layer.

<Additive>

The photosensitive resin composition layer may contain a known additive in addition to the above-described components, as necessary.

Examples of the additive include a radical polymerization inhibitor, a sensitizing agent, a plasticizer, a heterocyclic compound (triazole or the like), benzotriazoles, carboxybenzotriazoles, pyridines (isonicotinamide and the like), a purine base (adenine or the like), and a surfactant.

One kind of each additive may be used alone, or two or more kinds thereof may be used.

Examples of the radical polymerization inhibitor include the thermal polymerization inhibitors described in paragraph [0018] of JP4502784B. Among them, phenothiazine, phenoxazine, or 4-methoxyphenol is preferable. Examples of other radical polymerization inhibitors include naphthylamine, cuprous chloride, a nitrosophenylhydroxyamine aluminum salt, and diphenylnitrosamine. It is preferable to use a nitrosophenylhydroxyamine aluminum salt as a radical polymerization inhibitor so that the sensitivity of the photosensitive resin composition layer is not impaired.

Examples of the benzotriazoles include 1,2,3-benzotriazole, 1-chloro-1,2,3-benzotriazole, bis(N-2-ethylhexyl)aminomethylene-1,2,3-benzotriazole, bis(N-2-ethylhexyl)aminomethylene-1,2,3-tolyltriazole, and bis(N-2-hydroxyethyl)aminomethylene-1,2,3-benzotriazole.

Examples of the carboxybenzotriazoles include 4-carboxy-1,2,3-benzotriazole, 5-carboxy-1,2,3-benzotriazole, N—(N,N-di-2-ethylhexyl)aminomethylenecarboxybenzotriazole, N—(N,N-di-2-hydroxyethyl)aminomethylenecarboxybenzotriazole, and N—(N,N-di-2-ethylhexyl)aminoethylenecarboxybenzotriazole. As the carboxybenzotriazoles, it is possible to use, for example, a commercially available product such as CBT-1 (product name, JOHOKU CHEMICAL Co., Ltd.).

The total content of the radical polymerization inhibitor, the benzotriazoles, and the carboxybenzotriazoles is preferably 0.01% to 3% by mass and more preferably 0.05% to 1% by mass in a case where the total solid mass of the photosensitive resin composition layer is set to 100% by mass. It is preferable to set the above content to 0.01% by mass or more from the viewpoint of imparting storage stability to the composition. On the other hand, it is preferable that the above content is 3% by mass or less from the viewpoint of the maintenance of the sensitivity and the suppression of decolorization of the dye.

The sensitizing agent is not particularly limited, and a known sensitizing agent, a dye, or a pigment can be used. Examples of the sensitizing agent include a dialkylaminobenzophenone compound, a pyrazoline compound, an anthracene compound, a coumarin compound, a xanthone compound, a thioxanthone compound, an acridone compound, an oxazole compound, a benzoxazole compound, a thiazole compound, a benzothiazole compound, a triazole compound (for example, 1,2,4-triazole), a stilbene compound, a triazine compound, a thiophene compound, a naphthalimide compound, a triarylamine compound, and an aminoacridine compound.

The content of the sensitizing agent can be appropriately selected depending on the intended purpose.

From the viewpoints of improving the sensitivity to the light source and improving the curing rate by balancing the polymerization rate and the chain transfer, the content of the sensitizing agent is preferably 0.01% to 5% by mass and more preferably 0.05% to 1% by mass with respect to the total mass of the photosensitive resin composition layer.

Examples of the plasticizer and the heterocyclic compound include the compounds described in paragraphs [0097] to [0103] and [0111] to [0118] of WO2018/179640A.

The photosensitive resin composition may further contain known additives such as metal oxide particles, an antioxidant, a dispersing agent, an acid proliferation agent, a development accelerator, a conductive fiber, an ultraviolet absorbing agent, a thickener, a crosslinking agent, and an organic or inorganic precipitation inhibitor.

Examples of the additive contained in the photosensitive resin composition include the compounds described in paragraphs [0165] to [0184] of JP2014-085643A, and the content of this publication is incorporated in the present specification.

<Physical Properties of Photosensitive Resin Composition Layer>

(Film Thickness)

The layer thickness (the film thickness) of the photosensitive resin composition layer is not particularly limited. It is, for example, 0.1 to 300 μm in a large number of cases, and it is preferably 0.2 to 100 m, more preferably 0.5 to 50 m, still more preferably 0.5 to 15 m, particularly preferably 0.5 to 10 m, and most preferably 0.5 to 8 m. This makes it possible for the developability of the photosensitive resin composition layer to be improved and makes it possible for the resolution to be improved.

In addition, in one aspect, it is preferably 0.5 to 5 m, more preferably 0.5 to 4 m, and still more preferably 0.5 to 3 m.

In addition, from the viewpoint of excellent adhesiveness, the light transmittance of light having a wavelength of 365 nm in the photosensitive resin composition layer is preferably 10% or more, more preferably 30% or more, and still more preferably 50% or more. The upper limit thereof is not particularly limited; however, it is preferably 99.9% or less.

(Impurity and the Like)

The photosensitive resin composition layer may include a predetermined amount of impurities.

Specific examples of the impurities include sodium, potassium, magnesium, calcium, iron, manganese, copper, aluminum, titanium, chromium, cobalt, nickel, zinc, tin, halogen, and ions thereof. Among these, a halide ion, a sodium ion, and a potassium ion are easily mixed as impurities, and thus it is preferable to set the content of the impurities to the following content.

The upper limit of the content of the impurities is preferably 80 ppm by mass or less, more preferably 10 ppm by mass or less, and still more preferably 2 ppm by mass or less, with respect to the total mass of the photosensitive resin composition layer. The lower limit of the content is preferably 1 ppb by mass or more and more preferably 0.1 ppm by mass or more.

Examples of the method of keeping the impurities in the above range include selecting a raw material having a low content of impurities as a raw material for the photosensitive resin composition layer, preventing the impurities from being mixed during the production of the photosensitive resin composition layer, and washing and removing the impurities. Such a method makes it possible for the amount of impurities to be kept within the above range.

The impurities can be quantified by a known method such as inductively coupled plasma (ICP) emission spectroscopy, atomic absorption spectroscopy, and ion chromatography.

In the photosensitive resin composition layer, it is preferable that the content of the compound such as benzene, formaldehyde, trichloroethylene, 1,3-butadiene, carbon tetrachloride, chloroform, N,N-dimethylformamide, N,N-dimethylacetamide, or hexane is low. The upper limit of these compounds is preferably 100 ppm by mass or less, more preferably 20 ppm by mass or less, and still more preferably 4 ppm by mass or less, with respect to the total mass of the photosensitive resin composition layer.

The lower limit of the content is preferably 10 ppb by mass or more and more preferably 100 ppb by mass or more with respect to the total mass of the photosensitive resin composition layer. The content of these compounds can be suppressed in the same manner as in the above-described metal as impurities. Further, it can be quantified by a known measuring method.

(Residual Monomer)

The photosensitive resin composition layer may contain the residual monomer of each structural unit of the polymer P and the polymer A described above.

From the viewpoint of patterning properties and reliability, the content of the residual monomer is preferably 5,000 ppm by mass or less, more preferably 2,000 ppm by mass or less, and still more preferably 500 ppm by mass or less, with respect to the total mass of the polymer P or the polymer A. The lower limit thereof is not particularly limited; however, it is preferably 1 ppm by mass or more and more preferably 10 ppm by mass or more with respect to the total mass of the polymer P or the polymer A.

From the viewpoint of patterning properties and reliability, the residual monomer of each structural unit of the polymer P or the polymer A is preferably 3,000 ppm by mass or less, more preferably 600 ppm by mass or less, and still more preferably 100 ppm by mass or less, with respect to the total mass of the photosensitive resin composition layer. The lower limit thereof is not particularly limited; however, it is preferably 0.1 ppm by mass or more and more preferably 1 ppm by mass or more with respect to the total mass of the photosensitive resin composition layer.

The amount of the residual monomer can be measured by a known method such as liquid chromatography or gas chromatography.

[Thermoplastic Resin Composition Layer]

The resin composition layer may be a thermoplastic resin composition layer.

For example, in a transfer film having a temporary support and a resin composition layer, the thermoplastic resin composition layer is preferably formed between the temporary support and the resin composition layer.

In a case where the transfer film has a thermoplastic resin composition layer between the temporary support and the resin composition layer, the followability to the substrate in the affixing step of the transfer film and the substrate is improved, and the mixing of air bubbles between the substrate and the transfer film is suppressed, whereby the adhesiveness to an adjacent layer (for example, the temporary support) can be improved.

The thermoplastic resin composition layer means an aspect in which the alkali-soluble resin in the photosensitive resin composition layer is a thermoplastic resin.

The thermoplastic resin may be alkali-soluble. That is, it may be a resin that exhibits thermoplasticity and alkali solubility (hereinafter, also referred to as an “alkali-soluble thermoplastic resin”).

The thermoplastic resin composition layer may contain another thermoplastic resin in addition to the alkali-soluble thermoplastic resin.

<Alkali-Soluble Thermoplastic Resin>

Examples of the alkali-soluble thermoplastic resin include an acrylic resin, a polystyrene resin, a styrene-acrylic copolymer, a polyurethane resin, polyvinyl alcohol, polyvinyl formal, a polyamide resin, a polyester resin, an epoxy resin, a polyacetal resin, a polyhydroxystyrene resin, a polyimide resin, a polybenzoxazole resin, a polysiloxane resin, polyethyleneimine, polyallylamine, and polyalkylene glycol.

The alkali-soluble thermoplastic resin is preferably an acrylic resin from the viewpoint of developability and adhesiveness to an adjacent layer.

Here, the acrylic resin means a resin having at least one constitutional unit selected from the group consisting of a constitutional unit derived from (meth)acrylic acid, a constitutional unit derived from a (meth)acrylic acid ester, and a constitutional unit derived from a (meth)acrylic acid amide.

In the acrylic resin, the total content of the constitutional unit derived from (meth)acrylic acid, the constitutional unit derived from a (meth)acrylic acid ester, and the constitutional unit derived from a (meth)acrylic acid amide is preferably 30% by mass or more and more preferably 50% by mass or more with respect to the total mass the acrylic resin. Among the above, the total content of the constitutional unit derived from (meth)acrylic acid and the constitutional unit derived from a (meth)acrylic acid ester is preferably 30% to 100% by mass and more preferably 50% to 100% by mass with respect to the total mass of the acrylic resin.

Further, the alkali-soluble thermoplastic resin is preferably a polymer having an acid group.

Examples of the acid group include a carboxy group, a sulfo group, a phosphoric acid group, and a phosphonic acid group, where a carboxy group is preferable.

From the viewpoint of developability, the acid value of the alkali-soluble thermoplastic resin is preferably 60 mgKOH/g or more.

The upper limit of the acid value of the alkali-soluble thermoplastic resin is not particularly limited; however, it is preferably 300 mgKOH/g or less, more preferably 250 mgKOH/g or less, still more preferably 200 mgKOH/g or less, and particularly preferably 150 mgKOH/g or less.

The alkali-soluble thermoplastic resin (preferably, a carboxy group-containing acrylic resin) having an acid value of 60 mgKOH/g or more is not particularly limited and can be appropriately selected from known resins and used.

Examples thereof include an alkali-soluble resin which is the carboxy group-containing acrylic resin having an acid value of 60 mgKOH/g or more among the polymers described in paragraph [0025] of JP2011-095716A, the carboxy group-containing acrylic resin having an acid value of 60 mgKOH/g or more among the polymers described in paragraphs [0033] to [0052] of JP2010-237589A, and the carboxy group-containing acrylic resin having an acid value of 60 mgKOH/g or more among the binder polymers described in paragraphs [0053] to [0068] of JP2016-224162A.

The copolymerization ratio of the constitutional unit having a carboxy group in the above-described carboxy group-containing acrylic resin is preferably 5% to 50% by mass, more preferably 10% to 40% by mass, and still more preferably 12% to 30% by mass, with respect to the total mass of the acrylic resin.

The alkali-soluble thermoplastic resin is particularly preferably an acrylic resin having a constitutional unit derived from (meth)acrylic acid from the viewpoints of developability and adhesiveness to an adjacent layer.

The alkali-soluble thermoplastic resin may have a reactive group.

It suffices that the reactive group is any addition-polymerizable group. Examples of the reactive group include an ethylenically unsaturated group; a polycondensable group such as a hydroxy group or a carboxy group; and a polyaddition reactive group such as an epoxy group or a (blocked) isocyanate group.

The weight-average molecular weight (Mw) of the alkali-soluble thermoplastic resin is preferably 1,000 or more, more preferably 10,000 to 100,000, and still more preferably 20,000 to 50,000.

One kind of alkali-soluble thermoplastic resin may be used alone, or two or more kinds thereof may be used.

From the viewpoint of developability and adhesiveness to an adjacent layer, the content of the alkali-soluble thermoplastic resin is preferably 10.00% to 99.00% by mass, more preferably 20.00% to 90.00%, still more preferably 40.00% to 80.00% by mass, and particularly preferably 50.00% to 75.00% by mass, with respect to the total mass of the thermoplastic resin composition layer.

<Coloring Agent>

The thermoplastic resin composition layer preferably contains a coloring agent (hereinafter, simply also referred to as a “coloring agent B”) that has a maximum absorption wavelength of 450 nm or more in a wavelength range of 400 to 780 nm at the time of color development, where the maximum absorption wavelength is changed by an acid, a base, or a radical.

The preferred aspect of the coloring agent B is the same as the preferred aspect of the coloring agent N described above, except for the points described later.

From the viewpoints of the visibility of the exposed portion and the non-exposed portion and the resolution, the coloring agent B is preferably a coloring agent of which the maximum absorption wavelength is changed by an acid or a radical, and more preferably a coloring agent of which the maximum absorption wavelength is changed by an acid.

From the viewpoints of the visibility of the exposed portion and the non-exposed portion and the resolution, the thermoplastic resin composition layer preferably contains both a coloring agent of which the maximum absorption wavelength is changed by an acid as the coloring agent B and a compound that generates an acid due to light described later.

One kind of the coloring agent B may be used alone, or two or more kinds thereof may be used.

From the viewpoint of visibility of the exposed portion and the non-exposed portion, the content of the coloring agent B is preferably 0.2% by mass or more, more preferably 0.2% to 6.0% by mass, still more preferably 0.2% to 5.0% by mass, and particularly preferably 0.25% to 3.0% by mass, with respect to the total mass of the thermoplastic resin composition layer.

Here, the content of the coloring agent B means the content of the coloring agent in a case where the whole coloring agent B contained in the thermoplastic resin composition layer is in a colored state. Hereinafter, a method of quantifying the content of the coloring agent B will be described by taking a coloring agent that develops color by a radical as an example. A solution obtained by dissolving 0.001 g of the coloring agent in 100 mL of methyl ethyl ketone, and a solution obtained by dissolving 0.01 g of the coloring agent therein are prepared. A photoradical polymerization initiator Irgacure OXE01 (product name, BASF Japan Ltd.) is added to each of the obtained solutions, and radicals are generated by the irradiation with light of 365 nm to bring the whole coloring agent into a colored state. Then, in the atmospheric air, the absorbance of each solution having a liquid temperature of 25° C. is measured using a spectrophotometer (UV3100, manufactured by Shimadzu Corporation), and a calibration curve is prepared.

Next, the absorbance of the solution in which the whole coloring agent has been caused to develop a color is measured by the same method as the above except that 0.1 g of the thermoplastic resin composition layer is dissolved in methyl ethyl ketone instead of the coloring agent. From the obtained absorbance of the solution containing the thermoplastic resin composition layer, the amount of the coloring agent with respect to the total mass of the thermoplastic resin composition layer is calculated based on the calibration curve.

<Compound that Generates Acid, Base, or Radical Due to Light>

The thermoplastic resin composition may contain a compound that generates an acid, a base, or a radical due to light (hereinafter, also simply referred to as a “compound C”).

The compound C is preferably a compound that generates an acid, a base, or a radical by receiving an actinic ray such as an ultraviolet ray or a visible ray.

As the compound C, a known photoacid generator, a known photobase generator, and a known photoradical polymerization initiator (photoradical generator) can be used. Among the above, a photoacid generator is preferable.

(Photoacid Generator)

Examples of the photoacid generator include a photocationic polymerization initiator which may be contained in the above-described photosensitive resin composition layer, and the same applies to the preferred aspect thereof except for the points described later.

From the viewpoints of sensitivity and resolution, the photoacid generator preferably contains at least one compound selected from the group consisting of an onium salt compound and an oxime sulfonate compound, and from the viewpoints of sensitivity, resolution, and adhesiveness, it more preferably contains an oxime sulfonate compound.

Further, the photoacid generator is preferably a photoacid generator having the following structure.

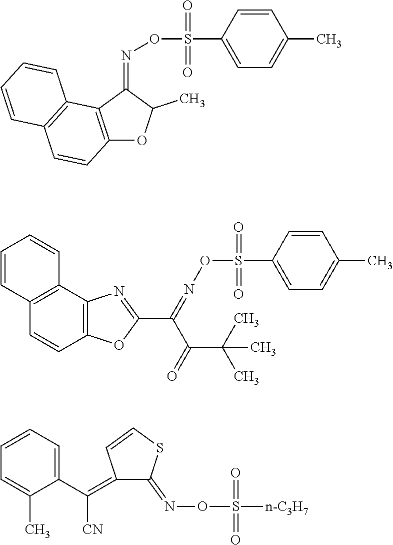

(Photoradical Polymerization Initiator)

Examples of the photoradical polymerization initiator include a photoradical polymerization initiator which may be contained in the above-described photosensitive resin composition layer, and the same applies to the preferred aspect thereof.

(Photobase Generator)

The photobase generator is not particularly limited as long as it is a known photobase generator, and examples thereof include 2-nitrobenzylcyclohexylcarbamate, triphenyl methanol, O-carbamoylhydroxylamide, O-carbamoyloxime, [[(2,6-dinitrobenzyl)oxy]carbonyl]cyclohexylamine, bis[[(2-nitrobenzyl)oxy]carbonyl]hexane-1,6-diamine, 4-(methylthiobenzoyl)-1-methyl-1-morpholinoethane, (4-morpholinobenzoyl)-1-benzyl-1-dimethylaminopropane, N-(2-nitrobenzyloxycarbonyl)pyrrolidine, hexaammine cobalt (III) tris(triphenylmethylborate), 2-benzyl-2-dimethylamino-1-(4-morpholinophenyl)-butanone, 2,6-dimethyl-3,5-diacetyl-4-(2-nitrophenyl)-1,4-dihydropyridine, and 2,6-dimethyl-3,5-diacetyl-4-(2,4-dinitrophenyl)-1,4-dihydropyridine.

One kind of the compound C may be used alone, or two or more kinds thereof may be used.

From the viewpoints of the visibility of the exposed portion and the non-exposed portion and the resolution, the content of the compound C is preferably 0.1% to 10% by mass and more preferably 0.5% to 5% by mass with respect to the total mass of the thermoplastic resin composition layer.

<Plasticizer>

The thermoplastic resin composition layer preferably contains a plasticizer from the viewpoints of adhesiveness to an adjacent layer, resolution, and developability.

The plasticizer preferably has a molecular weight (a weight-average molecular weight in a case where the plasticizer is an oligomer or a polymer and has a molecular weight distribution) smaller than that of the alkali-soluble resin. The molecular weight (the weight-average molecular weight) of the plasticizer is preferably 200 to 2,000.

The plasticizer is not particularly limited as long as it is a compound that is compatible with an alkali-soluble thermoplastic resin and exhibits plasticity. However, from the viewpoint of imparting plasticity, the plasticizer preferably has an oxyalkylene group in the molecule, and it is more preferably a polyalkylene glycol compound. The oxyalkylene group contained in the plasticizer more preferably has a polyethyleneoxy structure or a polypropyleneoxy structure.

In addition, the plasticizer preferably contains an (meth)acrylate compound from the viewpoints of resolution and storage stability. From the viewpoint of compatibility, resolution, and adhesiveness to an adjacent layer, it is more preferable that the alkali-soluble resin is an acrylic resin and the plasticizer contains a (meth)acrylate compound.

Examples of the (meth)acrylate compound that is used as the plasticizer include the (meth)acrylate compound described as the polymerizable compound contained in the photosensitive resin composition layer described above.

In a transfer film, in a case where the thermoplastic resin composition layer and the photosensitive resin composition layer are laminated in direct contact with each other, it is preferable that both the thermoplastic resin composition layer and the photosensitive resin composition layer contain the same (meth)acrylate compound. This is due to the reason that in a case where the thermoplastic resin composition layer and the photosensitive resin composition layer contain the same (meth)acrylate compound, the diffusion of components between the layers is suppressed and the storage stability is improved.

In a case where the thermoplastic resin composition layer contains a (meth)acrylate compound as a plasticizer, it is preferable that the (meth)acrylate compound does not polymerize even in the exposed portion after exposure from the viewpoint of adhesiveness to a layer adjacent to the thermoplastic resin composition layer.

In addition, the (meth)acrylate compound that is used as a plasticizer is preferably a polyfunctional (meth)acrylate compound having two or more a (meth)acryloyl groups in one molecule from the viewpoints of the resolution of the thermoplastic resin composition layer, the adhesiveness to an adjacent layer, and the developability.

Further, the (meth)acrylate compound that is used as a plasticizer is also preferably an (meth)acrylate compound having an acid group or a urethane (meth)acrylate compound.

One kind of plasticizer may be used alone, or two or more kinds thereof may be used.

From the viewpoints of the resolution of the thermoplastic resin composition layer, the adhesiveness to an adjacent layer, and the developability, the content of the plasticizer is preferably 1% to 70% by mass, more preferably 10% to 60% by mass, and still more preferably 15% to 50% by mass, with respect to the total mass of the thermoplastic resin composition layer.

<Sensitizing Agent>

The thermoplastic resin composition layer may contain a sensitizing agent.

The sensitizing agent is not particularly limited, and examples thereof include a sensitizing agent which may be contained in the photosensitive resin composition layer described above.

One kind of sensitizing agent may be used alone, or two or more kinds thereof may be used.

The content of the sensitizing agent can be appropriately selected depending on the intended purpose. However, it is preferably 0.01% to 5% by mass and more preferably 0.05% to 1% by mass with respect to the total mass of the thermoplastic resin composition layer from the viewpoints of the improvement of the sensitivity to the light source and the visibility of the exposed portion and the non-exposed portion.

<Additive>

In addition to those described above, the thermoplastic resin composition layer may contain a known additive as necessary.

In addition, the thermoplastic resin composition layer is described in paragraphs [0189] to [0193] of JP2014-085643A, and the content described in this publication is incorporated in the present specification.

<Physical Properties of Thermoplastic Resin Composition Layer>

(Film Thickness)

The layer thickness of the thermoplastic resin composition layer is not particularly limited; however, it is preferably 1 μm or more and more preferably 2 μm or more from the viewpoint of adhesiveness to an adjacent layer. The upper limit is not particularly limited. However, it is preferably 20 μm or less, more preferably 10 μm or less, and still more preferably 8 μm or less from the viewpoints of developability and resolution.

(Impurity and the Like)

The thermoplastic resin composition layer may include a predetermined amount of impurities.

The impurities are not particularly limited, and examples thereof include impurities which may be contained in the above-described photosensitive resin composition layer, and the same applies to the suitable range thereof.

(Residual Monomer)

The thermoplastic resin composition layer may contain a residual monomer of each structural unit of the above-described alkali-soluble thermoplastic resin.

The preferred range of the content of the residual monomer is the same as the content of the residual monomer which may be contained in the photosensitive resin composition layer.

[Coloration Resin Composition Layer]

The resin composition layer may be a coloration resin composition layer.

In recent years, a liquid crystal display window included in an electronic device may be attached with a cover glass having a black frame-shaped light shielding layer formed on the peripheral portion of the back surface of a transparent glass substrate or the like in order to protect the liquid crystal display window. A coloration resin composition layer can be used for forming such a light shielding layer.

The coloration resin composition layer contains a pigment.

The coloration resin composition layer may be a coloration resin composition layer that further contains a pigment, in addition to the resin (for example, the polymer P, the polymer A, or the like), the polymerizable compound, and the block copolymer and/or the compound (1). The coloration resin composition layer is also preferable to further contain a polymerization initiator, in addition to the resin (for example, the polymer P, the polymer A, or the like), the polymerizable compound, the pigment, and the block copolymer and/or the compound (1).

A pigment may be further added to each of the above-described resin composition layers to obtain a coloration resin composition layer.

For example, as described above, a pigment (or a pigment dispersion liquid) is added to the above-described photosensitive resin composition layer, thereby capable of being used as the coloration resin composition layer. That is, the photosensitive resin composition layer described above may be used as a photosensitive resin composition layer which is a coloration resin composition layer.

Similarly, each of the above-described resin composition layers may be used as a coloration resin composition layer to which a pigment has been added. For example, the photosensitive resin composition layer described above may be a coloration resin composition layer containing a pigment, as described above. That is, the photosensitive resin composition layer described above may be a photosensitive resin composition layer that is a coloration resin composition layer.

<Pigment>

The pigment contained in the coloration resin composition layer may be appropriately selected depending on the desired color tone, and it can be selected from a black pigment, a white pigment, and chromatic pigments other than black and white. Among them, in a case of forming a black pattern, a black pigment is suitably selected as the pigment.

As the black pigment, a known black pigment (an organic pigment, an inorganic pigment, or the like) can be appropriately selected as long as the effect of the present disclosure is not impaired. Among them, from the viewpoint of optical density, suitable examples of the black pigment include carbon black, titanium oxide, titanium carbide, iron oxide, and graphite, where carbon black is particularly preferable. From the viewpoint of surface resistance, the carbon black is preferably a carbon black in which at least a part of the surface is coated with a resin.

The black pigment (preferably carbon black) is preferably used in a form of a pigment dispersion liquid.

The dispersion liquid may be a dispersion liquid prepared by adding a mixture obtained by mixing in advance a black pigment and a pigment dispersing agent to an organic solvent (or a vehicle) and dispersing it with a disperser. The pigment dispersing agent may be selected depending on the pigment and the solvent, and for example, a commercially available dispersing agent can be used. It is noted that the vehicle refers to a medium portion which disperses a pigment in a case where the pigment is made to be a pigment dispersion liquid, where the vehicle is liquid and contains a binder component that holds the black pigment in a dispersed state and a solvent component (an organic solvent) that dissolves and dilutes the binder component.

The disperser is not particularly limited, and examples thereof include known dispersers such as a kneader, a roll mill, an attritor, a super mill, a dissolver, a homogenization mixer, and a sand mill. Further, fine pulverization may be carried out by mechanical grinding using frictional force. Regarding the disperser and fine pulverization, the description in “Encyclopedia of Pigments” (Kunizo Asakura, First Edition, Asakura Publishing Co., Ltd., 2000, 438, 310) can be referred to.

From the viewpoint of dispersion stability, the particle diameter of the black pigment is preferably 0.001 to 0.1 μm and more preferably 0.01 to 0.08 μm in terms of number average particle diameter.

Here, the particle diameter refers to a diameter of a circle in a case where the area of the pigment particles is determined from the photographic image of the pigment particles captured with an electronic microscope and a circle having the same area as the area of the pigment particles is assumed, and the number average particle diameter is an average value obtained by determining the above particle diameter for any 100 particles and averaging the determined diameters of the 100 particles.

As the pigment other than the black pigment, the white pigments described in paragraphs [0015] and [0114] of JP2005-007765A can be used as the white pigment. Specifically, among the white pigments, the inorganic pigment is preferably titanium oxide, zinc oxide, lithopone, light calcium carbonate, white carbon, aluminum oxide, aluminum hydroxide, or barium sulfate, more preferably titanium oxide or zinc oxide, and still more preferably titanium oxide. The inorganic pigment is preferably a rutile-type or anatase-type titanium oxide, and particularly preferably a rutile-type titanium oxide.

Further, the surface of titanium oxide may be subjected to a silica treatment, an alumina treatment, a titania treatment, a zirconia treatment, or an organic substance treatment, or may be subjected to two or more treatments. As a result, the catalytic activity of titanium oxide is suppressed, and thus heat resistance, light resistance, and the like are improved.

From the viewpoint of reducing the thickness of the photosensitive resin composition layer after heating, the surface treatment of the surface of titanium oxide is preferably at least one of an alumina treatment or a zirconia treatment, and particularly preferably both alumina treatment and zirconia treatment.

In addition, from the viewpoint of transferability, it is also preferable that the coloration resin composition layer further contains a chromatic pigment other than the black pigment and the white pigment. In a case where a chromatic pigment is contained, it is desirable that the chromatic pigment is well dispersed in the coloration resin layer, and from such a viewpoint, the particle diameter is preferably 0.1 μm or less and more preferably 0.08 μm or less. Examples of the chromatic pigment include Victoria pure blue BO (Color Index (hereinafter C.I.) 42595), Auramine (C.I. 41000), Fat black HB (C.I. 26150), Monolite yellow GT (C.I. Pigment yellow 12), Permanent yellow GR (C.I. Pigment yellow 17), Permanent yellow HR (C.I. Pigment yellow 83), Permanent carmine FBB (C.I. Pigment red 146), Hoster balm red ESB (C.I. Pigment violet 19), Permanent ruby FBH (C.I. Pigment red 11), Pastel pink B supra (C.I. Pigment red 81), Monastral first blue (C.I. Pigment blue 15), Monolite first black B (C.I. Pigment black 1), and Carbon, as well as C.I. Pigment red 97, C.I. Pigment red 122, C.I. Pigment red 149, C.I. Pigment red 168, C.I. Pigment red 177, C.I. Pigment red 180, C.I. Pigment red 192, C.I. Pigment red 215, C.I. Pigment Green 7, C.I. Pigment blue 15.1, C.I. Pigment blue 15.4, C.I. Pigment blue 22, C.I. Pigment blue 60, C.I. Pigment blue 64, and C.I. Pigment violet 23. Among them, C.I. Pigment red 177 is preferable.

The content of the pigment is preferably more than 3% by mass and 40% by mass or less, more preferably more than 3% by mass and 35% by mass or less, still more preferably more than 5% by mass and 35% by mass or less, and particularly preferably 10% to 35% by mass, with respect to the total mass of the coloration resin composition layer.

In a case where pigments (a white pigment and a chromatic pigment) other than the black pigment are contained, the content thereof is preferably 30% by mass or less, preferably 1% by mass to 20% by mass, and still more preferably 3% by mass to 15% by mass, with respect to the black pigment.

<Physical Properties of the Formed Layer>

(Film Thickness)

The layer thickness (the film thickness) of the coloration resin composition layer is 0.1 to 300 μm in a large number of cases, and it is preferably 0.2 to 100 m, more preferably 0.5 to 50 m, still more preferably 0.5 to 15 m, particularly preferably 0.5 to 10 m, and most preferably 0.5 to 8 am.

(Impurity and the Like)

The coloration resin composition layer may include a predetermined amount of impurities.

The impurities are not particularly limited, and examples thereof include impurities which may be contained in the above-described photosensitive resin composition layer, and the same applies to the suitable range thereof.

(Residual Monomer)

The coloration resin composition layer may contain a residual monomer of each structural unit of the above-described resin (for example, the polymer P, the polymer A, or the alkali-soluble resin).

The preferred range of the content of the residual monomer is the same as the content of the residual monomer which may be contained in the photosensitive resin composition layer.

[Water-Soluble Resin Composition Layer]

The resin composition layer may be a water-soluble resin composition layer.

The water-soluble resin composition layer is a resin composition layer containing a block copolymer and/or the compound (1), as well as a water-soluble resin.

Examples of the resin capable of being used as the water-soluble resin include resins such as a polyvinyl alcohol-based resin, a polyvinyl pyrrolidone-based resin, a cellulose-based resin, an acrylamide-based resin, a polyethylene oxide-based resin, gelatin, a vinyl ether-based resin, a polyamide resin, and a copolymer thereof.

In a case where the water-soluble resin composition layer containing a water-soluble resin is used as the interlayer, this water-soluble resin is preferably a resin different from the resin contained in the adjacent layer (for example, a resin different from the polymer P, the polymer A, and the alkali-soluble thermoplastic resin) from the viewpoint of suppressing the mixing of components between a plurality of layers.

From the viewpoints of oxygen blocking properties and suppressing mixing of components in a case of coating a plurality of layers and in a case of storing after coating, the water-soluble resin composition layer preferably contains polyvinyl alcohol and more preferably contains both polyvinyl alcohol and polyvinyl pyrrolidone.

One kind of water-soluble resin composition layer may be used alone, or two or more kinds thereof may be used.

The content of the water-soluble resin is not particularly limited. However, from the viewpoints of oxygen blocking properties and suppressing mixing of components in a case of coating a plurality of layers and in a case of storing after coating, it is preferably 50.0% by mass or more and less than 100.0% by mass, more preferably 70.0% by mass or more and less than 100.0% by mass, still more preferably 80.0% by mass or more and less than 100.0% by mass, and particularly preferably 90.0% by mass or more and less than 100.0% by mass, with respect to the total mass of the water-soluble resin composition layer.

The method for forming the water-soluble resin composition layer is not particularly limited, which can be carried out, for example, in the same manner as the method using the photosensitive resin composition.

A method of forming the interlayer (the water-soluble resin layer containing a water-soluble resin) is not particularly limited. Examples thereof include a method of forming a water-soluble resin composition layer by applying the water-soluble resin composition onto the surface of the thermoplastic resin composition layer or the photosensitive resin composition layer and drying the coating film of the water-soluble resin composition.

The layer thickness of the water-soluble resin composition layer is not particularly limited; however, it is preferably 0.1 to 5.0 μm and more preferably 0.5 to 3.0 m. This is due to the reason that in a case where the thickness of the water-soluble resin composition layer is within the above range, it is possible to suppress the mixing of components in a case of coating a plurality of layers and in a case of storing after the coating, without reducing the oxygen blocking properties, and it is possible to suppress an increase in the time for removing the water-soluble resin layer at the time of development.

(Impurity and the Like)

The water-soluble resin composition layer may include a predetermined amount of impurities.

The impurities are not particularly limited, and examples thereof include impurities which may be contained in the above-described photosensitive resin composition layer, and the same applies to the suitable range thereof.

(Residual Monomer)

The water-soluble resin composition layer may contain a residual monomer of each structural unit of the above-described resin (for example, the water-soluble resin, the polymer P, the polymer A, or the alkali-soluble resin).

The preferred range of the content of the residual monomer is the same as the content of the residual monomer which may be contained in the photosensitive resin composition layer.

The resin composition layer is, for example, preferably a layer consisting of only the components contained in the above-described resin composition layer.

Specifically, the resin composition layer according to the embodiment of the present invention is a layer consisting of only components that are contained in, for example, the photosensitive resin composition layer, the thermoplastic resin composition layer, the coloration resin composition layer, and/or the water-soluble resin composition layer, which are described above.

Examples of the resin composition layer other than the present invention include a resin composition layer consisting of a component other than the components contained in each of the following resin composition layers in the photosensitive resin composition layer, the thermoplastic resin composition layer, the coloration resin composition layer, and/or the water-soluble resin composition layer, which are described above.

[Cover Film]

The transfer film preferably has a cover film that is in contact with a surface of each resin composition layer that does not face the temporary support.

Hereinafter, in the present specification, a surface of the composition layer facing the temporary support is also referred to as a “first surface”, and a surface on a side opposite to the first surface is also referred to as a “second surface”.

Examples of the material that constitutes the cover film include a resin film and paper, where a resin film is preferable from the viewpoints of hardness and flexibility.

Examples of the resin film include a polyethylene film, a polypropylene film, a polyethylene terephthalate film, a cellulose triacetate film, a polystyrene film, and a polycarbonate film. Among them, a polyethylene film, a polypropylene film, or a polyethylene terephthalate film is preferable.

The thickness of the cover film is not particularly limited; however, it is preferably 5 to 100 μm and more preferably 10 to 50 m.

In addition, the arithmetic average roughness Ra value of the surface of the cover film in contact with each resin composition layer (hereinafter, also simply referred to as “the surface of the cover film”) is preferably 0.3 μm or less, more preferably 0.1 μm or less, and still more preferably 0.05 μm or less since the resolution is more excellent. This is conceived to be because in a case where the Ra value on the surface of the cover film is in the above range, the uniformity of the layer thickness of the resin pattern to be formed is improved.

The lower limit of the Ra value of the surface of the cover film is not particularly limited; however, it is preferably 0.001 μm or more.

The Ra value of the surface of the cover film is measured by the following method.

Using a three-dimensional optical profiler (New View7300, manufactured by Zygo Corporation), the surface of the cover film is measured under the following conditions to obtain a surface profile of the optical film.

As the measurement and analysis software, Microscope Application of MetroPro ver. 8.3.2 is used. Next, the Surface Map screen is displayed with the above analysis software, and the histogram data is obtained in the Surface Map screen. From the obtained histogram data, the arithmetic average roughness is calculated, and the Ra value of the surface of the cover film is obtained.

In a case where the cover film is affixed to the transfer film, the cover film may be peeled from the transfer film to measure the Ra value of the surface on which the peeling has been carried out.

[Manufacturing Method for Transfer Film]

The manufacturing method for the transfer film is not particularly limited, and a known manufacturing method, for example, a known method of forming each resin composition layer can be used.

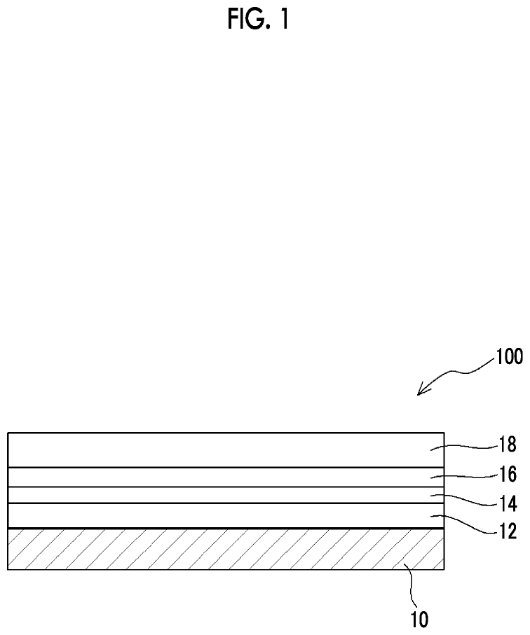

Hereinafter, a manufacturing method for a transfer film will be described with reference to FIG. 1. The transfer film is not limited to that having the configuration illustrated in FIG. 1.

FIG. 1 is a schematic view illustrating an example of a configuration of a transfer film. A transfer film 100 illustrated in FIG. 1 has a configuration in which a temporary support 10, a thermoplastic resin composition layer 12, an interlayer 14, a photosensitive resin composition layer 16, and a cover film 18 are laminated in this order.

It is noted that the transfer film includes the interlayer 14, it is possible to suppress the mixing of components in a case where a plurality of layers are coated and in a case of storage after the coating.

Examples of the interlayer include the oxygen blocking layer having an oxygen blocking function, which is described as a “separation layer” in JP1993-072724A (JP-H5-072724A). It is preferable that the interlayer is an oxygen blocking layer since the sensitivity at the time of exposure is improved, the time load of the exposure machine is reduced, and the productivity is improved.

The oxygen blocking layer that is used as the interlayer may be appropriately selected from known layers described in the above-described publications. Among them, it is preferably an oxygen blocking layer that exhibits low oxygen permeability and is dispersed or dissolved in water or an alkaline aqueous solution (an aqueous solution of 1% by mass sodium carbonate at 22° C.).

The interlayer and the resin composition capable of forming the interlayer will be described in detail later.

Examples of the manufacturing method for the transfer film 100 include a method including a step of applying a thermoplastic resin composition onto the surface of the temporary support 10 and then drying the coating film of the thermoplastic resin composition to form the thermoplastic resin composition layer 12, a step of applying an interlayer forming resin composition onto the surface of the thermoplastic resin composition layer 12 and then drying the coating film of the interlayer forming resin composition to form the interlayer 14, and a step of applying a photosensitive resin composition onto the surface of the interlayer 14 and then drying the coating film of the photosensitive resin composition to form the photosensitive resin composition layer 16.

The thermoplastic resin composition is a composition for forming the above-described thermoplastic resin composition layer, and it may contain the above-described various components. The thermoplastic resin composition may contain a solvent in order to improve coatability.

The photosensitive resin composition is a composition for forming the above-described photosensitive resin composition layer, and it may contain the above-described various components. The photosensitive resin composition may contain a solvent in order to improve coatability.

The cover film 18 is subjected to pressure bonding to the photosensitive resin composition layer 16 of the laminate manufactured by the manufacturing method described above, whereby the transfer film 100 is manufactured.

It is preferable that the manufacturing method for a transfer film according to the embodiment of the present invention includes a step of providing a cover film 18 to be in contact with a second surface of the photosensitive resin composition layer 16, whereby the transfer film 100 including the temporary support 10, the thermoplastic resin composition layer 12, the interlayer 14, the photosensitive resin composition layer 16, and the cover film 18 is manufactured.

After manufacturing the transfer film 100 according to the above-described manufacturing method, the transfer film 100 may be wound backward to produce and store the transfer film having a form of a roll. The transfer film having a roll form can be provided as it is in the affixing step to a substrate by the roll-to-roll method described later.

In the above-described manufacturing method, although both the thermoplastic resin composition layer and the photosensitive resin composition layer are the resin composition layer according to the embodiment of the present invention, it suffices that at least one of these is the resin composition layer according to the embodiment of the present invention, where one thereof may be a resin composition layer other than the present invention (for example, a thermoplastic resin composition layer other than the present invention and/or a photosensitive resin composition layer other than the present invention).

Similarly, in the transfer film 100, it suffices that at least one of the thermoplastic resin composition layer 12 and the photosensitive resin composition layer 16 is the resin composition layer according to the embodiment of the present invention, where the other thereof may be the resin composition layer other than the present invention.

[Interlayer]

The interlayer is preferably a water-soluble resin composition layer.

The aspect of the water-soluble resin composition layer is as described above.

[Refractive Index Adjusting Layer]

The transfer film may have a refractive index adjusting layer.

The position of the refractive index adjusting layer is not particularly limited; however, it is preferably disposed in contact with each resin composition layer. Among the above, the transfer film preferably has a temporary support, the photosensitive resin composition layer or thermoplastic resin composition layer, and the refractive index adjusting layer in this order.

In a case where the transfer film further includes the cover film described above, it is preferable to have the temporary support, the photosensitive resin composition layer or thermoplastic resin composition layer, the refractive index adjusting layer, and the cover film in this order.

As the refractive index adjusting layer, a known refractive index adjusting layer can be applied. Examples of the material contained in the refractive index adjusting layer include a resin and particles.

Examples of the resin include a resin which may be contained in the resin composition layer described above, where the polymer P and/or the water-soluble resin is preferable.

In addition, in the present specification, in a case where the refractive index adjusting layer contains, for example, a water-soluble resin, the refractive index adjusting layer also corresponds to the water-soluble resin composition layer.

Examples of the particles include zirconium oxide particles (ZrO₂ particles), niobium oxide particles (Nb₂O₅ particles), titanium oxide particles (TiO₂ particles), and silicon dioxide particles (SiO₂ particles).

In addition, it is preferable that the refractive index adjusting layer contains a metal oxidation inhibitor. In a case where the refractive index adjusting layer contains a metal oxidation inhibitor, the oxidation of a metal in contact with the refractive index adjusting layer can be suppressed.

The metal oxidation inhibitor is preferably, for example, a compound having an aromatic ring containing a nitrogen atom in the molecule. Examples of the metal oxidation inhibitor include imidazole, benzimidazole, tetrazole, mercaptothiadiazole, and benzotriazole.

The refractive index of the refractive index adjusting layer is preferably 1.60 or more and more preferably 1.63 or more.

The upper limit of the refractive index of the refractive index adjusting layer is preferably 2.10 or less and more preferably 1.85 or less.

The upper limit of the thickness of the refractive index adjusting layer is preferably 500 nm or less, more preferably 110 nm or less, and still more preferably 100 nm or less. The lower limit thereof is not particularly limited, and it is preferably 20 nm or more and more preferably 50 nm or more.

The thickness of the refractive index adjusting layer is calculated as an average value of any five points, measured by cross-sectional observation with a scanning electron microscope (SEM).

The refractive index adjusting layer may be a known refractive index adjusting layer, and examples thereof include the second resin layer disclosed in paragraphs [0200] to [0214] of JP2020-091322A.

An example of the aspect of the transfer film is shown below.

In each of the following configurations, one or more layers (the cover film and the like) may be removed or a layer may be further added between any layers, as desired.

(1) “Temporary support/thermoplastic resin composition layer/interlayer (water-soluble resin composition layer)/photosensitive resin composition layer/cover film”

(2) “Temporary support/thermoplastic resin composition layer/interlayer (water-soluble resin composition layer)/coloration resin composition layer/cover film”

(3) “Temporary support/thermoplastic resin composition layer/refractive index adjusting layer (water-soluble resin composition layer)/cover film”

(4) “Temporary support/photosensitive resin composition layer/cover film”

In the resin composition layers (layers other than the temporary support and the cover film) that constitute the transfer film having each of the above-described configurations, at least one layer of the thermoplastic resin layer or the photosensitive resin composition layer is the resin composition layer according to the embodiment of the present invention.

In each of the above configurations, it is also preferable that the photosensitive resin composition layer is a coloration resin composition layer.

[Manufacturing Method for Laminate and Manufacturing Method for Circuit Wire]

The present invention also relates to a manufacturing method for a laminate.

The manufacturing method for a laminate is not particularly limited as long as it is a manufacturing method for a laminate using the transfer film described above.

The manufacturing method for a laminate preferably includes an affixing step of bringing a substrate (preferably a substrate having conductivity) into contact with a surface (a surface of a composition layer) on a side opposite to a temporary support included in a transfer film and affixing the transfer film to the substrate (preferably the substrate having conductivity) to obtain a transfer film-attached substrate (hereinafter, also referred to as the “affixing step”), an exposure step of subjecting the resin composition layer to pattern exposure (hereinafter, also referred to as the “exposure step”), a development step of developing the exposed resin composition layer to form a resin pattern (hereinafter, also referred to the “development step”), and a peeling step of peeling the temporary support from the transfer film-attached substrate, between the affixing step and the exposure step or between the exposure step and the development step (hereinafter, also referred to as the “peeling step”).

It is noted that the resin composition layer that is subjected to pattern exposure may consist of one layer alone or may consist of two or more layers, where at least one layer constituting the resin composition layer is the resin composition layer according to the embodiment of the present invention.

In addition, the resin composition layer that is subjected to pattern exposure preferably includes at least one photosensitive resin composition layer (the photosensitive resin composition layer according to the embodiment of the present invention or a photosensitive resin composition layer other than the present invention). The photosensitive resin composition layer may be a coloration resin composition layer.

The manufacturing method for a circuit wire is not particularly limited as long as it is a manufacturing method for a circuit wire using the transfer film described above.

In a laminate in which a substrate, a conductive layer (a conductive layer included in the substrate), and a resin pattern manufactured by using the above-described transfer film are laminated in this order, the manufacturing method for a circuit wire is preferably a method including a step (hereinafter, also referred to as an “etching step”) of subjecting the conductive layer present in a region where the resin pattern is not disposed to an etching treatment.

That is, the manufacturing method for a circuit wire is preferably a method including an affixing step of bringing a substrate having a conductive layer into contact with a surface (a composition layer) on a side opposite to a temporary support included in a transfer film and affixing the transfer film to the substrate having the conductive layer to obtain a transfer film-attached substrate (hereinafter, also referred to as the “affixing step”), an exposure step of subjecting the resin composition layer to pattern exposure (hereinafter, also referred to as the “exposure step”), a development step of developing the exposed resin composition layer to form a resin pattern (hereinafter, also referred to the “development step”), a step of subjecting the conductive layer present in a region where the resin pattern is not disposed to an etching treatment (hereinafter, also referred to as the “etching step”), and a peeling step of peeling the temporary support from the transfer film-attached substrate, between the affixing step and the exposure step or between the exposure step and the development step (hereinafter, also referred to as the “peeling step”).

The same as described above applies to the preferred form of the resin composition layer that is subjected to pattern exposure.

Hereinafter, each step included in the manufacturing method for a laminate and the manufacturing method for a circuit wire will be described. However, unless otherwise specified, the content of the description for each step included in the manufacturing method for a laminate shall also apply to the manufacturing method for a circuit wire.

[Affixing Step]

The manufacturing method for a laminate preferably includes an affixing step.

In the affixing step, it is preferable that a substrate (a conductive layer in a case where a conductive layer is provided on the surface of the substrate) is brought into contact with the surface of the transfer film on a side opposite to the temporary support, and the transfer film is subjected to pressure bonding to the substrate. Since the above aspect improves the adhesiveness between the resin composition layer and the substrate, it can be suitably used as an etching resist in a case where a conductive layer is etched by using a resin pattern on which a pattern is formed after the exposure and the development.

In a case where the transfer film includes a cover film, the cover film may be removed from the surface of the transfer film and then affixed.

The method of subjecting the substrate to pressure bonding to the transfer film is not particularly limited, and a known transfer method or a laminating method can be used.

The affixing of the transfer film to the substrate is preferably carried out by superposing the substrate on a surface of the transfer film on a side opposite to the temporary support and then applying pressure using a means such as a roll and carrying out heating. For affixing, it is possible to use a known laminator such as a laminator, a vacuum laminator, or an auto-cut laminator capable of further improving productivity.

The manufacturing method for a laminate including the affixing step and the manufacturing method for a circuit wire are preferably carried out according to a roll-to-roll method.

The roll-to-roll method refers to a method that includes, in a case of using a substrate capable of being wound backward and wound forward as the substrate, a step (hereinafter, also referred to as a “forward winding step”) of winding forward the substrate or a structure body including the substrate before any one of the steps included in the manufacturing method for a laminate or the manufacturing method for a circuit wire and a step (hereinafter, also referred to as a “backward winding step”) of winding backward the substrate or the structure body including the substrate after any one of the above steps, and at least any one of the steps (preferably all steps or all steps other than the heating step) is carried out while transporting the base material or the structure body including the substrate.

The forward winding method in the forward winding step and the backward winding method in the backward winding step are not particularly limited, and known methods may be used in the manufacturing method to which the roll-to-roll method is applied.

<Substrate>

As the substrate used for forming the resin pattern using the transfer film according to the embodiment of the present invention, a known substrate may be used; however, a substrate having a conductive layer is preferable, and it is more preferable to have a conductive layer on the surface of the substrate.

The substrate may have any layer other than the conductive layer, as necessary.

Examples of the base material that constitutes the substrate include glass, silicon, and a film.

The base material that constitutes the substrate is preferably transparent. In the present specification, “transparent” means that the transmittance of light having a wavelength of 400 to 700 nm is 80% or more.

In addition, the refractive index of the base material that constitutes the substrate is preferably 1.50 to 1.52.

Examples of the transparent glass base material include reinforced glass represented by Gorilla Glass manufactured by Corning Incorporated. Further, as the transparent glass base material, the materials used in JP2010-086684A, JP2010-152809A, and JP2010-257492A can be used.

In a case where a film base material is used as the base material, it is preferable to use a film base material having low optical distortion and/or high transparency. Examples of such a film base material include polyethylene terephthalate (PET), polyethylene naphthalate, polycarbonate, triacetyl cellulose, and a cycloolefin polymer.

The base material of the substrate is preferably a film base material in a case of being manufactured by a roll-to-roll method. Further, in a case where a circuit wire for a touch panel is manufactured by a roll-to-roll method, it is preferable that the base material is a sheet-shaped resin composition.

Examples of the conductive layer included in the substrate include a conductive layer that is used for a general circuit wire and a touch panel wire.

From the viewpoint of conductivity and thin wire forming properties, the conductive layer is preferably at least one layer selected from the group consisting of a metal layer, a conductive metal oxide layer, a graphene layer, a carbon nanotube layer, and a conductive polymer layer, more preferably a metal layer, and still more preferably a copper layer or a silver layer.

The substrate may have one conductive layer alone or may have two or more conductive layers. In a case of having two or more conductive layers, it is preferable to have conductive layers made of different materials.

Examples of the material of the conductive layer include a metal and a conductive metal oxide.

Examples of the metal include A1, Zn, Cu, Fe, Ni, Cr, Mo, Ag, and Au.

Examples of the conductive metal oxide include indium tin oxide (ITO), indium zinc oxide (IZO), and SiO₂.

In the present specification, “conductivity” means that the volume resistivity is less than 1×10⁶ Ωcm. The volume resistivity of the conductive metal oxide is preferably less than 1×10⁴ Ωcm.

In a case where a resin pattern is manufactured using a substrate having a plurality of conductive layers, it is preferable that at least one conductive layer among the plurality of conductive layers contains a conductive metal oxide.

The conductive layer is preferably an electrode pattern corresponding to a sensor of a visible part that is used in a capacitance type touch panel or a wire of a peripheral lead-out part.

[Exposure Step]

The manufacturing method for a laminate preferably includes, after the affixing step, a step (an exposure step) of subjecting the resin composition layer to pattern exposure.

The detailed arrangement and the specific size of the pattern in the pattern exposure are not particularly limited. At least a part of the pattern (preferably, a portion of the electrode pattern and/or lead-out wire of the touch panel) preferably contains a thin wire having a width of 20 μm or less and more preferably contains a thin wire having a width of 10 μm or less so that the display quality of the display device (for example, a touch panel) including an input device having a circuit wire manufactured according to the manufacturing method for a circuit wire improved and the area occupied by the lead-out wire is reduced.

The light source that is used for exposure can be appropriately selected and used as long as it is a light source that emits light having a wavelength (for example, 365 nm or 405 nm) with which the photosensitive resin composition layer can be exposed. Specific examples thereof include an ultra-high pressure mercury lamp, a high pressure mercury lamp, a metal halide lamp, and a light emitting diode (LED).

The exposure amount is preferably 5 to 200 mJ/cm² and more preferably 10 to 100 mJ/cm².

[Peeling Step]

The peeling step is a step of peeling the temporary support from the resin composition layer-attached substrate between the affixing step and the exposure step, or between the exposure step and the development step described later.

The peeling method is not particularly limited, and a mechanism similar to the cover film peeling mechanism described in paragraphs [0161] and [0162] of JP2010-072589A can be used.

As a result, in the exposure step, the pattern exposure may be carried out after the temporary support is peeled off from the resin composition layer, or the pattern exposure may be carried out through the temporary support before the temporary support is peeled off, and then the temporary support may be peeled off. In a case where the temporary support is peeled off before exposure, the mask may be exposed in a state of being brought into contact with the resin composition layer or may be exposed in a state of being in close proximity without being brought into contact with the resin composition layer. In a case where the temporary support is exposed without peeling, the mask may be exposed in a state of being brought into contact with the temporary support or may be exposed in a state of being in close proximity without being brought into contact with the temporary support. In order to prevent mask contamination due to contact between the composition layer and the mask and to avoid the influence of foreign substances adhered to the mask on the exposure, it is preferable to carry out pattern exposure without peeling off the temporary support. The exposure method can be carried out by appropriately selecting and using a contact exposure method in a case of contact exposure, and in a case of a non-contact exposure method, a proximity exposure method, a lens-based and mirror-based projection exposure method, and a direct exposure method using an exposure laser or the like. In a case of the lens-based or mirror-based projection exposure, an exposure machine having a proper numerical aperture (NA) of a lens in response to the required resolving power and the focal depth can be used. In a case of the direct exposure method, drawing may be carried out directly on the photosensitive resin composition layer, or reduced projection exposure may be carried out on the photosensitive resin composition layer through a lens. Further, the exposure may be carried out not only in the atmospheric air but also under reduced pressure or vacuum, or the exposure may be carried out by interposing a liquid such as water between the light source and the resin composition layer.

[Development Step]

The manufacturing method for a laminate preferably includes, after the exposure step, a step (a development step) of developing the exposed resin composition layer to form a resin pattern.

In a case where the resin composition layer includes a photosensitive resin composition layer (the photosensitive resin composition layer according to the embodiment of the present invention or a photosensitive resin composition layer other than the present invention), the resin composition layer undergoes a curing reaction according to the exposed pattern to form a cured film (a patterned cured film), and only the non-exposed portion of the resin composition layer can be removed with a developer (an alkali developer or the like).

In a case where the transfer film has, together with the photosensitive resin composition layer, a resin composition layer different from this, only a portion similar to the portion of the different resin composition layer, which is removed in the photosensitive resin composition layer, may be removed, or an entire portion thereof including a portion other than the portion removed in the photosensitive resin composition layer may be removed.

For example, in a case where the transfer film has the thermoplastic resin composition layer and/or the water-soluble resin composition layer together with the photosensitive resin composition layer, only the thermoplastic resin composition layer and/or the water-soluble resin composition layer of the non-exposed portion may be removed in the development step together with the photosensitive resin composition layer of the non-exposed portion. In addition, in the development step, the thermoplastic resin composition layer and/or the water-soluble resin composition layer in both regions of the exposed portion and the non-exposed portion may be removed in a form of being dissolved or dispersed in the developer.

In the resin pattern obtained after the development, a part or the whole thereof may be a layer obtained by causing the resin composition layer according to the embodiment of the present invention or to undergo a change such as a curing reaction. For example, in a case where the resin composition layer of the transfer film includes the photosensitive resin composition layer according to the embodiment of the present invention, a part or the whole of the resin pattern is a material obtained by subjecting the photosensitive resin composition layer according to the embodiment of the present invention to a curing reaction.

In addition, in the resin pattern obtained after the development, a layer obtained by causing the resin composition layer according to the embodiment of the present invention to undergo a change such as a curing reaction may not be included. That is, the resin pattern obtained after the development may consist of only a resin composition layer other than the present invention and/or a layer obtained by causing the resin composition other than the present invention to undergo a change such as a curing reaction.

Development of the exposed resin composition layer in the development step can be carried out using an alkali developer.

As the alkali developer, it is possible to use, for example, a known developer such as the developer described in JP1993-072724A (JP-H5-072724A).

The alkali developer is preferably an alkaline aqueous solution-based developer containing a compound having pKa=7 to 13 at a concentration of 0.05 to 5 mol/L (liter). The alkali developer may contain a water-soluble organic solvent and/or a surfactant. The alkali developer is also preferably the developer described in paragraph [0194] of WO2015/093271A. The content of the organic solvent in the alkali developer is preferably 0% by mass or more and less than 90% by mass with respect to the total mass of the developer.

The development method is not particularly limited, and it may be any of puddle development, shower development, shower, and spin development, and dip development. The shower development is a development treatment of removing the non-exposed portion by spraying a developer onto the resin composition layer after exposure with a shower.

After the development step, it is preferable to spray a cleaning agent with a shower to remove the development residue while rubbing it with a brush.

The liquid temperature of the developer is not particularly limited; however, it is preferably 20° C. to 40° C.

[Etching Step]

In a laminate in which a substrate, a conductive layer (a conductive layer included in the substrate), and a resin pattern (more preferably, a resin pattern manufactured according to the manufacturing method including the affixing step, the exposure step, and the development step) are laminated in this order, the manufacturing method for a circuit wire preferably contains a step (an “etching step”) of subjecting the conductive layer present in a region where the resin pattern is not disposed to an etching treatment.

In the etching step, the resin pattern formed from the resin composition layer is used as an etching resist to carry out an etching treatment of the conductive layer.

As the method of etching treatment, a known method can be applied, and examples thereof include the methods described in paragraphs [0209] and [0210] of JP2017-120435A and paragraphs [0048] to [0054] of JP2010-152155A, a wet etching method in which immersion in an etchant is carried out, and a dry etching method such as plasma etching.

As the etchant that is used for wet etching, an acidic or alkaline etchant may be appropriately selected according to the etching target.

Examples of the acidic etchant include an aqueous solution of an acidic component alone selected from hydrochloric acid, sulfuric acid, nitric acid, acetic acid, hydrofluoric acid, oxalic acid, and phosphoric acid, and a mixed aqueous solution of an acidic component with a salt selected from iron (III) chloride, ammonium fluoride, or potassium permanganate. The acidic component may be a component in which a plurality of acidic components are combined.

Examples of the alkaline etchant include an aqueous solution of an alkaline component alone selected from sodium hydroxide, potassium hydroxide, ammonia, an organic amine, and a salt of an organic amine (tetramethylammonium hydroxide or the like), and a mixed aqueous solution of an alkaline component with a salt (potassium permanganate or the like). The alkaline component may be a component in which a plurality of alkaline components are combined.

[Removal Step]

In the manufacturing method for a circuit wire, it is preferable to carry out a step (a removal step) of removing the remaining resin pattern.

The removal step is not particularly limited and can be carried out as necessary; however, it is preferably carried out after the etching step.

The method of removing the remaining resin pattern is not particularly limited; however, examples thereof include a method of carrying out removal by a chemical treatment, and a method of carrying out removal with a removing liquid is preferable.

Examples of the method of removing the resin composition layer include a method in which a substrate having the remaining resin pattern is immersed in a removing liquid under stirring, having a liquid temperature of preferably 30° C. to 80° C. and more preferably 50° C. to 80° C. for 1 to 30 minutes.

Examples of the removing liquid include a removing liquid in which an inorganic alkaline component or an organic alkaline component is dissolved in water, dimethyl sulfoxide, N-methylpyrrolidone, or a mixed solution thereof. Examples of the inorganic alkaline component include sodium hydroxide and potassium hydroxide. Examples of the organic alkaline component include a primary amine compound, a secondary amine compound, a tertiary amine compound, and a quaternary ammonium salt compound.

Further, a removing liquid may be used and then removed by a known method such as a spray method, a shower method, or a puddle method.

[Other Steps]

The manufacturing method for a circuit wire may include any steps (other steps) other than the above-described steps. Examples thereof include the following steps, which are not limited to these steps.

Further, examples of the exposure step, the development step, and the other steps, which are applicable to the manufacturing method for a circuit wire, include the steps described in paragraphs [0035] to [0051] of JP2006-023696A.

<Cover Film Peeling Step>

In a case where the transfer film includes a cover film, the manufacturing method for a laminate and the manufacturing method for a circuit wire preferably include a step of peeling the cover film from the transfer film. The method of peeling the cover film is not limited, and a known method can be applied.

<Step of Reducing Visible Light Reflectivity>

The manufacturing method for a circuit wire may include a step of carrying out a treatment of reducing the visible light reflectivity of a part or all of a plurality of conductive layers included in the base material.

Examples of the treatment of reducing the visible light reflectivity include an oxidation treatment. In a case where the base material has a conductive layer containing copper, the visible light reflectivity of the conductive layer can be reduced by subjecting copper to the oxidation treatment to obtain copper oxide and then blackening the conductive layer.

The treatment of reducing the visible light reflectivity is described in paragraphs [0017] to [0025] of JP2014-150118A and paragraphs [0041] and [0042], paragraph [0048], and paragraph [0058] of JP2013-206315A, and the contents described in these publications are incorporated in the present specification.

<Step of Forming Insulating Film and Step of Forming New Conductive Layer on Surface of Insulating Film>

The manufacturing method for a circuit wire preferably includes a step of forming an insulating film on the surface of the circuit wire and a step of forming a new conductive layer on the surface of the insulating film.

These steps make it possible to form a second electrode pattern insulated from the first electrode pattern.

The step of forming an insulating film is not particularly limited, and examples thereof include a known method of forming a permanent film. Further, an insulating film having a desired pattern may be formed by photolithography using a photosensitive material having an insulating property.

The step of forming a new conductive layer on the insulating film is not particularly limited, and a new conductive layer having a desired pattern may be formed by, for example, photolithography using a photosensitive material having conductivity.

In the manufacturing method for a circuit wire, it is also preferable that a substrate having a plurality of conductive layers on both surfaces of the base material is used, and a conductive pattern is formed sequentially or simultaneously on the conductive layers formed on both surfaces of the base material. With such a configuration, it is possible to form a circuit wire for a touch panel in which the first conductive pattern is formed on one surface of the base material and the second conductive pattern is formed on the other surface thereof. It is also preferable to form a circuit wire for a touch panel, having such a configuration, from both surfaces of the base material in a roll-to-roll manner.

[Use Application of Circuit Wire]

The circuit wire manufactured according to the manufacturing method for a circuit wire can be applied to various devices. Examples of the device including the circuit wire manufactured according to the above-described manufacturing method include an input device, where a touch panel is preferable, and a capacitance type touch panel is more preferable. In addition, the input device can be applied to display devices such as an organic EL display device and a liquid crystal display device.

[Manufacturing Method for Electronic Device]

The present invention also relates to a manufacturing method for an electronic device.

The manufacturing method for an electronic device is preferably a manufacturing method for an electronic device using the transfer film described above.

Among the above, the manufacturing method for an electronic device preferably includes the above-described manufacturing method for a laminate.

Examples of the electronic device include an input device, where a touch panel is preferable. Further, the input device can be applied to display devices such as an organic electroluminescence display device and a liquid crystal display device.

In a laminate in which a substrate, a conductive layer (a conductive layer included in the substrate), and a resin pattern manufactured according to using the above-described transfer film are laminated in this order, the manufacturing method for a touch panel is also preferably a method including a step of subjecting the conductive layer present in a region where the resin pattern is not disposed to an etching treatment to form a wire for a touch panel, and it is more preferably a method using a resin pattern that is manufactured according to a manufacturing method including the affixing step, the exposure step, and the development step.

The specific aspect of each step in the manufacturing method for a touch panel including a step of forming a wire for a touch panel and the embodiment associated with the order for carrying out respective steps are as described in the above-described “manufacturing method for a circuit wire”, and the same applies to the preferred aspect thereof.

In addition, the manufacturing method for a touch panel including a step of forming a wire for a touch panel may include any steps (other steps) other than those described above.

As the method for forming a wire for a touch panel, the method described in FIG. 1 of WO2016/190405A can also be referred to.

A touch panel having at least a wire for a touch panel is manufactured by the above-described manufacturing method for a touch panel. The touch panel preferably has a transparent substrate, electrodes, and an insulating layer or protective layer.

Examples of the detection method for the touch panel include known methods such as a resistive membrane method, a capacitance method, an ultrasonic method, an electromagnetic induction method, and an optical method. Among the above, a capacitance method is preferable.

Examples of the touch panel include a so-called in-cell type (for example, those illustrated in FIG. 5, FIG. 6, FIG. 7, and FIG. 8 of JP2012-517051A), a so-called on-cell type (for example, one described in FIG. 19 of JP2013-168125A and those described in FIG. 1 and FIG. 5 of JP2012-89102A), an one glass solution (OGS) type, a touch-on-lens (TOL) type (for example, one described in FIG. 2 of JP2013-54727A), various out-cell types (so-called GG, G1·G2, GFF, GF2, GF1, G1F, and the like), and other configurations (for example, those described in FIG. 6 of JP2013-164871A).

Examples of the touch panel include those described in paragraph [0229] of JP2017-120345A.

### EXAMPLES

Hereinafter, the present invention will be described in more detail with reference to Examples. The materials, amounts of use, proportions, treatments, procedures, and the like described in the following Examples can be modified as appropriate as long as the gist of the invention is maintained. Accordingly, the scope of the present invention should not be construed as being limited to Examples shown below.

In the following Examples, unless otherwise specified, “parts” and “%” mean “parts by mass” and “% by mass”, respectively.

### Synthesis

[Compound (1)]

<Compound A-1>

A compound A-1 was synthesized according to Synthesis Example 5 of paragraph [0139] of WO2011/152126A. The average number of moles of propylene oxide added to the obtained compound A-1 was 5.

<Compound A-2>

A Compound A-2 was synthesized according to Example 3 of paragraph [0033] of CN102911353A. The average number of moles of propylene oxide added to the obtained compound A-2 was 3.

The structures of the compounds A-1 to A-2 obtained above are shown below.

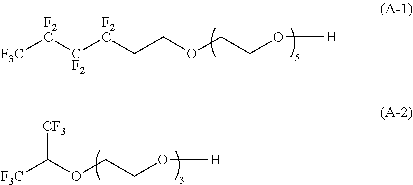

[Block Copolymer]

<Block Copolymer B-1>

A block copolymer B-1 was synthesized according to Journal of Polymer Research, 2018, 25 (7), 1-7.

The following synthetic raw materials were used for synthesis; 1H,1H,2H,2H-nonafluorohexyl acrylate (manufactured by Tokyo Chemical Industry Co., Ltd.), polyethylene glycol monoacrylate (Blemmer AE-400 (the average number of moles of polyethylene glycol added is 10, manufactured by NOF Corporation)), methyl-2-bromo-2-methylpropanoate (manufactured by Tokyo Chemical Industry Co., Ltd.), 2,2′-bipyridine (manufactured by FUJIFILM Wako Pure Chemical Corporation), copper bromide (manufactured by FUJIFILM Wako Pure Chemical Corporation)), and propylene glycol monomethyl ether acetate (PGMEA, manufactured by FUJIFILM Wako Pure Chemical Corporation). The obtained solid was diluted with PGMEA to obtain a PGMEA solution of the block copolymer B-1 (solid content concentration: 20% by mass).

In the present specification, the “solid content” means all components excluding a solvent. In addition, a liquid component is also regarded as a solid content in a case where it is a component excluding a solvent.

<Block Copolymer B-2>

A PGMEA solution (solid content concentration: 20% by mass) of the block copolymer B-2 was obtained by the same procedure as in <Block copolymer B-1> described above, except that as synthetic raw materials, 1H,1H,2H,2H-nonafluorohexyl acrylate was changed to 1H,1H,2H,2H-nonafluorohexyl methacrylate (manufactured by Tokyo Chemical Industry Co., Ltd.) and polyethylene glycol monoacrylate (Blemmer AE-400 (the average number of moles of polyethylene glycol added is 10, manufactured by NOF Corporation)) was changed to polyethylene glycol monoacrylate (Blemmer AE-200 (the average number of moles of polyethylene glycol added is 4.5, manufactured by NOF Corporation)).

<Block Copolymer B-3>

A PGMEA solution (solid content concentration: 20% by mass) of the block copolymer B-3 was obtained in the same procedure as in <Block copolymer B-1> described above, except that as a synthetic raw material, 1H,1H,2H,2H-nonafluorohexyl acrylate was changed to 1,1,1,3,3,3-hexafluoroisopropylacrylate (manufactured by Tokyo Chemical Industry Co., Ltd.).

[Comparative Compound R-1]

Cyclohexanone (FUJIFILM Wako Pure Chemical Corporation) (25.0 g) was charged into a three-neck flask of 300 mL and equipped with a stirrer, a thermometer, a reflux condenser, and a nitrogen gas introduction pipe, and the temperature was raised to 80° C. Next, a mixed solution consisting of 1H,1H,2H,2H-nonafluorohexyl acrylate (manufactured by Tokyo Chemical Industry Co., Ltd.) (35.5 g, 111.8 mmol), Blemmer AE-400 (n≈10, manufactured by NOF Corporation) (60.5 g, 111.8 mmol), cyclohexanone (25.0 g), and a polymerization initiator V-601 (manufactured by FUJIFILM Wako Pure Chemical Corporation) (0.342 g) was dropwise added at a constant rate so that the dropwise addition was completed in 180 minutes. After the completion of the dropwise addition, stirring was further continued for 1 hour, a solution consisting of V-601 (0.342 g) and cyclohexanone (1.00 g) was added thereto, and immediately after the addition, the temperature was raised to 93° C., followed by further stirring for 2 hours. After obtaining a solid by the reprecipitation treatment, the obtained solid was diluted with PGMEA to obtain a PGMEA solution (120 g, solid content concentration: 20% by mass) of a comparative compound R-1 (a random copolymer).

The structures of the block copolymers and the comparative compound, obtained as described above, are shown below. It is noted that numerical value attached to the constitutional unit in the copolymer indicates the content (in terms of % by mass) of each structural unit with respect to the total mass of each copolymer.

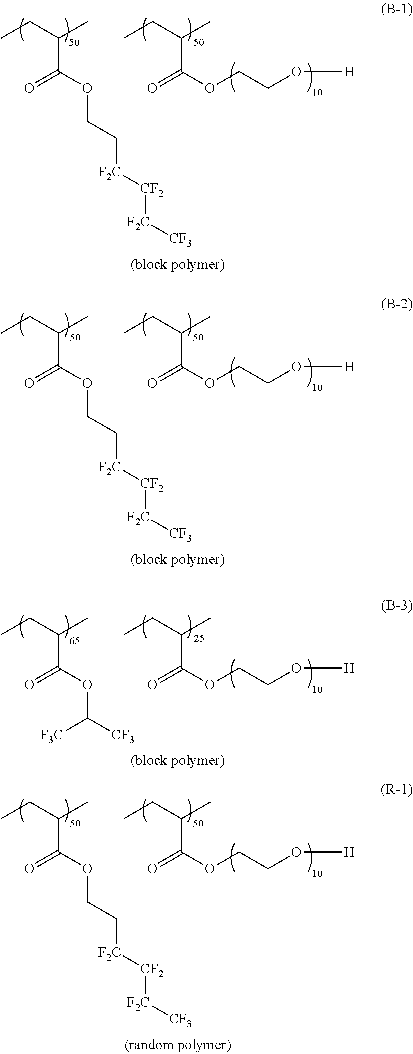

It is noted that any one of MEGAFACE F444, F551, F552, and F555 (all of which are manufactured by DIC Corporation) is a comparative compound that does not correspond to the block copolymer and does not correspond to the compound (1).

The weight-average molecular weight (Mw), the number-average molecular weight (Mn), and the dispersivity (Mw/Mn) of each block copolymer were as follows. It is noted that weight-average molecular weight (Mw) of the copolymer was calculated in terms of polystyrene by gel permeation chromatography (GPC) (EcoSEC HLC-8320GPC (manufactured by Tosoh Corporation)), measurement conditions of an eluent of THF, a flow rate of 0.35 ml/min, and a temperature of 40° C. As the columns to be used, TSKgel SuperHZM-H, TSKgel SuperHZ4000, and TSKgel SuperHZ200 (manufactured by Tosoh Corporation) were connected in series and used.

TABLE 1

| | Average molecular weight | | Dispersity |
|---|---|---|---|
| | Mw | Mn | Mw/Mn |
| B-1 | 12,000 | 9,200 | 1.30 |
| B-2 | 14,100 | 10,400 | 1.35 |
| B-3 | 13,000 | 9,100 | 1.23 |
| R-1 | 20,000 | 9,100 | 2.20 |

[Resin]

In the following synthesis examples, the abbreviations respectively indicate the following compounds.
St: Styrene (manufactured by FUJIFILM Wako Pure Chemical Corporation)
MAA: Methacrylic acid (manufactured by Fujifilm Wako Pure Chemical Corporation)
MMA: Methyl methacrylate (manufactured by FUJIFILM Wako Pure Chemical Corporation)
BzMA: Benzyl methacrylate (manufactured by Fujifilm Wako Pure Chemical Corporation)
AA: Acrylic acid (manufactured by Tokyo Chemical Industry Co., Ltd.)
MAA-GMA: Glycidyl methacrylate adduct of methacrylic acid
CHMA: Cyclohexyl methacrylate (manufactured by Mitsubishi Gas Chemical Company, Inc.)
AMA: Allyl methacrylate (manufactured by Fujifilm Wako Pure Chemical Corporation)
PGMEA: Propylene glycol monomethyl ether acetate (manufactured by Showa Denko K.K.)
MEK: Methyl ethyl ketone (manufactured by SANKYO CHEMICAL Co., Ltd.)
V-601: Dimethyl-2,2′-azobis(2-methylpropionate) (manufactured by FUJIFILM Wako Pure Chemical Corporation)
ATHF: Tetrahydrofuran-2-yl acrylate (a synthetic product)
EA: Ethyl acrylate (manufactured by Fujifilm Wako Pure Chemical Corporation)
CHA: Cyclohexyl acrylate (manufactured by Fujifilm Wako Pure Chemical Corporation)
PMPMA: 1,2,2,6,6-pentamethyl-4-piperidyl methacrylate (manufactured by FUJIFILM Wako Pure Chemical Corporation)

<Resin P-1>

PGMEA (116.5 parts) was placed in a three-neck flask, and the temperature was raised to 90° C. in a nitrogen atmosphere. A solution obtained by adding St (52.0 parts), MMA (19.0 parts), MAA (29.0 parts), V-601 (4.0 parts), and PGMEA (116.5 parts) was added dropwise over 2 hours to the solution in the flask maintained at 90° C.±2° C. After completion of the dropwise addition, the solution in the flask was stirred at 90° C.±2° C. for 2 hours to obtain a solution containing the resin P-1 (solid content concentration: 30.0% by mass).

<Resins P-2 to P-4>

A solution containing any one of the resins P-2 to P-4 (solid content concentrations of all solutions: 30.0% by mass) was obtained in the same procedure as in <Synthesis of resin P-1> described above, except that the kind of monomers used was changed as shown in Table 2.

<Resins P-5 and P-6>

Propylene glycol monomethyl ether acetate (60 g, Fujifilm Wako Pure Chemical Corporation) and propylene glycol monomethyl ether (240 g, Fujifilm Wako Pure Chemical Corporation) were added to a flask having a capacity of 2,000 mL. The obtained liquid was heated to 90° C. while being stirred at a stirring speed of 250 rpm (rpm: round per minute).

For the preparation of a dropping liquid (1), methacrylic acid (107.1 g, manufactured by Mitsubishi Chemical Corporation, product name: Acryester M), methyl methacrylate (5.46 g, manufactured by Mitsubishi Gas Chemical Company, Inc., product name: MMA), and cyclohexyl methacrylate (231.42 g, manufactured by Mitsubishi Gas Chemical Company, Inc., product name: CHMA) were mixed and diluted with propylene glycol monomethyl ether acetate (60.0 g) to obtain the dropping liquid (1).

For the preparation of a dropping liquid (2), dimethyl 2,2′-azobis(2-methylpropionate) (9.637 g, FUJIFILM Wako Pure Chemical Corporation, product name: V-601) was dissolved in propylene glycol monomethyl ether acetate (136.56 g) to obtain a dropping liquid (2).

The dropping liquid (1) and the dropping liquid (2) were simultaneously added dropwise over 3 hours to the above-described flask (specifically, the 2,000 mL flask containing a liquid heated to 90° C.) having a capacity of 2,000 mL. After completion of the dropwise addition, V-601 (2.401 g) was added to the flask every hour three times. Then, stirring was further carried out at 90° C. for 3 hours.

Then, the solution (the reaction solution) obtained in the flask was diluted with propylene glycol monomethyl ether acetate (178.66 g). Next, tetraethylammonium bromide (1.8 g, Fujifilm Wako Pure Chemical Corporation) and hydroquinone monomethyl ether (0.8 g, Fujifilm Wako Pure Chemical Corporation) were added to the above reaction solution. Thereafter, the temperature of the reaction solution was raised to 100° C.

Next, 76.03 g of glycidyl methacrylate (manufactured by NOF Corporation, product name: Blemmer G) was dropwise added to the reaction solution over 1 hour. The above reaction solution was reacted at 100° C. for 6 hours to obtain 1,158 g of a solution of the resin P-5 (solid content concentration: 36.3% by mass). The obtained resin P-5 had a weight-average molecular weight of 27,000, a number-average molecular weight of 15,000, and an acid value of 95 mgKOH/g.

The resin P-6 was synthesized with reference to the synthesis method for the resin P-5.

<Resin P-7>

Propylene glycol monomethyl ether (270.0 g) was added to a three-neck flask, and the temperature was raised to 70° C. under a nitrogen stream while stirring.

On the other hand, allyl methacrylate (45.6 g, Fujifilm Wako Pure Chemical Corporation) and methacrylic acid (14.4 g) were dissolved in propylene glycol monomethyl ether (270.0 g), and further, V-65 (3.94 g, FUJIFILM Wako Pure Chemical Corporation) was dissolved therein to prepare a dropping liquid, which was added dropwise into the flask over 2.5 hours. The stirred state was maintained as it was, and the reaction was carried out for 2.0 hours. Then, the temperature of the contents in the flask was returned to room temperature, the contents in the flask were added dropwise into 2.7 L of ion exchange water in a stirred state, and reprecipitation was carried out to obtain a suspension. The suspension was filtered through Nutche (a Buchner funnel) in which a filter paper was placed, and the filtrate was further washed with ion exchange water to obtain a powder in a state of being wet. Blast drying was carried out at 45° C., and it was confirmed that a constant weight was reached, whereby a resin P-7 was obtained as a powder at a yield of 70%. The amount of the residual monomer in the powder measured by using gas chromatography was less than 0.1% by mass with respect to the polymer solid content.

<Resin P-8>

Acrylic acid (72.1 parts by mass, 1.0 molar equivalent) and hexane (72.1 parts by mass) were added to a three-neck flask and cooled to 20° C. After dropwise adding camphorsulfonic acid (0.007 parts by mass, 0.03 mmol equivalent) and 2-dihydrofuran (77.9 parts by mass, 1.0 molar equivalent) into the flask, the contents (the reaction solution) in the flask were stirred at 20° C.±2° C. for 1.5 hours, the temperature was subsequently raised to 35° C., and stirring was carried out for 2 hours. After spreading KYOWAAD 200 (a filter material, an aluminum hydroxide powder, manufactured by Kyowa Chemical Industry Co., Ltd.) and KYOWAAD 1000 (a filter material, a hydrotalcite powder, manufactured by Kyowa Chemical Industry Co., Ltd.) on Nutche (a Buchner funnel) in this order, the above reaction solution was filtered to obtain a filtrate. Hydroquinone monomethyl ether (MEHQ, 0.0012 parts) was added to the obtained filtrate, and then the concentration under reduced pressure was carried out at 40° C. to prepare tetrahydrofuran-2-yl acrylate (ATHF) (140.8 parts) as a colorless oily substance (yield: 99.0%).

PGMEA (75.0 parts) was placed in a three-neck flask, and the temperature was raised to 90° C. in a nitrogen atmosphere. A solution to which ATHF (29.0 parts) obtained as described above, MMA (35.0 parts), ethyl acrylate (EA, 30.0 parts), cyclohexyl acrylate (CHA, 5.0 parts), 1,2,2,6,6-pentamethyl-4-piperidyl methacrylate (PMPMA, 1.0 parts), V-601 (4.0 parts), and PGMEA (75.0 parts) was added dropwise over 2 hours to a solution in a three-neck flask maintained at 90° C.±2° C. After completion of the dropwise addition, stirring was carried out at 90° C.±2° C. for 2 hours to obtain a solution containing the resin P-8 (solid content concentration: 40.0% by mass).

Table 2 shows the kind and mass ratio of each monomer used for synthesizing each resin and the weight-average molecular weight (Mw) of each resin. The resins P-1 to P-7 correspond to an alkali-soluble resin (the polymer P), and the resin P-8 corresponds to the resin having (the polymer A) a constitutional unit having an acid group protected by an acid-decomposable group. It is noted that each of the resins P-1 to P-6 and P-8 was added to the resin composition in a form of a solution, and the resin P-7 was added to the resin composition in a form of a powder.

It is noted that the unit of the amount of the monomer in Table 1 is % by mass.

TABLE 2

| | P-1 | P-2 | P-3 | P-4 | P-5 | P-6 | P-7 | P-8 |
|---|---|---|---|---|---|---|---|---|
| St | 52.0 | | 32.0 | | | 47.7 | | |
| BzMA | | 81.0 | | 75.0 | | | | |
| MAA | 29.0 | 19.0 | 28.0 | 10.0 | 26.5 | 19.0 | 24.0 | 35.0 |
| MMA | 19.0 | | 40.0 | | 2.0 | 1.3 | | |
| AA | | | | 15.0 | | | | |
| MAA- | | | | | 20.0 | 32.0 | | |
| GMA | | | | | | | | |
| CHMA | | | | | 51.5 | | | |
| AMA | | | | | | | 76.0 | |
| ATHF | | | | | | | | 29.0 |
| EA | | | | | | | | 30.0 |
| CHA | | | | | | | | 5.0 |
| PMPMA | | | | | | | | 1.0 |
| Mw | 60,000 | 40,000 | 40,000 | 30,000 | 27,000 | 17,000 | 25,000 | 30,000 |

[Thermal Crosslinking Compound]

### Synthesis of Blocked Isocyanate Compounds Q-1 and Q-2

Butanone oxime (manufactured by Idemitsu Kosan Co., Ltd.) (453 g) was dissolved in methyl ethyl ketone (700 g) under a nitrogen stream. To the obtained solution, 1,3-bis(isocyanatomethyl)cyclohexane (a mixture of cis and trans isomers, manufactured by Mitsui Chemicals, Inc., TAKENATE 600) (500 g) was added dropwise over 1 hour under ice cooling, and after the dropwise addition, the reaction was further carried out for 1 hour. Then, the temperature of the solution was raised to 40° C., and the reaction was carried out for 1 hour. It was confirmed that the reaction was completed by ¹H-nuclear magnetic resonance (NMR) and high performance liquid chromatography (HPLC), whereby a methyl ethyl ketone solution (solid content concentration: 57.7% by mass) of a blocked isocyanate compound Q-1 was obtained.

In addition, a methyl ethyl ketone solution (solid content concentration: 75.0% by mass) of a blocked isocyanate compound Q-2 was obtained with reference to a synthesis method for the blocked isocyanate compound Q-1.

It is noted that each of the blocked isocyanate compounds Q-1 and Q-2 was added to the resin composition in a form of a solution.

| Blocked isocyanate | | |
|---|---|---|
| compound | Structure | NCO value [mmol/g] |
| Q-1 | 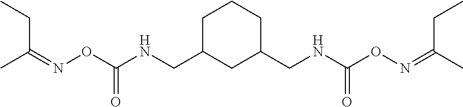 [SMILES: CC/C(C)=N\OC(=O)NCC1CCCC(CNC(=O)O/N=C(/C)CC)C1] | 5.4 |
| Q-2 | 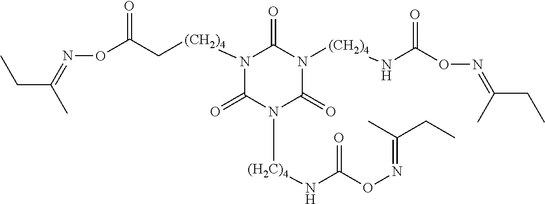 | 3.9 |

### Examples 1 to 3 and Comparative Examples 1 and 2

[Preparation of Resin Composition]

According to Tables 3 to 5, each of the components was mixed with stirring to prepare each resin composition.

In the table, the numerical value for each component in each resin composition indicates the adding amount (in terms of part by mass) of each component.

It is noted that the resin was added to each resin composition in a form of a solution containing the resin. In the table, the numerical value indicating the adding amount of the resin is the mass of the added “solution containing the resin”.

Hereinafter, the same shall apply to components which are added to the composition in a form of being contained in the mixed solution, unless otherwise specified.

TABLE 3

| | | Thermoplastic resin composition | | | |
|---|---|---|---|---|---|
| | | 1 | 2 | 3 | 4 |
| Resin | P-4 | 42.85 | 42.85 | | 42.85 |
| | P-5 | | | 35.15 | |
| | Acrybase FF187 (manufactured by Fujikura Kasei Co., Ltd.) | | | 35.15 | |
| Coloring agent | BB-1 | 0.08 | 0.08 | | 0.08 |
| Photoacid generator | C-1 | 0.32 | 0.32 | | 0.32 |
| Polymerizable | Tricyclodecanedimethanol diacrylate (A-DCP, manufactured | 4.63 | 4.63 | 6.01 | 4.63 |
| compound | by SHIN-NAKAMURA CHEMICAL Co, Ltd.) | | | | |
| | Monomer having carboxy group, ARONIX TO-2349 | 2.31 | 2.31 | 3.00 | 2.31 |
| | (manufactured by Toagosei Co., Ltd.) | | | | |
| | Urethane acrylate 8UX-015A(manufactured by Taisei Fine | 0.77 | 0.77 | 1.00 | 0.77 |
| | Chemical Co., Ltd.) | | | | |
| Block copolymer | B-1 | 0.035 | | | |
| | B-2 | | 0.035 | | |
| | B-3 | | | 0.040 | |
| Comparative compound | MEGAFACE F551A (manufactured by DIC Corporation) | | | | 0.035 |
| Solvent | PGMEA | 9.51 | 9.51 | 9.51 | 9.51 |
| | MEK | 39.50 | 39.50 | 39.50 | 39.50 |

| | | | | |
|---|---|---|---|---|
| Average film thickness of thermoplastic resin composition layer (μm) | 2.0 | 2.0 | 7.0 | 7.0 |

In Table 3, each component indicates the following component.
P-4 and P-5: The alkali-soluble resins described above
ACRYBASE FF187: A solution containing a resin which is an alkali-soluble thermoplastic resin, (solid content concentration: 40% by mass, solvent: PGMEA, manufactured by Fujikura Kasei Co., Ltd.)
BB-1: A coloring agent, a compound having a structure shown below 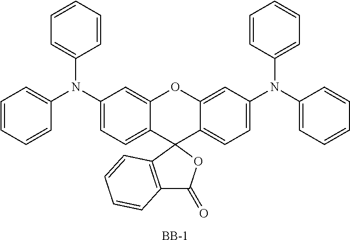
C-1: A photoacid generator, a compound having a structure shown below (the synthesis was carried out according to the compound described in paragraph [0227] of JP2013-047765A and the method described in paragraph [0227] thereof). 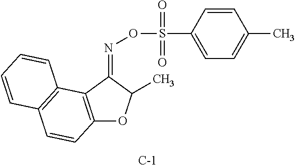
B-1 to B-3: The block copolymers described above
PGMEA: Propylene glycol monomethyl ether acetate (manufactured by Showa Denko K.K.)
MEK: Methyl ethyl ketone (manufactured by SANKYO CHEMICAL Co., Ltd.)

In the table, the column “Average film thickness of thermoplastic resin composition layer (μm)” indicates the average film thickness of the thermoplastic resin composition layer formed in a case where a test has been carried out using the thermoplastic resin composition.

TABLE 4

| | | Water-soluble resin composition | | |
|---|---|---|---|---|
| | | 1 | 2 | 3 |
| Resin | PVA 4-88LA (manufactured by | 32.2 | | |
| | KURARAY Co., Ltd.) | | | |
| | PVA205 (manufactured by | | 32.2 | 32.2 |
| | KURARAY Co., Ltd.) | | | |
| | Polyvinylpyrrolidone | 14.9 | 14.9 | 14.9 |
| | (manufactured by Nippon Shokubai | | | |
| | Co., Ltd.) | | | |
| Compound (1) | A-1 | 0.02 | | |
| | A-2 | | 0.02 | |
| Comparative | MEGAFACE F444 (manufactured | | | 0.02 |
| compound | by DIC Corporation) | | | |
| Solvent | Ion exchange water | 524.0 | 524.0 | 524.0 |
| | Methanol (manufactured by | 429.0 | 429.0 | 429.0 |
| | Mitsubishi Gas Chemical Company, | | | |
| | Inc.) | | | |

| | | | |
|---|---|---|---|
| Average film thickness of water-soluble resin | 1.0 | 1.0 | 1.0 |
| composition layer (μm) | | | |

In Table 4, each component indicates the following component.
PVA 4-88LA: Kuraray Poval 4-88LA (a water-soluble resin), manufactured by KURARAY Co., Ltd.
PVA 205: Kuraray Poval 205 (a water-soluble resin), manufactured by KURARAY Co., Ltd.
Polyvinylpyrrolidone: A water-soluble resin, manufactured by Nippon Shokubai Co., Ltd.
A-1 and A-2: The compound (1) described above
MEGAFACE F444: Comparative compound, manufactured by DIC Corporation
Ion exchange water
Methanol: A solvent, manufactured by Mitsubishi Gas Chemical Company, Inc.

In the table, the column “Average film thickness of water-soluble resin composition layer (μm)” indicates the average film thickness of the water-soluble resin composition layer formed in a case where a test has been carried out using the water-soluble resin composition.

TABLE 5

| | | Photosensitive resin composition | | | | |
|---|---|---|---|---|---|---|
| | | 1 | 2 | 3 | 4 | 5 |
| Resin | P-1 | 50.00 | | | 51.00 | |
| | P-2 | | | 59.20 | | |
| | P-3 | | 62.20 | | | 62.20 |
| Polymerizable | BPE-500 (manufactured by SHIN-NAKAMURA | 36.20 | | 27.00 | 15.00 | |
| compound | CHEMICAL Co., Ltd.) | | | | | |
| | BPE-200 (manufactured by SHIN-NAKAMURA | | 20.00 | | | 20.00 |
| | CHEMICAL Co., Ltd.) | | | | | |
| | Dimethacrylate of polyethylene glycol which is obtained | | | | 10.00 | |
| | by adding 15 mol of ethylene oxide in average and 2 mol | | | | | |
| | of propylene oxide in average to both ends of bisphenol A, | | | | | |
| | respectively | | | | | |
| | M-270 (manufactured by Toagosei Co., Ltd.) | 5.00 | | | | |
| | A-TMPT (manufactured by SHIN-NAKAMURA | | 6.00 | | 5.00 | 6.00 |
| | CHEMICAL Co., Ltd.) | | | | | |
| | SR-454 (manufactured by Arkema S.A.) | | 9.00 | | 5.00 | 9.00 |
| | SR-502 (manufactured by Arkema S.A.) | | | 4.00 | | |
| | A-9300-CL1 (manufactured by SHIN-NAKAMURA | | | 7.80 | 9.77 | |
| | CHEMICAL Co., Ltd.) | | | | | |
| Photopolymerization | B-CIM (manufactured by KUROGANE KASEI Co., Ltd.) | 7.00 | 1.90 | 1.10 | 3.00 | 1.90 |
| initiator | SB-PI 701 (manufactured by Sanyo Trading Co., Ltd.) | 0.60 | 0.30 | 0.10 | 0.30 | 0.30 |
| Coloring agent | Leucocrystal violet (manufactured by Tokyo Chemical | 0.40 | 0.40 | 0.66 | 0.60 | 0.40 |
| | Industry Co., Ltd.) | | | | | |
| | Brilliant green (manufactured by Tokyo Chemical | | 0.05 | | 0.02 | 0.05 |
| | Industry Co., Ltd.) | | | | | |
| Additive | N-phenylglycine (manufactured by Tokyo Chemical | 0.20 | | | | |
| | Industry Co., Ltd.) | | | | | |
| | CBT-1 (manufactured by JOHOKU CHEMICAL Co., | 0.10 | 0.03 | 0.03 | | 0.03 |
| | Ltd.) | | | | | |
| | 1:1 mixture (in terms of mass ratio) of 1-(2-di-n- | | | | 0.10 | |
| | butylaminomethyl)-5-carboxybenzotriazole and 1-(2-di-n- | | | | | |
| | butylaminomethyl)-6-carboxy benzotriazole | | | | | |
| | TDP-G (manufactured by Kawaguchi Chemical Industry | 0.30 | | | | |
| | Company, Co., Ltd.) | | | | | |
| | Irganox 245 (manufactured by BASF SE) | | 0.10 | 0.10 | 0.20 | 0.10 |
| | N-nitrosophenyl hydroxylamine aluminum salt | | 0.02 | 0.01 | 0.01 | 0.02 |
| | (manufactured by FUJIFILM Wako Pure Chemical | | | | | |
| | Corporation) | | | | | |
| | Phenidone (manufactured by Tokyo Chemical Industry | 0.01 | | | | |
| | Co., Ltd.) | | | | | |
| Block copolymer | B-1 | 0.34 | | | | |
| | B-2 | | 0.34 | | | |
| | B-3 | | | 0.34 | | |
| Comparative | MEGAFACE F552 (manufactured by DIC Corporation) | | | | 0.34 | |
| compound | R-1 | | | | | 0.34 |
| Solvent | PGMEA | 227 | 227 | 227 | 227 | 227 |
| | MEK | 340 | 340 | 340 | 340 | 340 |

| | | | | | |
|---|---|---|---|---|---|
| Average film thickness of photosensitive resin layer (μm) | 2.0 | 2.0 | 2.0 | 2.0 | 2.0 |

In Table 5, each component indicates the following component.
P-1 to P-3: The alkali-soluble resins described above
BPE-500: 2,2-bis(4-((meth)acryloxypentethoxy)phenyl)propane, manufactured by SHIN-NAKAMURA CHEMICAL Co., Ltd.
BPE-200: 2,2-bis(4-((meth)acryloxydiethoxy)phenyl)propane, manufactured by SHIN-NAKAMURA CHEMICAL Co., Ltd.
M-270: Polypropylene glycol diacrylate (n≈12), manufactured by Toagosei Co., Ltd.
A-TMPT: Trimethylolpropane triacrylate, manufactured by SHIN-NAKAMURA CHEMICAL Co., Ltd.
SR-454: Ethoxylated (3) trimethylolpropane triacrylate, manufactured by Arkema S. A.
SR-502: Ethoxylated (9) trimethylolpropane triacrylate, manufactured by Arkema S. A.
A-9300-CL1: A caprolactone-modified (meth)acrylate compound, manufactured by SHIN-NAKAMURA CHEMICAL Co., Ltd.
B-CIM: 2,2′-bis(2-chlorophenyl)-4,4′,5,5′-tetraphenylbisimidazole, manufactured by Hampford Research Inc.
SB-PI701: 4,4′-bis(diethylamino)benzophenone, manufactured by Sanyo Trading Co., Ltd.
Leucocrystal violet: manufactured by Tokyo Chemical Industry Co., Ltd.
Brilliant green: Manufactured by Tokyo Chemical Industry Co., Ltd.
N-phenylglycine: Manufactured by Tokyo Chemical Industry Co., Ltd.
CBT-1: Carboxybenzotriazole, manufactured by JOHOKU CHEMICAL Co., Ltd.
TDP-G: Phenothiazine, manufactured by Kawaguchi Chemical Industry Company, Co., Ltd.
Irganox 245: A hindered phenol-based antioxidant, manufactured by BASF SE
N-nitrosophenyl hydroxylamine aluminum salt: Manufactured by Fujifilm Wako Pure Chemical Corporation
Phenidone: Manufactured by Tokyo Chemical Industry Co., Ltd.
B-1 to B-3: The block copolymers described above
MEGAFACE F552: Comparative compound, manufactured by DIC Corporation
R-1: Comparative compound described above
PGMEA: Propylene glycol monomethyl ether acetate (manufactured by Showa Denko K. K.)
MEK: Methyl ethyl ketone (manufactured by SANKYO CHEMICAL Co., Ltd.)

It is noted that in the table, the column “Average film thickness of photosensitive resin composition layer (μm)” indicates the average film thickness of the photosensitive resin composition layer formed in a case where a test has been carried out using each photosensitive resin composition.

[Preparation of Transfer Film]

Using a slit-shaped nozzle, the prepared thermoplastic resin composition 1 was applied onto a polyethylene terephthalate film (a temporary support, Lumirror 16KS40 (manufactured by Toray Industries, Inc.)) having a thickness of 16 μm so that the width was 1.0 μm and the average film thickness of the composition layer after drying was a specific film thickness, and it was allowed to pass through, over 60 seconds, a drying zone of 3 m in which the temperature was set to 80° C. and the film surface wind speed was set to be 3 m/sec by adjusting the intake amount and the exhaust amount, thereby obtaining a laminate A having the temporary support and the thermoplastic resin composition layer.

Subsequently, the coating amount was adjusted so that the width was 1.0 μm and the average film thickness of the water-soluble resin composition layer after drying was the specific film thickness, and using a slit-shaped nozzle, a water-soluble resin composition 1 was applied onto the thermoplastic resin composition layer of the obtained laminate A, and then the laminate A was allowed to pass through, over 60 seconds, a drying zone of 3 m in which the temperature was set to 100° C. and the film surface wind speed was set to be 3 m/sec by adjusting the intake amount and the exhaust amount, thereby obtaining a laminate B in which a water-soluble resin composition layer was formed on the thermoplastic resin composition layer.

Further, the coating amount was adjusted so that the width was 1.0 m and the average film thickness of the photosensitive resin composition layer after drying was the specific film thickness, and using a slit-shaped nozzle, a photosensitive resin composition 1 was applied onto the water-soluble resin layer of the obtained laminate B, and then the laminate B was allowed to pass through, over 60 seconds, a drying zone of 3 m in which the temperature was set to 80° C. and the film surface wind speed was set to be 3 m/sec by adjusting the intake amount and the exhaust amount, thereby obtaining a transfer film of Example 1 in which a photosensitive resin composition layer was formed on the water-soluble resin composition layer.

The obtained transfer film of Example 1 has each of the resin composition layers in the following order; temporary support/thermoplastic resin composition layer (first layer)/water-soluble resin composition layer (second layer)/photosensitive resin composition layer (third layer).

Each of transfer films was obtained in the same procedure as in Example 1, except that in Examples 2 and 3 and Comparative Examples 1 and 2, the respective resin composition layers were changed as described in Table 6.

[Evaluation of Resolution]

A copper layer having a thickness of 200 nm was provided on a polyethylene terephthalate (PET) film having a thickness of 100 μm by a sputtering method, and a PET substrate attached with a copper layer was prepared.

The prepared respective transfer films (Examples 1 to 3 and Comparative Examples 1 and 2) were wound forward, and then the surface of the photosensitive resin composition layer as the outermost layer, which had been disposed on the temporary support, was affixed to the above-described PET substrate attached with a copper layer under laminating conditions of a roll temperature of 100° C., a linear pressure of 1.0 MPa, and a linear speed of 4.0 m/min, thereby laminating the PET substrate with a copper layer to the transfer film. Next, after exposure with an ultra-high pressure mercury lamp through a line-and-space pattern mask (Duty ratio 1:1, line width: 20 μm) without peeling off the temporary support, the temporary support was peeled off and developed. Development was carried out using a 1.0% sodium carbonate aqueous solution at 25° C. for 30 seconds by shower development. An exposure amount at which the resist line width was 20 μm was defined as the optimum exposure amount, when a line-and-space pattern was formed by the above method.

Any region of 1 cm² in the line-and-space pattern formed at the optimum exposure amount was observed with a scanning electron microscope (SEM), and the minimum line width resolved without peeling of the resist pattern and without forming residues was evaluated according to the following evaluation standards. Evaluation A or B is a practically acceptable range.

(Evaluation Standard)

A: The minimum line width is less than 5 μm.

B: The minimum line width is 5 μm or more and less than 7 μm.

C: The minimum line width is 7 μm or more and less than 9 μm.

D: The minimum line width is 9 μm or more and less than 11 μm.

E: The minimum line width is 11 μm or more.

TABLE 6

| | | | | | Comparative | Comparative |
|---|---|---|---|---|---|---|
| Resin composition layer | | Example 1 | Example 2 | Example 3 | Example 1 | Example 2 |
| First layer | Thermoplastic resin | 1 | 2 | 3 | 4 | 4 |
| | composition | | | | | |
| | Block copolymer | B-1 | B-2 | B-3 | MEGAFACE | MEGAFACE |
| | or comparative | | | | F551 | F551 |
| | compound | | | | | |
| Second | Water-soluble resin | 1 | 1 | 2 | 3 | 3 |
| layer | composition | | | | | |
| | Compound (1) | A-1 | A-1 | A-2 | MEGAFACE | MEGAFACE |
| | or comparative | | | | F444 | F444 |
| | compound | | | | | |
| Third layer | Photosensitive resin | 1 | 2 | 3 | 4 | 5 |
| | composition | | | | | |
| | Block copolymer | B-1 | B-2 | B-3 | MEGAFACE | R-1 |
| | or comparative | | | | F552 | |
| | compound | | | | | |
| Evaluation | Resolution | A | A | B | E | C |
| result | | | | | | |

From the results of Examples 1 to 3, it has been confirmed that in a case where the transfer film according to the embodiment of the present invention is used, a desired effect is obtained

From the comparison among Examples 1 and 2 and Example 3, it has been confirmed that in a case where the constitutional unit X and the compound represented by Formula (1) have a group represented by Formula (A), the effect of the present invention is more excellent.

### Examples 4 to 6 and Comparative Examples 3 and 4

[Preparation of Resin Composition]

According to Tables 3, 4, and 7, each of the components was mixed with stirring to prepare each resin composition.

In the table, the numerical value for each component in each resin composition indicates the adding amount (in terms of part by mass) of each component.

TABLE 7

| | | Photosensitive resin composition (coloration composition layer) | | | | |
|---|---|---|---|---|---|---|
| | | 6 | 7 | 8 | 9 | 10 |
| Pigment | Black pigment dispersion | 186.4 | 186.4 | 186.4 | 186.4 | 186.4 |
| | FDK-T-11 | | | | | |
| Resin | ACRIT 8KB-001 | 182.6 | 182.6 | 182.6 | 182.6 | 182.6 |
| Polymerizable | A-NOD-N | 4.4 | 4.4 | 4.4 | 4.4 | 4.4 |
| compound | A-DCP | 13.3 | 13.3 | 13.3 | 13.3 | 13.3 |
| | 8UX-015A | 8.9 | 8.9 | 8.9 | 8.9 | 8.9 |
| | 75% by mass PGMEA solution | 3.9 | 3.9 | 3.9 | 3.9 | 3.9 |
| | of KAYARAD DPHA | | | | | |
| Photopolymerization | Irgacure OXE02 | 7.7 | 7.7 | 7.7 | 7.7 | 7.7 |
| initiator | | | | | | |
| Additive | 1,2,3-triazole | 3.2 | 3.2 | 3.2 | 3.2 | 3.2 |
| Block copolymer | B-1 | 1.6 | | | | |
| | B-2 | | 1.6 | | | |
| | B-3 | | | 1.6 | | |
| Comparative | MEGAFACE F555A (manufactured | | | | 1.6 | |
| compound | by DIC Corporation) | | | | | |
| | R-1 | | | | | 1.6 |
| Solvent | PGMEA | 195.8 | 195.8 | 195.8 | 195.8 | 195.8 |
| | MEK | 392.5 | 392.5 | 392.5 | 392.5 | 392.5 |

| | | | | | |
|---|---|---|---|---|---|
| Total (part by mass) | 1000 | 1000 | 1000 | 1000 | 1000 |
| Average film thickness of photosensitive resin | 3.0 | 3.0 | 3.0 | 3.0 | 3.0 |
| composition layer (μm) | | | | | |

In Table 7, each component indicates the following component.
Black pigment dispersion FDK-T-11: Manufactured by TOKYO PRINTING INK MFG. Co., Ltd.
ACRIT 8KB-001: An alkali-soluble resin, solid content concentration: 38% by mass, solvent: PGMEA, manufactured by Taisei Fine Chemical Co., Ltd., ACRIT (registered trade name) 8KB-001
A-NOD-N: 1,9-nonanediol diacrylate, manufactured by SHIN-NAKAMURA CHEMICAL Co., Ltd.
A-DCP: Tricyclodecanedimethanol diacrylate (manufactured by SHIN-NAKAMURA CHEMICAL Co., Ltd.)
8UX-015A: Urethane acrylate, manufactured by Taisei Fine Chemical Co., Ltd.
75% by mass PGMEA solution of KAYARAD DPHA: A 75% by mass propylene glycol monomethyl ether acetate solution of KAYARAD DPHA (product name: manufactured by Nippon Kayaku Co., Ltd. The composition of KAYARAD DPHA is shown below.

It is noted that in the table, the column “Average film thickness of photosensitive resin composition layer (μm)” indicates the average film thickness of the photosensitive resin composition layer formed in a case where a test has been carried out using each photosensitive resin composition.

In addition, the photosensitive resin compositions 6 to 10 correspond to a photosensitive resin composition which is a coloration resin composition.

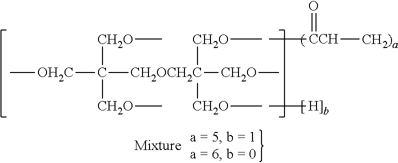

Irgacure OXE-02: Manufactured by BASF SE, ethanone, 1-[9-ethyl-6-(2-methylbenzoyl)-9H-carbazole-3-yl]-1-(0-acetyloxime)
1,2,4-triazole: Manufactured by Tokyo Chemical Industry Co., Ltd.
B-1 to B-3: The block copolymers described above
MEGAFACE F555A: Manufactured by DIC Corporation
R-1: Comparative compound described above
PGMEA: Propylene glycol monomethyl ether acetate (manufactured by Showa Denko K.K.)
MEK: Methyl ethyl ketone (manufactured by SANKYO CHEMICAL Co., Ltd.)

[Preparation of Transfer Film]

Each transfer film was produced in the same procedure as in [Preparation of transfer film] in Examples 1 to 3 and Comparative Examples 1 and 2 described above, except that each resin composition was used according to Table 8.

[Evaluation of Concentration Unevenness]

A polyethylene terephthalate film (a PET substrate) having a thickness of 100 μm was prepared.

The produced transfer film was wound forward, and then the surface of the photosensitive resin composition layer (the coloration resin composition layer) as the outermost layer, which had been disposed on the temporary support, was affixed to the above-described PET substrate under laminating conditions of a roll temperature of 100° C., a linear pressure of 1.0 MPa, and a linear speed of 4.0 m/min, thereby laminating the PET substrate to the transfer film. Next, after exposure with an ultra-high pressure mercury lamp without peeling off the temporary support, the temporary support was peeled off and developed. Development was carried out using a 1.0% sodium carbonate aqueous solution at 25° C. for 30 seconds by shower development. An exposure amount at which the resist line width was 20 μm was defined as the optimum exposure amount, when a line-and-space pattern mask was formed through a line-and-space pattern mask (Duty ratio 1:1, line width: 20 μm) by the above method.

A cured film formed at the optimum exposure amount was placed on a high-intensity schaukasten, and the concentration unevenness was visually observed. Evaluation was carried out according to the following evaluation standards. Evaluation A or B is a practically acceptable range.

(Evaluation Standard)

A: No unevenness is seen (very good).

B: Slight unevenness is seen, but it is at an unnoticeable level (good).

C: Although unevenness is observed, the unevenness is at a practical level (normal).

D: There is unevenness (slightly bad).

E: There is strong unevenness (very bad).

TABLE 8

| | | | | | Comparative | Comparative |
|---|---|---|---|---|---|---|
| Resin composition layer | | Example 4 | Example 5 | Example 6 | Example 3 | Example 4 |
| First layer | Thermoplastic resin | 1 | 2 | 3 | 4 | 4 |
| | composition | | | | | |
| | Block copolymer | B-1 | B-2 | B-3 | MEGAFACE | MEGAFACE |
| | or comparative | | | | F551 | F551 |
| | compound | | | | | |
| Second | Water-soluble resin | 1 | 1 | 2 | 3 | 3 |
| layer | composition | | | | | |
| | Compound (1) | A-1 | A-1 | A-2 | MEGAFACE | MEGAFACE |
| | or comparative | | | | F444 | F444 |
| | compound | | | | | |
| Third layer | Photosensitive resin | 6 | 7 | 8 | 9 | 10 |
| | composition | | | | | |
| | (coloration | | | | | |
| | composition layer) | | | | | |
| | Block copolymer | B-1 | B-2 | B-3 | MEGAFACE | R-1 |
| | or comparative | | | | F555 | |
| | compound | | | | | |
| Evaluation | Concentration | A | A | B | E | C |
| result | unevenness | | | | | |

From the results of Examples 4 to 6, it has been confirmed that in a case where the transfer film according to the embodiment of the present invention is used, a desired effect is obtained From the comparison among Examples 4 and 5 and Example 6, it has been confirmed that in a case where the constitutional unit X and the compound represented by Formula (1) have a group represented by Formula (A), the effect of the present invention is more excellent.

### Examples 7 to 9 and Comparative Examples 5 and 6

[Preparation of Resin Composition]

According to Tables 9 and 10, each of the components was mixed with stirring to prepare each resin composition.

In the table, the numerical value for each component in each resin composition indicates the adding amount (in terms of part by mass) of each component.

TABLE 9

| | | Photosensitive resin composition | | | | |
|---|---|---|---|---|---|---|
| | | 11 | 12 | 13 | 14 | 15 |
| Resin | P-5 | 42.85 | | | | |
| | P-6 | | 49.03 | 49.03 | 49.03 | 49.03 |
| Polymerizable | A-DCP (manufactured by SHIN-NAKAMURA | 5.60 | 18.26 | 18.26 | 18.26 | 18.26 |
| compound | CHEMICAL Co., Ltd.) | | | | | |
| | A-NOD-N (manufactured by SHIN-NAKAMURA | | 2.79 | 2.79 | 2.79 | 2.79 |
| | CHEMICAL Co., Ltd.) | | | | | |
| | A-DPH (manufactured by SHIN-NAKAMURA | | 8.15 | 8.15 | 8.15 | 8.15 |
| | CHEMICAL Co., Ltd.) | | | | | |
| | Monomer having carboxy group, ARONIX TO- | 0.93 | 3.04 | 3.04 | 3.04 | 3.04 |
| | 2349 (manufactured by Toagosei Co., Ltd.) | | | | | |
| | Urethane acrylate 8UX-015A(manufactured by | 2.80 | | | | |
| | Taisei Fine Chemical Co., Ltd.) | | | | | |
| Photopolymerization | Irgacure OXE02 (manufactured by BASF SE) | 0.11 | 0.37 | 0.37 | 0.37 | 0.37 |
| initiator | | | | | | |
| | Irgacure 907 (manufactured by BASF SE) | 0.21 | 0.74 | 0.74 | 0.74 | 0.74 |
| Thermal crosslinking | DURANATE TPA-B80E (manufactured by Asahi | 4.53 | | | | |
| compound | Kasei Chemicals Co., Ltd.) | | | | | |
| | Q-1 | | 2.97 | 2.97 | 2.97 | 2.97 |
| | Q-2 | | 12.50 | 12.50 | 12.50 | 12.50 |
| Additive | N-phenylglycine (manufactured by Tokyo | 0.03 | 0.10 | 0.10 | 0.10 | 0.10 |
| | Chemical Industry Co., Ltd.) | | | | | |
| | Benzimidazole (manufactured by Tokyo Chemical | 0.09 | 0.13 | 0.13 | 0.13 | 0.13 |
| | Industry Co., Ltd.) | | | | | |
| | Isonicotinamide (manufactured by Tokyo | | 0.52 | 0.52 | 0.52 | 0.52 |
| | Chemical Industry Co., Ltd.) | | | | | |
| | SMA EF-40 (manufactured by TOMOEGAWA | | 1.20 | 1.20 | 1.20 | 1.20 |
| | Industry Co., Ltd.) | | | | | |
| Block copolymer | B-1 | 0.16 | | | | |
| | B-2 | | 0.16 | | | |
| | B-3 | | | 0.16 | | |
| Comparative | MEGAFACE F551A (manufactured by DIC | | | | 0.16 | |
| compound | Corporation) | | | | | |
| | R-1 | | | | | 0.16 |
| Solvent | MEK | 42.69 | 42.69 | 42.69 | 42.69 | 42.69 |

| | | | | | |
|---|---|---|---|---|---|
| Average film thickness of photosensitive resin composition layer (μm) | 8.0 | 5.0 | 5.0 | 5.0 | 5.0 |

In Table 9, each component indicates the following component.
P-5 and P-6: The alkali-soluble resins described above
A-DCP: Tricyclodecanedimethanol diacrylate (manufactured by SHIN-NAKAMURA CHEMICAL Co., Ltd.)
A-NOD-N: 1,9-nonanediol diacrylate, manufactured by SHIN-NAKAMURA CHEMICAL Co., Ltd.
A-DPH: Dipentaerythritol hexaacrylate, manufactured by Shin-Nakamura Chemical Co., Ltd.
Monomer having a carboxy group: ARONIX TO-2349, manufactured by Toagosei Co., Ltd.
Urethane acrylate 8UX-015A, manufactured by Taisei Fine Chemical Co., Ltd.
IRGACURE OXE-02: l-[9-ethyl-6-(2-methylbenzoyl)-9H-carbazole-3-yl]-1-(O-acetyloxime), manufactured by BASF SE.
Omnirad 907: 2-methyl-1-(4-methylthiophenyl)-2-morpholinopropane-1-one, manufactured by BASF SE
DURANATE TPA-B80E: The blocked isocyanate compound described above
Q-1 and Q-2: The blocked isocyanate compound described above
N-phenylglycine: Manufactured by Tokyo Chemical Industry Co., Ltd.
Benzimidazole: Manufactured by Tokyo Chemical Industry Co., Ltd.
Isonicotinamide: Manufactured by Tokyo Chemical Industry Co., Ltd.
SMA EF-40: A copolymer of styrene/maleic acid anhydride=4:1 (in terms of molar ratio), acid anhydride value: 1.94 mmol/g, Mw: 10,500 (manufactured by Cray Valley) B-1 to B-3: Block copolymers
MEGAFACE F551 A: Comparative Compound (manufactured by DIC Corporation)
MEK: Methyl ethyl ketone

It is noted that in the table, the column “Average film thickness of photosensitive resin composition layer (μm)” indicates the average film thickness of the photosensitive resin composition layer formed in a case where a test has been carried out using each photosensitive resin composition.

TABLE 10

| | Water-soluble resin composition layer | | |
|---|---|---|---|
| | 4 | 5 | 6 |
| NanoUse OZS-30M: ZiO₂ particle (containing tin oxide) | 4.34 | 4.34 | 4.34 |
| Methanol dispersion liquid (nonvolatile fraction: 30.5%) | | | |
| manufactured by Nissan Chemical Industries, Ltd. | | | |
| Ammonia water (25%) | 7.84 | 7.84 | 7.84 |
| P-7 | 0.21 | 0.20 | 0.21 |
| ARUFON UC-3920 (manufactured by Toagosei Co., Ltd.) | 0.08 | 0.02 | 0.08 |
| Monomer having carboxy group, ARONIX TO-2349 | 0.03 | 0.03 | 0.03 |
| (manufactured by Toagosei Co., Ltd.) | | | |
| Benzotriazole BT-LX (manufactured by JOHOKU | 0.03 | | 0.03 |
| CHEMICAL Co., Ltd.) | | | |
| Adenine (manufactured by Tokyo Chemical Industry | | 0.03 | |
| Co., Ltd.) | | | |
| N-methyldiethanolamine (manufactured by Tokyo | | 0.03 | |
| Chemical Industry Co., Ltd.) | | | |
| Monoisopropanolamine | 0.02 | | 0.02 |
| A-1 | 0.01 | | |
| A-2 | | 0.01 | |
| MEGAFACE F444 (manufactured by DIC Corporation) | | | 0.01 |
| Ion exchange water | 21.7 | 21.3 | 21.7 |
| Methanol | 65.8 | 66.2 | 65.8 |
| Average film thickness of refractive index adjusting layer (nm) | 80 | 80 | 80 |

In Table 10, each component indicates the following component.
NanoUse OZS-30M: Zro₂ particles (containing tin oxide) methanol dispersion liquid (nonvolatile fraction: 30.5% by mass), manufactured by Nissan Chemical Industries, Ltd.
Ammonia water (25% by mass)
P-7: The alkali-soluble resin described above
ARUFON UC-3920: A water-soluble resin, manufactured by Toagosei Co., Ltd.
Monomer having a carboxy group: ARONIX TO-2349, manufactured by Toagosei Co., Ltd.
Benzotriazole BT-LX, manufactured by JOHOKU CHEMICAL Co., Ltd.,
Adenine, manufactured by Tokyo Chemical Industry Co., Ltd.
N-methyldiethanolamine, manufactured by Tokyo Chemical Industry Co., Ltd.
Monoisopropanolamine
A-1 and A-2: The compound (1) described above
MEGAFACE F444: Comparative compound, manufactured by DIC Corporation
Ion exchange water
Methanol

In the table, the column “Average film thickness of water-soluble resin composition layer (μm)” indicates the average film thickness of the water-soluble resin composition layer formed in a case where a test has been carried out using the water-soluble resin composition.

In addition, the water-soluble resin compositions 4 to 6 also correspond to the composition for forming a refractive index adjusting layer.

[Preparation of Transfer Film]

Each transfer film was produced in the same procedure as in [Preparation of transfer film] in Examples 1 to 3 and Comparative Examples 1 and 2 described above, except that each resin composition was used according to Table 11.

[Evaluation of Surface Defects]

A polyethylene terephthalate film (a PET substrate) having a thickness of 100 μm was prepared.

The produced transfer film was wound forward, and then the surface of the outermost layer (the photosensitive resin composition layer) of the composition layers disposed on the temporary support was affixed to the above-described PET substrate under laminating conditions of a roll temperature of 100° C., a linear pressure of 1.0 MPa, and a linear speed of 4.0 m/min, thereby laminating the PET substrate to the transfer film. Next, after exposure with an ultra-high pressure mercury lamp without peeling off the temporary support, the temporary support was peeled off and developed. Development was carried out using a 1.0% sodium carbonate aqueous solution at 25° C. for 30 seconds by shower development. An exposure amount at which the resist line width was 20 μm was defined as the optimum exposure amount, when a line-and-space pattern mask was formed through a line-and-space pattern mask (Duty ratio 1:1, line width: 20 μm) by the above method.

The surface of the cured film formed at the optimum exposure amount was visually observed for a region having a length of 10 μm and a width of 1.5 m, and surface defects were evaluated according to the following evaluation standards. Evaluation A or B is a practically acceptable range.

(Evaluation Standard)

A: Surface defects are less than 1 defect/m².

B: Surface defects are 1 defect/m² or more and less than 3 defects/m².

C: Surface defects are 3 defects/m² or more and less than 5 defects/m².

D: Surface defects are 5 defects/m² or more and less than 10 defects/m².

E: Surface defects are 10 defects/m² or more.

TABLE 11

| | | | | | Comparative | Comparative |
|---|---|---|---|---|---|---|
| Resin composition layer | | Example 7 | Example 8 | Example 9 | Example 5 | Example 6 |
| First layer | Photosensitive resin composition | 11 | 12 | 13 | 14 | 15 |
| | Block copolymer | B-1 | B-2 | B-3 | MEGAFACE | R-1 |
| | or comparative compound | | | | F551 | |
| Second layer | Water-soluble resin composition | 4 | 5 | 5 | 6 | 6 |
| | (refractive index adjusting | | | | | |
| | composition) | | | | | |
| | Compound (1) | A-1 | A-1 | A-2 | MEGAFACE | MEGAFACE |
| | or comparative compound | | | | F444 | F444 |
| Evaluation result | Surface defect | A | A | B | E | C |

From the results of Examples 7 to 9, it has been confirmed that in a case where the transfer film according to the embodiment of the present invention is used, a desired effect is obtained

From the comparison among Examples 7 and 8 and Example 9, it has been confirmed that in a case where the constitutional unit X and the compound represented by Formula (1) have a group represented by Formula (A), the effect of the present invention is more excellent.

### Examples 10 to 12 and Comparative Examples 7 and 8

[Preparation of Resin Composition]

According to Table 12, each of the components was mixed with stirring to prepare each resin composition.

In the table, the numerical value for each component in each resin composition indicates the adding amount (in terms of part by mass) of each component.

TABLE 12

| | | Photosensitive resin composition | | | | |
|---|---|---|---|---|---|---|
| | | 16 | 17 | 18 | 19 | 20 |
| Resin | P-8 | 94.12 | 94.12 | 94.12 | 94.12 | 94.12 |
| Photoacid generator | C-1 | 5 | 5 | 5 | 5 | 5 |
| Coloring agent | BB-1 | 0.13 | 0.13 | 0.13 | 0.13 | 0.13 |
| Additive | 1,2,3-benzotriazole | 0.17 | 0.17 | 0.17 | 0.17 | 0.17 |
| Block copolymer | B-1 | 0.21 | | | | |
| | B-2 | | 0.21 | | | |
| | B-3 | | | 0.21 | | |
| Comparative | MEGAFACE F552 (manufactured by | | | | 0.21 | |
| compound | DIC Corporation) | | | | | |
| | R-1 | | | | | 0.21 |
| Solvent | n-propyl acetate | 567 | 567 | 567 | 567 | 567 |

| | | | | | |
|---|---|---|---|---|---|
| Average film thickness of photosensitive resin composition | 3.0 | 3.0 | 3.0 | 3.0 | 3.0 |
| layer (μm) | | | | | |

In Table 12, each component indicates the following component.
P-8: The above-described resin having a constitutional unit having an acid group protected by an acid-decomposable group
C-1: A photoacid generator, a compound having a structure shown below (the synthesis was carried out according to the compound described in paragraph [0227] of JP2013-047765A and the method described in paragraph [0227] thereof). 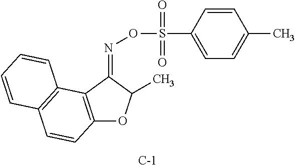
BB-1: A coloring agent, a compound having a structure shown below 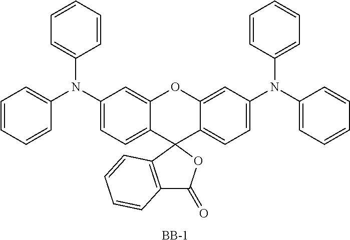
1,2,3-benzotriazole
B-1 to B-3: The block copolymers described above
MEGAFACE F552: Comparative compound, manufactured by DIC Corporation
R-1: Comparative compound described above
n-propyl acetate

It is noted that in the table, the column “Average film thickness of photosensitive resin composition layer (μm)” indicates the average film thickness of the photosensitive resin composition layer formed in a case where a test has been carried out using each photosensitive resin composition.

[Preparation of Transfer Film]

Using a slit-shaped nozzle, the prepared photosensitive resin composition 16 was applied onto a polyethylene terephthalate film (Lumirror 16KS40 (manufactured by Toray Industries, Inc.)) having a thickness of 16 μm so that the width was 1.0 μm and the average film thickness of the composition layer after drying was the specific film thickness, and it was allowed to pass through, over 60 seconds, a drying zone of 3 m in which the temperature was set to 100° C. and the film surface wind speed was set to be 3 m/sec by adjusting the intake amount and the exhaust amount, thereby obtaining a transfer film of Example 10.

Each of transfer films was obtained in the same procedure as in Example 10, except that in Examples 11 and 12 and Comparative Examples 7 and 8, the thermoplastic resin compositions were changed as described in Table 13.

[Evaluation of Resolution]

The resolution was evaluated according to the same procedure and evaluation standards as in [Evaluation of resolution] in Examples 1 to 3 and Comparative Examples 1 and 2 described above.

TABLE 13

| | | | | | Comparative | Comparative |
|---|---|---|---|---|---|---|
| Resin composition layer | | Example 10 | Example 11 | Example 12 | Example 7 | Example 8 |
| First layer | Photosensitive resin composition | 16 | 17 | 18 | 19 | 20 |
| | Block copolymer or comparative | B-1 | B-2 | B-3 | MEGAFACE | R-1 |
| | compound | | | | F552 | |
| Evaluation | Resolution | A | A | B | D | C |
| result | | | | | | |

From the results of Examples 10 to 12, it has been confirmed that in a case where the transfer film according to the embodiment of the present invention is used, a desired effect is obtained

From the comparison among Examples 10 and 11 and Example 12, it has been confirmed that in a case where the constitutional unit X and the compound represented by Formula (1) have a group represented by Formula (A), the effect of the present invention is more excellent.

### EXPLANATION OF REFERENCES

10: temporary support
12: thermoplastic resin layer
14: interlayer
16: photosensitive resin composition layer
18: cover film
100: transfer film

What is claimed is:

1. A transfer film comprising:
a temporary support; and
a resin composition layer disposed on the temporary support,
wherein the resin composition layer contains
a resin, and
at least one compound selected from the group consisting of a block copolymer, which contains a block consisting of a constitutional unit X having a group represented by Formula (A) or a group represented by Formula (B) and a block a constitutional unit Y having a poly(oxyalkylene) group, and a compound represented by Formula (1),
*—(CH₂)ₘ—(CF₂)ₙ—CF₃ Formula (A)
in Formula (A), m and n each independently represent an integer of 1 to 3, and
represents a bonding position,
*—Li—CH(CF₃)—CF₃ Formula (B)
in Formula (B), L¹ represents an oxygen atom or an alkylene group, and * represents a bonding position,
Z-L²-W Formula (1)
in Formula (1), Z represents a group represented by Formula (A) or a group represented by Formula (B),
L² represents a single bond or a divalent linking group, and
W represents a group including a poly(oxyalkylene) group.

2. The transfer film according to claim 1,
wherein the constitutional unit X and the compound represented by Formula (1) have a group represented by Formula (A).

3. The transfer film according to claim 1,
wherein the constitutional unit X and the compound represented by Formula (1) have a group represented by Formula (B).

4. The transfer film according to claim 1,
wherein the compound represented by Formula (I) is contained, and a molecular weight of the compound represented by Formula (1) is 2,000 or less.

5. The transfer film according to claim 1,
wherein the block copolymer is contained, and a weight-average molecular weight of the block copolymer is 5,000 or more.

6. The transfer film according to claim 1,
wherein the resin is an alkali-soluble resin, and
the resin composition layer further contains a polymerizable compound.

7. The transfer film according to claim 1,
wherein the resin is a resin having a constitutional unit having an acid group protected by an acid-decomposable group, and
the resin composition layer further contains a photoacid generator.

8. The transfer film according to claim 1,
wherein the resin composition layer is a water-soluble resin composition layer.

9. The transfer film according to claim 8,
wherein the water-soluble resin composition layer contains metal oxide particles.

10. The transfer film according to claim 1,
wherein the resin composition layer is a thermoplastic resin composition layer.

11. The transfer film according to claim 1,
wherein the resin composition layer further contains a pigment.

12. The transfer film according to claim 1,
wherein the resin composition layer includes two or more layers of the resin composition layer.

13. A manufacturing method for a laminate, comprising:
an affixing step of bringing a substrate into contact with a surface of the transfer film according to claim 1 on a side opposite to the temporary support and affixing the transfer film to the substrate to obtain a transfer film-attached substrate;
an exposure step of subjecting the resin composition layer to pattern exposure;
a development step of developing the exposed resin composition layer to form a resin pattern; and
a peeling step of peeling the temporary support from the transfer film-attached substrate between the affixing step and the exposure step, or between the exposure step and the development step.

14. A manufacturing method for a circuit wire, comprising:
an affixing step of bringing a surface of the transfer film according to claim 1 on a side opposite to the temporary support into contact with a substrate having a conductive layer and affixing the transfer film to the substrate having the conductive layer to obtain a transfer film-attached substrate;
an exposure step of subjecting the resin composition layer to pattern exposure;
a development step of developing the exposed resin composition layer to form a resin pattern;
an etching step of subjecting the conductive layer in a region where the resin pattern is not disposed to an etching treatment; and
a peeling step of peeling the temporary support from the transfer film-attached substrate, between the affixing step and the exposure step or between the exposure step and the development step.

15. A manufacturing method for an electronic device, comprising:
the manufacturing method for a laminate according to claim 13,
wherein the electronic device includes the resin pattern as a cured film.

16. The transfer film according to claim 1,
wherein the block copolymer is contained, a weight-average molecular weight of the block copolymer is 5,000 or more, and the constitutional unit X is a constitutional unit represented by Formula (C), 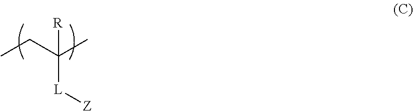
where R represents a hydrogen atom or a substituent, L represents a single bond or a divalent linking group, Z represents a group represented by the Formula (A) or a group represented by the Formula (B),
a content of the block copolymer is 0.01% to 3.00% by mass with respect to a total mass of the resin composition layer,
the resin is an alkali-soluble resin, and a content of the resin is 20.00% to 80.00% by mass with respect to a total mass of the resin composition layer, and
the resin composition layer further contains a polymerizable compound, and the polymerizable compound has an ethylenically unsaturated group as a polymerizable group.
